(19) United States
(12) Patent Application Publication
(10) Pub. No.: US 2026/0011612 A1
(43) Pub. Date: Jan. 8, 2026

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventors: HIROYUKI SHIGETA, KANAGAWA (JP); DAISUKE CHINO, KANAGAWA (JP); YUTAKA OOTAKI, KANAGAWA (JP); KIYOHISA SAKAI, KANAGAWA (JP)

(21) Appl. No.: 18/881,383

(22) PCT Filed: Jun. 30, 2023
(86) PCT No.: PCT/JP2023/024323

§ 371 Date: Jan. 6, 2025

(30) Foreign Application Priority Data
Jul. 12, 2022 (JP) 2022-111614

(51) Int. Cl. H01L 23/053; H01L 23/10; H10F 77/40; H10F 77/50

(52) U.S. Cl. CPC H01L 23/053; H01L 23/10; H10F 77/407; H10F 77/50

(57) ABSTRACT

A semiconductor device enables obtainment of an attachment state of a cover member in order to obtain good handleability and to prevent foreign matter from entering the inside of a package, and enables the cover member to be easily removed in order to solve problems such as ghost and flare caused by the presence of the cover member. The semiconductor device includes: a substrate; a semiconductor element mounted on the substrate; a cover member covering the semiconductor element from above; a frame supporting the cover member relative to the substrate; and a cover holding portion detachably holding the cover member relative to at least a part of the frame.

### TECHNICAL FIELD

The present disclosure relates to a semiconductor device and an electronic device.

### BACKGROUND ART

Examples of a known semiconductor device including a semiconductor element (semiconductor chip) such as an imaging element, such as a CMOS image sensor, or a light emitting element, such as a semiconductor laser, include a semiconductor device having a hollow package structure obtained by tightly covering an upper opening portion of a box-shaped package main body portion having a semiconductor chip installed therein with a transparent cover glass that is a cover member. The cover glass is, for example, a member required to obtain good handleability of the semiconductor device during the step of mounting a lens unit on the semiconductor device and the like, or to prevent foreign matter from entering the package of the semiconductor device.

Regarding the package structure as described above, for example, when the semiconductor device is incorporated into a predetermined set structure forming an electronic device such as a camera device, the cover glass is removed from the package main body portion for the reason that, for example, the cover glass may cause ghost, flare, or an error in optical path distance. That is, as one mode of use of the semiconductor device, the semiconductor device is used with the cover glass once attached to the package main body portion removed.

Generally speaking, the cover glass, however, is fixed to the opening portion of the package main body portion with an adhesive to tightly cover the opening portion, so that it is not easy to remove the cover glass. At present, the cover glass is removed by forcibly peeling off the bonding portion of the cover glass with respect to the package main body portion, or the cover glass is removed by relying on a specialist.

Therefore, Patent Document 1 discloses a configuration where a cover glass is detachably fixed to a housing forming a package main body portion with an adhesive as a detachably attachable means. Patent Document 1 discloses that the adhesive has such an adhesive strength as to prevent the cover glass from separating during handling such as transportation of an imaging device or processing and to allow the cover glass to separate without breaking the housing or the cover glass.

### CITATION LIST

### Patent Document

Patent Document 1: Japanese Patent Application Laid-Open No. 11-355508

### SUMMARY OF THE INVENTION

### Problems to be Solved by the Invention

Patent Document 1 includes a description of the adhesive strength of the adhesive for fixing the cover glass, but does not specifically disclose a material of the adhesive, a bonding method, and the like. For this reason, it is difficult to obtain the adhesive strength of the adhesive as described above after reflow mounting on the set substrate or the like, and the technology disclosed in Patent Document 1 has poor feasibility.

Also, according to the configuration that uses an adhesive for fixing the cover glass, the glass may break at the time of removing the cover glass depending on the adhesive strength of the adhesive. In a case where the glass breaks, there is a possibility that a defect such as an imaging defect, for example, occurs due to scattered glass fragments adhering to pixels of the semiconductor chip.

An object of the present technology is to provide a semiconductor device and an electronic device capable of obtaining an attachment state of a cover member in order to obtain good handleability of the semiconductor device and to prevent foreign matter from entering the inside of a package, and allowing the cover member to be easily removed in order to solve problems such as ghost and flare caused by the presence of the cover member.

### Solutions to Problems

A semiconductor device according to the present technology includes a substrate; a semiconductor element mounted on the substrate; a cover member covering the semiconductor element from above; a frame supporting the cover member relative to the substrate; and a cover holding portion detachably holding the cover member relative to at least a part of the frame.

According to another aspect of the semiconductor device according to the present technology, in the semiconductor device, the frame includes a frame main body portion that surrounds the semiconductor element and forms a support surface supporting the cover member, and the semiconductor device further includes, as the cover holding portion, a cover fixing portion that is provided on an upper side of the frame main body portion and fixes the cover member to the frame by restricting movement of the cover member supported on the support surface relative to the frame main body portion.

According to another aspect of the semiconductor device according to the present technology, in the semiconductor device, the cover member is a member having a shape of a flat plate, and the frame includes, as the cover fixing portion, a step forming portion that forms a step portion relative to the support surface and comes into contact with a side surface of the cover member to restrict movement of the cover member, and a retaining portion that comes into contact with the side surface of the cover member and restricts movement of the cover member in a direction away from the support surface.

According to another aspect of the semiconductor device according to the present technology, in the semiconductor device, the frame includes, as the retaining portion, a clip portion configured to attach and detach the cover member to and from the frame main body portion with temporary elastic deformation, and a hook portion provided on an opposite side of the cover member from the clip portion, the hook portion allowing an edge portion of the cover member to be fitted between the hook portion and the support surface.

According to another aspect of the semiconductor device according to the present technology, in the semiconductor device, the frame main body portion has a recess that opens at the support surface and is partially covered with the cover member.

According to another aspect of the semiconductor device according to the present technology, in the semiconductor device, the frame includes a first frame portion fixed to the substrate and a second frame portion that forms the cover holding portion and is detachably attached to the first frame portion.

According to another aspect of the semiconductor device according to the present technology, in the semiconductor device, the second frame portion includes a frame-shaped main body portion holding the cover member and an engagement portion that is provided in the main body portion and engages with the first frame portion such that the second frame portion is held by the first frame portion.

According to another aspect of the semiconductor device according to the present technology, in the semiconductor device, the engagement portion is a rotation engaging body rotatably supported relative to the main body portion in a state of being urged by an urging member in a direction of engaging with an engaged portion formed in the first frame portion.

According to another aspect of the semiconductor device according to the present technology, in the semiconductor device, the first frame portion has a recess that opens at an upper surface and is partially covered with the cover member.

According to another aspect of the semiconductor device according to the present technology, in the semiconductor device, the frame includes a frame main body portion that surrounds the semiconductor element and forms a support surface that supports the cover member, and the semiconductor device further includes, as the cover holding portion, a step forming portion that is provided on an upper side of the frame main body portion, forms a step portion relative to the support surface, and comes into contact with a side surface of the cover member to restrict movement of the cover member, and a bonding portion that is interposed between the frame main body portion and the cover member and includes an adhesive for fixing the cover member to the frame main body portion.

According to another aspect of the semiconductor device according to the present technology, in the semiconductor device, the frame main body portion has a recess that opens at the support surface and is partially covered with the cover member.

According to another aspect of the semiconductor device according to the present technology, in the semiconductor device, the adhesive includes a hot melt adhesive, and a recess for positioning the bonding portion is formed in at least one of the support surface and a lower surface of the cover member facing the support surface.

A semiconductor device according to the present technology includes: a substrate; a semiconductor element mounted on the substrate; a cover member covering the semiconductor element from above; a frame supporting the cover member relative to the substrate; and a frame holding portion detachably holding the frame relative to the substrate.

According to another aspect of the semiconductor device according to the present technology, in the semiconductor device, the frame includes a frame main body portion that surrounds the semiconductor element and forms a support surface that supports the cover member, the cover member is fixed to the support surface, and the semiconductor device further includes, as the frame holding portion, a step forming portion that is provided on a lower side of the frame main body portion, forms a step portion relative to a lower surface of the frame main body portion, and comes into contact with a side surface of the substrate to restrict movement of the substrate, and a bonding portion that is interposed between the frame main body portion and the substrate and includes an adhesive for fixing the frame main body portion to the substrate.

According to another aspect of the semiconductor device according to the present technology, in the semiconductor device, the adhesive includes a hot melt adhesive, and a recess for positioning the bonding portion is formed in at least one of a lower surface of the frame main body portion and an upper surface of the substrate facing the lower surface.

According to another aspect of the semiconductor device according to the present technology, in the semiconductor device, the frame includes a frame main body portion that surrounds the semiconductor element and forms a support surface supporting the cover member, the cover member is fixed to the support surface, and the semiconductor device further includes, as the frame holding portion, an engagement portion that is provided on a lower side of the frame main body portion and fixes the frame to the substrate by engaging with the substrate.

According to another aspect of the semiconductor device according to the present technology, in the semiconductor device, the engagement portion includes a retaining protruding piece portion that is configured to be in a state of being retained to an engaged portion formed in the substrate with temporary elastic deformation.

According to another aspect of the semiconductor device according to the present technology, in the semiconductor device, the engagement portion and the substrate are configured such that relative rotation of the frame and the substrate with an up-down direction as a rotation axis direction causes a state in which the engagement portion engages with an engaged portion formed in the substrate.

An electronic device according to the present technology includes a semiconductor device including: a substrate; a semiconductor element mounted on the substrate; a cover member covering the semiconductor element from above; a frame supporting the cover member relative to the substrate; and a cover holding portion detachably holding the cover member relative to at least a part of the frame.

An electronic device according to the present technology includes a semiconductor device including: a substrate; a semiconductor element mounted on the substrate; a cover member covering the semiconductor element from above; a frame supporting the cover member relative to the substrate; and a frame holding portion detachably holding the frame relative to the substrate.

### BRIEF DESCRIPTION OF DRAWINGS

FIG. 1 is a plan view of the configuration of the solid-state imaging device according to a first embodiment of the present technology.

FIG. 2 is a cross-sectional end view taken along line A-A in FIG. 1.

FIG. 3 is a cross-sectional end view taken along line B-B in FIG. 1.

FIG. 4 is a cross-sectional end view taken along line C-C in FIG. 1.

FIG. 5 is an enlarged view of section D in FIG. 2.

FIG. 6 is an enlarged view of section E in FIG. 2.

FIG. 7 is a diagram for describing a method for manufacturing the solid-state imaging device according to the first embodiment of the present technology.

FIG. 8 is a diagram for describing the method for manufacturing the solid-state imaging device according to the first embodiment of the present technology.

FIG. 9 is a diagram for describing the method for manufacturing the solid-state imaging device according to the first embodiment of the present technology.

FIG. 10 is an explanatory diagram of a method for removing the cover glass of the solid-state imaging device according to the first embodiment of the present technology.

FIG. 11 is a side cross-sectional view illustrating a usage example of the solid-state imaging device according to the first embodiment of the present technology.

FIG. 12 is a plan view of the configuration of a modification of the solid-state imaging device according to the first embodiment of the present technology.

FIG. 13 is a cross-sectional end view taken along line F-F in FIG. 12.

FIG. 14 is a diagram for describing a method for manufacturing the configuration of a first modification of the solid-state imaging device according to the first embodiment of the present technology.

FIG. 15 is a plan view of the configuration of a second modification of the solid-state imaging device according to the first embodiment of the present technology.

FIG. 16 is a cross-sectional end view taken along line G-G in FIG. 15.

FIG. 17 is a plan view of the configuration of the solid-state imaging device according to a second embodiment of the present technology.

FIG. 18 is a cross-sectional end view taken along line H-H in FIG. 17.

FIG. 19 is a cross-sectional end view taken along line I-I in FIG. 17.

FIG. 20 is a cross-sectional end view taken along line J-J in FIG. 17.

FIG. 21 is a side end view illustrating a state in which a lid body of the solid-state imaging device according to the second embodiment of the present technology is removed.

FIG. 22 is a diagram for describing a method for manufacturing the solid-state imaging device according to the second embodiment of the present technology.

FIG. 23 is an upper perspective view illustrating the configuration of the solid-state imaging device according to a third embodiment of the present technology.

FIG. 24 is a cross-sectional view taken along line K-K in FIG. 23.

FIG. 25 is an enlarged view of section L in FIG. 24.

FIG. 26 is an exploded perspective view illustrating the configuration of the solid-state imaging device according to the third embodiment of the present technology.

FIG. 27 is a lower perspective view illustrating a lid body according to the third embodiment of the present technology.

FIG. 28 is a diagram for describing a method for manufacturing the solid-state imaging device according to the third embodiment of the present technology.

FIG. 29 is an upper perspective view illustrating the configuration of a modification of the solid-state imaging device according to the third embodiment of the present technology.

FIG. 30 is a cross-sectional view taken along line M-M in FIG. 29.

FIG. 31 is an upper perspective view illustrating the configuration of a modification of the solid-state imaging device according to the third embodiment of the present technology.

FIG. 32 is a plan view of the configuration of the solid-state imaging device according to a fourth embodiment of the present technology.

FIG. 33 is a cross-sectional end view taken along line N-N in FIG. 32.

FIG. 34 is a cross-sectional end view taken along line O-O in FIG. 32.

FIG. 35 is a cross-sectional end view taken along line P-P in FIG. 32.

FIG. 36 is a diagram for describing a method for manufacturing the solid-state imaging device according to the fourth embodiment of the present technology.

FIG. 37 is an explanatory diagram of a method for removing the cover glass of the solid-state imaging device according to the fourth embodiment of the present technology.

FIG. 38 is a side cross-sectional view illustrating a usage example of the solid-state imaging device according to the fourth embodiment of the present technology.

FIG. 39 is a side cross-sectional view of the configuration of a first modification of the solid-state imaging device according to the fourth embodiment of the present technology.

FIG. 40 is a side cross-sectional view of the configuration of a second modification of the solid-state imaging device according to the fourth embodiment of the present technology.

FIG. 41 is an enlarged view of section Q in FIG. 40.

FIG. 42 is a diagram for describing a method for manufacturing the configuration of a second modification of the solid-state imaging device according to the fourth embodiment of the present technology.

FIG. 43 is a partially enlarged side cross-sectional view of the configuration of a third modification of the solid-state imaging device according to the fourth embodiment of the present technology.

FIG. 44 is a partially enlarged side cross-sectional view of the configuration of a fourth modification of the solid-state imaging device according to the fourth embodiment of the present technology.

FIG. 45 is a partially enlarged side cross-sectional view of the configuration of a fifth modification of the solid-state imaging device according to the fourth embodiment of the present technology.

FIG. 46 is a side cross-sectional view of the configuration of a solid-state imaging device according to a fifth embodiment of the present technology.

FIG. 47 is a diagram for describing a method for manufacturing the solid-state imaging device according to the fifth embodiment of the present technology.

FIG. 48 is a side cross-sectional view of the configuration of a first modification of the solid-state imaging device according to the fifth embodiment of the present technology.

FIG. 49 is an enlarged view of section R in FIG. 48.

FIG. 50 is a partially enlarged side cross-sectional view of the configuration of a second modification of the solid-state imaging device according to the fifth embodiment of the present technology.

FIG. 51 is a partially enlarged side cross-sectional view of the configuration of a third modification of the solid-state imaging device according to the fifth embodiment of the present technology.

FIG. 52 is a partially enlarged side cross-sectional view of the configuration of a fourth modification of the solid-state imaging device according to the fifth embodiment of the present technology.

FIG. 53 is an upper perspective view illustrating the configuration of a solid-state imaging device according to a sixth embodiment of the present technology.

FIG. 54 is a cross-sectional end view taken along line S-S in FIG. 53.

FIG. 55 is an enlarged view of section T in FIG. 54.

FIG. 56 is a plan view illustrating the configuration of the substrate side of the solid-state imaging device according to the sixth embodiment of the present technology.

FIG. 57 is an exploded perspective view illustrating the configuration of the solid-state imaging device according to the sixth embodiment of the present technology.

FIG. 58 is a diagram for describing a method for manufacturing the solid-state imaging device according to the sixth embodiment of the present technology.

FIG. 59 is a diagram for describing a method for manufacturing the solid-state imaging device according to the sixth embodiment of the present technology.

FIG. 60 is a plan view illustrating the configuration of the substrate side of a first modification of the solid-state imaging device according to the sixth embodiment of the present technology.

FIG. 61 is a plan view illustrating the configuration of the substrate side of a second modification of the solid-state imaging device according to the sixth embodiment of the present technology.

FIG. 62 is a side cross-sectional view of the configuration of a third modification of the solid-state imaging device according to the sixth embodiment of the present technology.

FIG. 63 is an enlarged view of section U in FIG. 62.

FIG. 64 is a plan view illustrating the configuration of the substrate side of a third modification of the solid-state imaging device according to the sixth embodiment of the present technology.

FIG. 65 is an exploded perspective view illustrating the configuration of a third modification of the solid-state imaging device according to the sixth embodiment of the present technology.

FIG. 66 is an explanatory diagram of a manufacturing method of a third modification of the solid-state imaging device according to the sixth embodiment of the present technology.

FIG. 67 is a plan view illustrating the configuration of the substrate side of a fourth modification of the solid-state imaging device according to the sixth embodiment of the present technology.

FIG. 68 is an exploded perspective view illustrating the configuration of a fourth modification of the solid-state imaging device according to the sixth embodiment of the present technology.

FIG. 69 is a partially cutout cross-sectional plan view illustrating the configuration of a solid-state imaging device according to a seventh embodiment of the present technology.

FIG. 70 is a cross-sectional view taken along line V-V in FIG. 69.

FIG. 71 is an exploded perspective view illustrating the configuration of the solid-state imaging device according to the seventh embodiment of the present technology.

FIG. 72 is a diagram for describing a method for manufacturing the solid-state imaging device according to the seventh embodiment of the present technology.

FIG. 73 is a diagram for describing a method for manufacturing the solid-state imaging device according to the seventh embodiment of the present technology.

FIG. 74 is a partially cutout cross-sectional plan view illustrating the configuration of a modification of the solid-state imaging device according to the seventh embodiment of the present technology.

FIG. 75 is an exploded perspective view illustrating the configuration of a modification of the solid-state imaging device according to the seventh embodiment of the present technology.

FIG. 76 is a block diagram illustrating a configuration example of an electronic device including a solid-state imaging device according to an embodiment of the present technology.

### MODE FOR CARRYING OUT THE INVENTION

According to the present technology, it is possible to easily remove a cover member as necessary by devising the configuration of a frame portion that holds the cover member such as a cover glass, and it is possible to avoid disadvantages while having advantages due to the presence of the cover member.

Hereinafter, modes for carrying out the present technology (hereinafter referred to as “embodiments”) will be described with reference to the drawings. Note that the drawings are schematic, and dimensional ratios and the like of the respective parts do not necessarily match actual ones. Furthermore, it is needless to say that dimensional relationships and ratios are partly different between the drawings. In the embodiments to be described below, an imaging device (solid-state imaging device) including a solid-state imaging element that is an example of a semiconductor element will be described as an example of a semiconductor device. Note that the embodiments will be described in the following order.
1. Configuration example of solid-state imaging device according to first embodiment
2. Method for manufacturing solid-state imaging device according to first embodiment
3. Use example of solid-state imaging device according to first embodiment
4. Modification of solid-state imaging device according to first embodiment
5. Configuration example of solid-state imaging device according to second embodiment
6. Method for manufacturing solid-state imaging device according to second embodiment
7. Configuration example of solid-state imaging device according to third embodiment
8. Method for manufacturing solid-state imaging device according to third embodiment
9. Modification of solid-state imaging device according to third embodiment
10. Configuration example of solid-state imaging device according to fourth embodiment
11. Method for manufacturing solid-state imaging device according to fourth embodiment
12. Use example of solid-state imaging device according to fourth embodiment
13. Modification of solid-state imaging device according to fourth embodiment
14. Configuration example of solid-state imaging device according to fifth embodiment
15. Method for manufacturing solid-state imaging device according to fifth embodiment
16. Modification of solid-state imaging device according to fifth embodiment
17. Configuration example of solid-state imaging device according to sixth embodiment
18. Method for manufacturing solid-state imaging device according to sixth embodiment
19. Modification of solid-state imaging device according to sixth embodiment
20. Configuration example of solid-state imaging device according to seventh embodiment
21. Method for manufacturing solid-state imaging device according to seventh embodiment
22. Modification of solid-state imaging device according to seventh embodiment
23. Configuration example of electronic device

### 1. Configuration Example of Solid-State Imaging Device According to First Embodiment

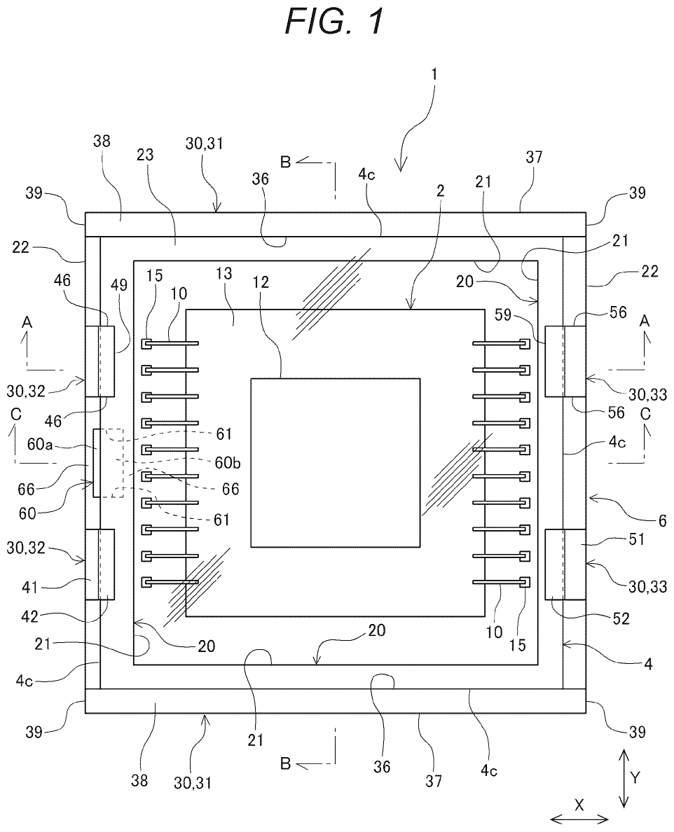

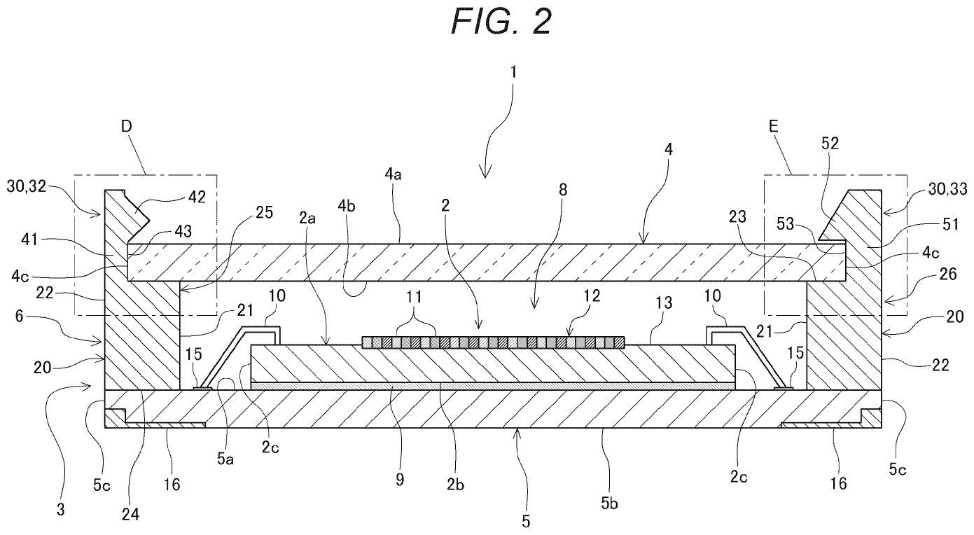

A configuration example of a solid-state imaging device according to a first embodiment of the present technology will be described with reference to FIGS. 1 to 6. Note that the up-down direction of a solid-state imaging device 1 refers to the up-down direction of FIG. 2.

As illustrated in FIGS. 1 and 2, the solid-state imaging device 1 includes a substrate 5, an image sensor 2 as a solid-state imaging element mounted on the substrate 5, a transparent cover glass 4 as a cover member covering the image sensor 2 from above, and a frame 6 forming a frame portion, which supports the cover glass 4 relative to the substrate 5. In the solid-state imaging device 1, a package main body portion 3 is formed by the substrate 5, on which the image sensor 2 is mounted, and the frame 6, which is provided on the substrate 5. Note that, in FIG. 1, a part that can be seen through the cover glass 4 is indicated by a solid line.

The solid-state imaging device 1 has a hollow package structure obtained by covering an upper opening portion of the box-shaped package main body portion 3 having the image sensor 2 as a semiconductor chip installed therein with the cover glass 4. That is, the solid-state imaging device 1 has, as a package structure, a structure in which the cover glass 4 is mounted on the substrate 5 with the frame 6 interposed between the cover glass 4 and the substrate 5, the substrate 5 having the image sensor 2 installed thereon, and a cavity 8 as a hollow portion is formed around the image sensor 2.

The substrate 5 is an interposer substrate, and is a flat member having a rectangular plate-shaped outline. The substrate 5 has a surface 5a that is one plate surface on which the image sensor 2 is mounted, a back surface 5b that is the other plate surface on the opposite side from the surface 5a, and side surfaces 5c provided on the four sides. The image sensor 2 is die-bonded to the surface 5a of the substrate 5. The image sensor 2 is bonded to the surface 5a of the substrate 5 with a die bonding material 9 including an insulating or conductive adhesive or the like. Note that a plate thickness direction of the substrate 5 coincides with the up-down direction of the solid-state imaging device 1, and the side corresponding to the surface 5a and the side corresponding to the back surface 5b coincide with the upper side and the lower side, respectively.

The substrate 5 is a ceramic substrate using ceramics such as alumina (Al2O3) or aluminum nitride (AlN) silicon nitride (Si3N4) as a base material, and is a circuit board on which a predetermined circuit pattern including a metal material is formed. Note that the substrate 5 may be, for example, another type of substrate such as an organic substrate using an organic material such as glass epoxy resin, which is a type of fiber-reinforced plastic, as a base material, and a glass substrate using glass.

The image sensor 2 is a semiconductor element including a semiconductor substrate including silicon (Si), which is an example of a semiconductor. The image sensor 2 is a rectangular plate-shaped chip, the side corresponding to the front surface 2a, which is one of plate surfaces, is a light receiving surface side, and the other plate surface on the opposite side is a back surface 2b. The image sensor 2 has side surfaces 2c provided on the four sides.

Multiple light receiving elements (photoelectric conversion elements) are formed on the side corresponding to the front surface 2a of the image sensor 2. The image sensor 2 is a complementary metal oxide semiconductor (CMOS) image sensor. Note that the image sensor 2 may be another type of imaging element such as a charge coupled device (CCD) image sensor.

The image sensor 2 includes, on the side corresponding to the front surface 2a, a pixel region 12 that is a light receiving region in which a large number of pixels 11 are formed, and a peripheral region 13 that is a region around the pixel region 12. In the pixel region 12, the large number of pixels 11 are formed in a predetermined arrangement pattern such as a Bayer arrangement, and form a light receiving portion in the image sensor 2. A predetermined peripheral circuit is formed in the peripheral region 13. The pixels 11 each include a photodiode as a photoelectric converter having a photoelectric conversion function, and multiple pixel transistors.

On the side corresponding to the front surface 2a of the image sensor 2, a color filter and an on-chip lens are formed on the semiconductor substrate so as to correspond to each pixel 11 via an antireflection film including an oxide film or the like, a planarization film including an organic material, and the like. The light incident on the on-chip lens is received by the photodiode via a color filter, a planarization film, and the like.

Note that the configuration of the image sensor 2 according to the present technology is not particularly limited. Examples of the configuration of the image sensor 2 include a front side illumination type in which the pixel region 12 is formed on the front surface side of the semiconductor substrate, a back side illumination type in which photodiodes and the like are arranged on the opposite side, and the back surface side of the semiconductor substrate serves as the light receiving surface side in order to improve light transmittance, and the like.

The substrate 5 and the image sensor 2 are electrically connected by multiple wires (bonding wires) 10 as connection members. The wires 10 are conductive wires and are thin metal wires including, for example, Au (gold), Cu (copper), Al (aluminum), or the like. Each wire 10 has one end connected to an electrode 15 formed on the surface 5a of the substrate 5, and has the other end connected to an electrode formed in the peripheral region 13 of the front surface 2a of the image sensor 2, and these electrodes are electrically connected to each other.

The multiple wires 10 are provided on the basis of the number of electrodes 15 of the substrate 5 or the like. In the example illustrated in FIG. 1, the multiple wires 10 are provided with respect to a pair of side portions facing each other in the image sensor 2. However, the arrangement position of the multiple wires 10 is not particularly limited, and for example, the multiple wires 10 may be provided with respect to four side portions of the image sensor 2.

The electrode 15 of the substrate 5 to which each wire 10 is connected is electrically connected to multiple terminal electrodes 16 formed on the side corresponding to the back surface 5b of the substrate 5 via a predetermined wiring portion formed in the substrate 5. For each terminal electrode 16, for example, a connection terminal, such as a solder ball or the like, is provided as a terminal for electrically connecting to a set substrate that is a circuit board on which the solid-state imaging device 1 is installed in an electronic device in which the solid-state imaging device 1 is mounted.

The frame 6 forms a frame-shaped portion provided on the substrate 5 so as to surround the image sensor 2, and forms a peripheral wall portion on the substrate 5. The frame 6 includes wall portions 20 provided on the four sides in a rectangular shape (including a square shape) in plan view corresponding to the rectangular shape of the substrate 5 in plan view, and the wall portions 20 form a frame-shaped frame main body portion 26. Each wall portion 20 has a substantially rectangular outline with the up-down direction as a longitudinal direction in side cross-sectional view (see FIG. 2). The wall portion 20 has an inner wall surface 21 that is a wall surface adjacent to the image sensor 2 and an outer wall surface 22 that is an outer wall surface on the opposite side from the inner wall surface 21.

The frame 6 is provided so as to make the outer wall surface 22 of each wall portion 20 flush with the side surface 5c of the substrate 5. Note that the frame 6 may be provided such that the outer wall surface 22 of each wall portion 20 is positioned inside or outside relative to the side surface 5c of the substrate 5.

The frame 6 has a glass support surface 23 on the upper side. The glass support surface 23 is a surface formed by the upper surface of each wall portion 20, and has a rectangular frame shape in plan view. The glass support surface 23 is formed as a plane located on a predetermined virtual plane perpendicular to the up-down direction. In the frame 6, the glass support surface 23 is in contact with the peripheral edge portion of the lower surface 4b of the cover glass 4 and serves as a support surface that supports the cover glass 4.

As described above, the frame 6 includes, as the frame main body portion 26, a frame-shaped portion formed by the four wall portions 20, which surround the image sensor 2 and form the glass support surface 23 that supports the cover glass 4. Also, the frame 6 also has a lower surface 24, which is a surface on the opposite side of the glass support surface 23 in the frame main body portion 26.

The frame 6 has a rectangular opening portion 25 on the upper side. The opening portion 25 is formed by the inner wall surfaces 21 provided on the four sides corresponding to the outline of the frame 6 in plan view. In the frame 6, the glass support surface 23 forms an opening end surface of the opening portion 25. The frame 6 thus forms the opening portion 25 of the package main body portion 3.

The frame 6 is provided on the surface 5a of the substrate 5 such that the lower surface 24 is positioned outside the electrodes 15, to which the wires 10 are connected, without coming into contact with the wires 10 and the electrodes 15. The frame 6 is provided by fixing a frame-shaped member on the surface 5a of the substrate 5 with an adhesive such as an epoxy resin adhesive or an acrylic resin adhesive.

The frame 6 is a single member including, for example, a resin material such as an epoxy resin, a metal material such as stainless steel or copper (Cu), or ceramics. As the material of the frame 6, a material that is easily elastically deformed to some extent is used. Furthermore, from the viewpoint of preventing reflection of light, for example, a low-reflection black resin material obtained by adding a black pigment such as carbon black or titanium black to resin such as a liquid crystal polymer or polyetheretherketone (PEEK) is used, and the frame 6 is manufactured by a known method such as injection molding or transfer molding. Note that the frame 6 is not limited to, for example, a configuration that includes only one type of material, and may have a composite structure having a portion including a metal material and a portion including a resin material.

Additionally, the frame 6 may be a portion formed in a predetermined shape by performing injection molding using a mold, such as a transfer mold, with respect to the substrate 5. In this case, in injection molding for forming the frame 6, for example, a frame portion including a portion to be the frame 6 corresponding to each substrate element is formed in a lattice shape by injection molding with respect to an integrated collective substrate in which multiple substrate elements to be the substrate 5 are continuous. Then, the molded product in which the frame portion is formed on the collective substrate by injection molding is divided by dicing or the like, whereby the configuration having the frame 6 on the substrate 5, that is, the package main body portion 3 is obtained.

When the frame 6 is formed by injection molding using a mold, the material of the frame 6 is, for example, a thermosetting resin containing silicon oxide as a main component or containing a filler such as alumina. Specifically, as the resin material forming the frame 6, for example, a thermosetting resin such as a phenol-based resin, a silicone-based resin, an acryl-based resin, an epoxy-based resin, or a urethane-based resin, a thermoplastic resin such as polyamide-imide or polypropylene, a photosensitive resin such as a UV-curable resin, which is an acryl-based resin, rubber, or other known resin materials are used alone or in combination. Even in this case, by using a black resin material containing a black pigment such as carbon black as the material of the frame 6, the frame 6 becomes a black portion, and the frame 6 can function as a light shielding portion.

As described above, the package main body portion 3 includes the substrate 5 forming a substrate portion on which the image sensor 2 is mounted, and the frame 6 provided on the upper side of the substrate 5 so as to surround the image sensor 2 and forming a frame portion having the opening portion 25 formed on the upper side. As described above, in the package main body portion 3, the frame 6 that is a component separate from the substrate 5 forming the substrate portion forms the frame portion. Note that the package main body portion 3 may include an integrated member such as a box-shaped package substrate having an upper side as an open side.

The cover glass 4 is an example of a transparent member, is provided on the substrate 5 via the frame 6, and is located above the image sensor 2. The cover glass 4 is a flat plate-shaped member having a rectangular plate-shaped outer shape and having an outer dimension larger than that of the image sensor 2. The cover glass 4 has an upper surface 4a that is an upper plate surface, a lower surface 4b that is a lower plate surface on the opposite side from the upper surface 4a and faces the image sensor 2, and side surfaces 4c provided on the four sides.

The cover glass 4 closes the opening portion 25 in a state of being supported on the glass support surface 23 of the frame 6. The cover glass 4 is provided on the frame 6 so as to be parallel to and spaced apart from the image sensor 2 on the light receiving surface side of the image sensor 2. The cover glass 4 has an outline dimension larger than an opening dimension of the opening portion 25, and is provided on the glass support surface 23 of the frame 6 to cover the entirety of the opening portion 25 from above.

The cover glass 4 transmits various types of light incident from the side corresponding to the upper surface 4a through an optical system such as a lens located above the cover glass 4. The light transmitted through the cover glass 4 reaches the light receiving surface of the image sensor 2 through the cavity 8. The cover glass 4 has a function of protecting the light receiving surface side of the image sensor 2. Note that, as the transparent member according to the present technology, for example, a plastic plate, a silicon plate, or the like may be used instead of the cover glass 4.

In the solid-state imaging device 1 having the above configuration, the light transmitted through the cover glass 4 passes through the cavity 8, and is received and detected by the light receiving elements forming the pixels 11 arranged in the pixel region 12 of the image sensor 2.

The solid-state imaging device 1 having the above configuration includes the following configuration for a fixing structure of the cover glass 4 fixed to the frame 6 forming the package main body portion 3. That is, the solid-state imaging device 1 includes a cover fixing portion 30 provided on the upper side of the frame main body portion 26 as a cover holding portion that detachably holds the cover glass 4 relative to the frame 6. The cover fixing portion 30 is a portion that fixes the cover glass 4 to the frame 6 by restricting the movement of the cover glass 4, which is supported on the glass support surface 23, relative to the frame main body portion 26. The cover fixing portion 30 is provided as a part of the frame 6.

Hereinafter, for convenience of description, the left-right direction and the up-down direction in FIG. 1 are defined as an X direction (first direction) and a Y direction (second direction), respectively, which are orthogonal to each other in plan view of the solid-state imaging device 1, and the left and right of FIG. 2 correspond to the left and right of the solid-state imaging device 1.

In the solid-state imaging device 1, the frame 6 includes, as the cover fixing portion 30, a pair of step forming portions 31 provided so as to face each other, and retaining portions (32, 33) provided so as to face each other. The step forming portion 31 and the retaining portions (32, 33) are provided as sections of the wall portions 20 protruding upward from the glass support surface 23.

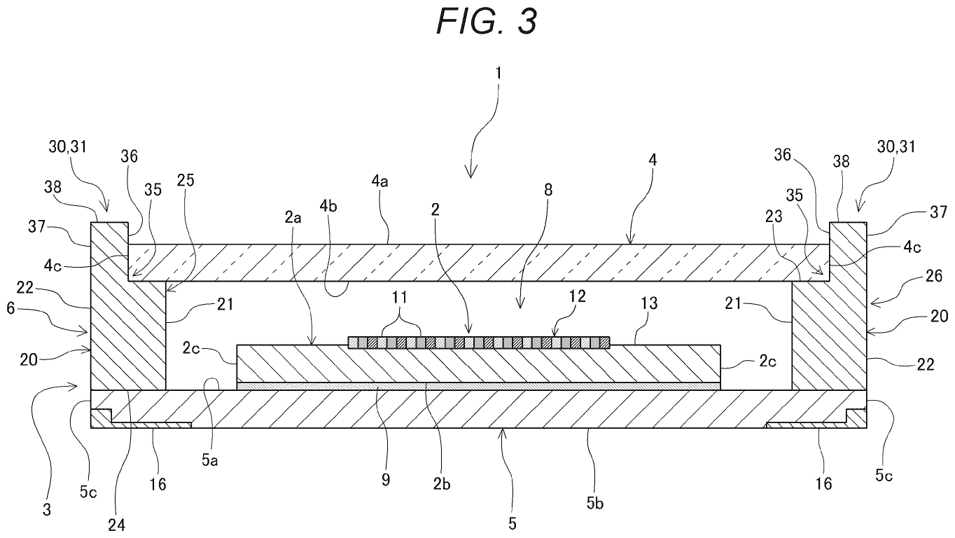

Each step forming portion 31 is a portion that forms a step portion 35 relative to the glass support surface 23 and is in contact with the side surface 4c of the cover glass 4 to restrict the movement of the cover glass 4 relative to the frame 6 (see FIG. 3). The step forming portions 31 are wall-shaped portions formed along a pair of wall portions 20 facing each other relative to the frame main body portion 26 formed in a frame shape by the four wall portions 20.

Each step forming portion 31 is provided on the wall portion 20 on the outer side (the side corresponding to the outer wall surface 22) in the wall thickness direction of the wall portion 20, and forms the step portion 35 together with the glass support surface 23. The step forming portion 31 includes an inner side surface 36, which is an inner wall surface and serves as a contact surface with the side surface 4c of the cover glass 4, an outer side surface 37, which is a wall surface opposite to the inner side surface 36, and a horizontal upper surface 38. The step forming portion 31 is formed such that the outer side surface 37 is located on the same plane as the outer wall surface 22 of the wall portion 20.

The step forming portions 31 are provided on the pair of wall portions 20, which face each other in the Y direction, over the entire ranges of the wall portions 20 in the extending direction (X direction). That is, each step forming portion 31 is provided such that the end surfaces 39 on both sides in the X direction are flush with the outer wall surface 22 of the adjacent wall portion 20 (see FIG. 1). However, the step forming portion 31 may be provided on the corresponding wall portion 20 partially along the extending direction of the wall portion 20 or provided at multiple positions.

The step forming portion 31 has the upper surface 38 as a step surface that is higher with respect to the glass support surface 23. At the step portion 35, the inner side surface 36 is positioned outside the inner wall surface 21 of the wall portion 20 and is formed as a surface parallel to the inner wall surface 21. In the example illustrated in FIG. 3, the step forming portion 31 has a dimension of about ½ of the wall thickness of the wall portion 20 in the wall thickness direction of the wall portion 20. However, the dimension of the step forming portion 31 in the wall thickness direction is not particularly limited.

The pair of step forming portions 31 is set such that the dimension between the inner side surfaces 36 facing each other is substantially the same as or slightly larger than the dimension of the cover glass 4 in the Y direction. The pair of step forming portions 31 restricts the movement of the cover glass 4 in the Y direction on the glass support surface 23 by coming into contact with the side surfaces 4c of the cover glass 4 at the inner side surfaces 36 in a state in which the cover glass 4 is fitted between the pair of step forming portions 31. As described above, the pair of step forming portions 31 form the step portions 35 that prevent lateral displacement of the cover glass 4 supported on the glass support surface 23 in the Y direction on both sides of the frame main body portion 26 in the Y direction.

In the example illustrated in FIG. 3, the dimension in the up-down direction of the step forming portion 31 is greater than the plate thickness dimension of the cover glass 4. However, the dimension in the up-down direction of the step forming portion 31 may be about the same as the plate thickness dimension of the cover glass 4, or may be less than the plate thickness dimension of the cover glass 4.

The retaining portions (32, 33) are portions that are in contact with the side surfaces 4c of the cover glass 4 and restrict movement in a direction away from the glass support surface 23. The frame 6 includes clip portions 32 as first retaining portions and hook portions 33 as second retaining portions as retaining portions for fixing the cover glass 4 to the frame 6 together with the pair of step forming portions 31.

The clip portions 32 and the hook portions 33 are partially formed in the extending direction (Y direction) of the wall portions 20. Also, the clip portions 32 and the hook portions 33 are formed in a common position range in the Y direction. However, in each wall portion 20, the clip portions 32 and the hook portions 33 may be provided over the entire range of the wall portion 20 in the extending direction, or may be formed in mutually different positional ranges in the Y direction.

The clip portions 32 and the hook portions 33 are provided in the frame main body portion 26 at a pair of wall portions 20 facing each other, and are provided so as to face each other. In the illustrated example, the clip portions 32 are provided at the left wall portion 20, and the hook portions 33 are provided at the right wall portion 20.

Two sets of a clip portion 32 and a hook portions 33 facing each other are provided. That is, the clip portions 32 are provided at two positions of the left wall portion 20 at a predetermined interval in the Y direction, and the hook portions 33 are provided at the positions of the right wall portion 20 facing the clip portions 32. In the frame main body portion 26, the two sets of a clip portion 32 and a hook portion 33 are provided symmetrically with respect to the Y direction.

The clip portions 32 are provided on the outer side (the side corresponding to the outer wall surface 22) of the wall portion 20 in the wall thickness direction of the wall portion 20. Each clip portion 32 includes a support column 41 formed in an upright state on the glass support surface 23 and a retaining protrusion 42 protruding inward in the X direction relative to the support column 41.

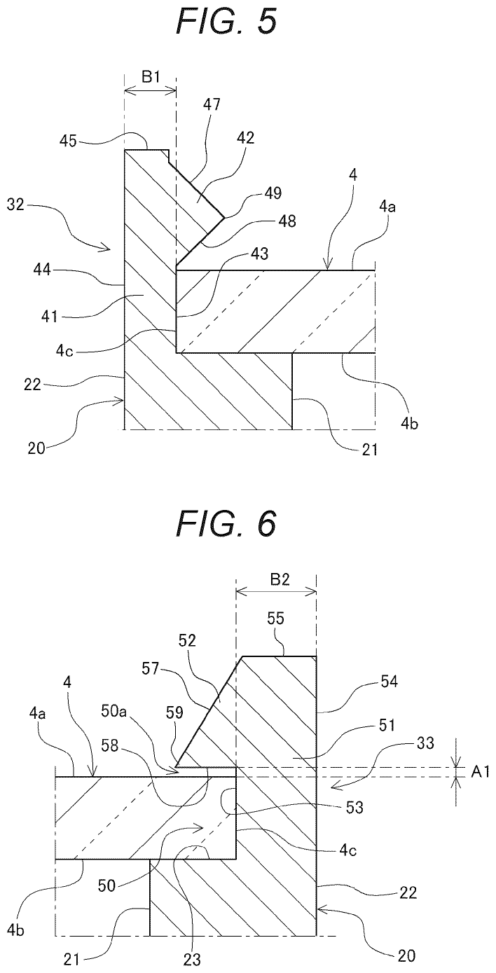

As illustrated in FIG. 5, the support column 41 is a wall-shaped portion with the X direction as the wall thickness direction, and includes an inner side surface 43, which is an inner wall surface and serves as a contact surface with the side surface 4c of the cover glass 4, an outer side surface 44, which is a wall surface opposite to the inner side surface 43, and a horizontal upper surface 45. The clip portion 32 is formed such that the outer side surface 44 is located on the same plane as the outer wall surface 22 of the wall portion 20. Also, the clip portion 32 has side end surfaces 46 on both sides in the Y direction, and is formed to have a constant cross-sectional shape in the entire Y direction (see FIG. 1).

In the clip portion 32, the inner side surface 43 is positioned outside the inner wall surface 21 of the wall portion 20 and is formed as a surface parallel to the inner wall surface 21. In the example illustrated in FIG. 2, the thickness dimension (dimension in the X direction) of the support column 41 is about ⅓ of the wall thickness of the wall portion 20. However, the thickness dimension of the support column 41 is not particularly limited. Additionally, the support column 41 is formed such that the dimension of the inner side surface 43 in the up-down direction is substantially the same as or slightly larger than the plate thickness of the cover glass 4.

The retaining protrusion 42 is formed on an upper part of the support column 41. The retaining protrusion 42 includes an upper inclined surface 47, which is inclined downward from the outside to the inside in the wall thickness direction of the wall portion 20, and a lower inclined surface 48, which is inclined in a direction from the lower side to the upper side from the outside to the inside in the wall thickness direction of the wall portion 20 (see FIG. 5).

The retaining protrusion 42 has a crest shape with the peak side on the inner side in side view formed by the upper inclined surface 47 and the lower inclined surface 48. The upper inclined surface 47 and the lower inclined surface 48 form a ridge portion 49 in the Y direction as an end portion on the protruding side of the retaining protrusion 42. In the example shown in FIG. 2, the upper inclined surface 47 and the lower inclined surface 48 are formed so as to be vertically symmetrical in side view, and are formed so as to form an angle of about 90° in side view. Note that there is no limitation on the angle formed by the upper inclined surface 47 and the lower inclined surface 48 in side view.

The hook portions 33 are provided on the opposite side of the cover glass 4 from the clip portions 32 in the X direction. The hook portions 33 are provided on the wall portion 20 on the outer side (the side corresponding to the outer wall surface 22) in the wall thickness direction of the wall portion 20. Each hook portion 33 includes a support column 51 formed in an upright state on the glass support surface 23, and a retaining protrusion 52 protruding inward in the X direction relative to the support column 51.

As illustrated in FIG. 6, the support column 51 is a wall-shaped portion with the X direction as the wall thickness direction, and includes an inner side surface 53, which is an inner wall surface and serves as a contact surface with the side surface 4c of the cover glass 4, an outer side surface 54, which is a wall surface opposite to the inner side surface 53, and a horizontal upper surface 55. The hook portion 33 is formed such that the outer side surface 54 is located on the same plane as the outer wall surface 22 of the wall portion 20. Also, the hook portion 33 has side end surfaces 56 on both sides in the Y direction, and is formed to have a constant cross-sectional shape in the entire Y direction.

In the hook portion 33, the inner side surface 53 is positioned outside the inner wall surface 21 of the wall portion 20 and is formed as a surface parallel to the inner wall surface 21. In the example illustrated in FIG. 2, the thickness dimension (dimension in the X direction) of the support column 51 is about ½ of the wall thickness of the wall portion 20. However, the thickness dimension of the support column 51 is not particularly limited. Additionally, the support column 51 is formed such that the dimension of the inner side surface 53 in the up-down direction is slightly greater than the plate thickness dimension of the cover glass 4.

The retaining protrusion 52 is formed on an upper part of the support column 51. The retaining protrusion 52 includes an upper inclined surface 57, which is downwardly inclined from the outside to the inside in the wall thickness direction of the wall portion 20, and a horizontal retaining surface 58, which is located above the glass support surface 23 and faces the glass support surface 23 (see FIG. 6).

The retaining protrusion 52 has a crest shape with the peak side on the inner side in side view formed by the upper inclined surface 57 and the retaining surface 58. The upper inclined surface 57 and the retaining surface 58 form a ridge portion 59 in the Y direction as an end portion on the protruding side of the retaining protrusion 52. In the example shown in FIG. 2, the upper inclined surface 57 and the retaining surface 58 are formed so as to form an angle of about 60° in side view. Note that there is no limitation on the angle formed by the upper inclined surface 57 and the retaining surface 58 in side view.

The clip portion 32 and the hook portion 33 are set such that the dimension between the inner side surfaces 43 and 53 facing each other is substantially the same as or slightly larger than the dimension of the cover glass 4 in the X direction. The clip portion 32 and the hook portion 33 restrict the movement of the cover glass 4 in the X direction on the glass support surface 23 by coming into contact with the side surfaces 4c of the cover glass 4 at the inner side surfaces 43 and 53 in a state in which the cover glass 4 is fitted between the clip portion 32 and the hook portion 33.

Also, the clip portions 32 and the hook portions 33 restrict upward movement of the cover glass 4 relative to the glass support surface 23 by positioning the cover glass 4 on the glass support surface 23 below the retaining protrusions 42 and 52. That is, the clip portion 32 and the hook portion 33 retain the cover glass 4 relative to the wall portion 20 and restrict the movement of the cover glass 4 in a direction away from the glass support surface 23 with the retaining protrusions 42 and 52 serving as contact portions with respect to the upper surface 4a of the cover glass 4.

Specifically, the clip portion 32 retains the cover glass 4 relative to the wall portion 20 with the lower inclined surface 48 of the retaining protrusion 42 serving as a contact surface with the upper corner portion of the cover glass 4. The hook portion 33 retains the cover glass 4 relative to the wall portion 20 with the retaining surface 58 of the retaining protrusion 52 serving as a contact surface with the upper surface 4a of the cover glass 4.

The hook portion 33 allows the right edge portion of the cover glass 4 to be fitted between the hook portions 33 and the glass support surface 23. That is, as illustrated in FIG. 6, the inner side surface 53 and the retaining surface 58 of the hook portion 33 form a recess 50 together with the glass support surface 23. The recess 50 has an open side on the inner side in the wall thickness direction of the wall portion 20. The hook portion 33 holds the cover glass 4 with the right edge portion of the cover glass 4 fitted in the recess 50.

As illustrated in FIG. 6, in a state in which the cover glass 4 is supported on the glass support surface 23, there is a gap 50a between the upper surface 4a of the cover glass 4 and the retaining surface 58 of the hook portion 33. In FIG. 6, the size of the gap 50a is indicated by a dimension Al.

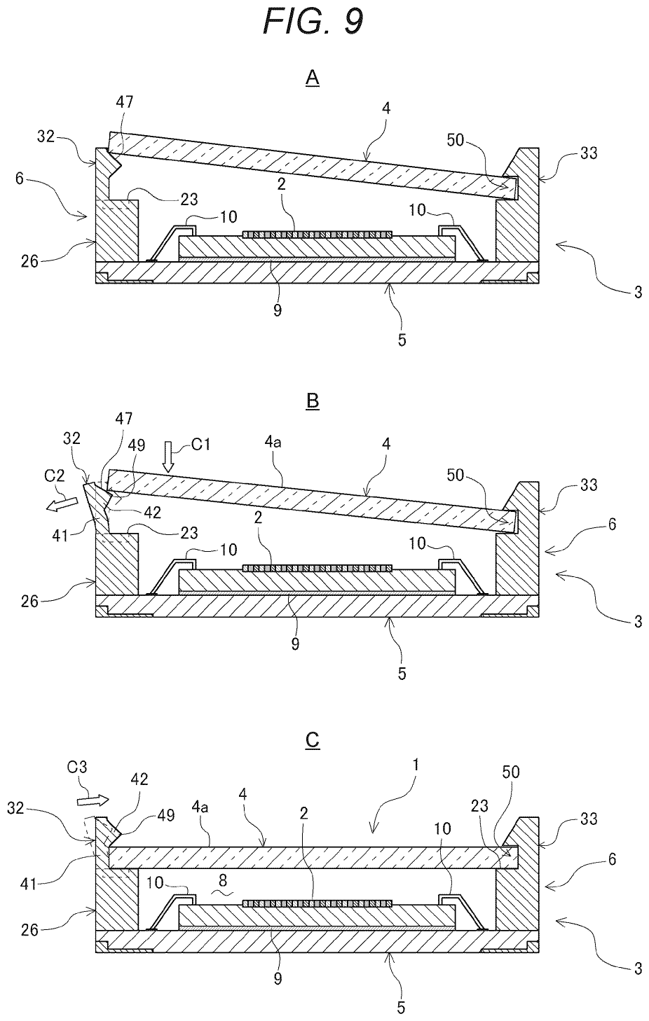

The clip portion 32 allows the cover glass 4 to be attached to and detached from the frame main body portion 26 with temporary elastic deformation. Specifically, as temporary elastic deformation, the clip portion 32 deforms to warp outward in the wall thickness direction of the wall portion 20 so as to widen the space between the clip portion 32 and the hook portion 33 for the cover glass 4 that is being attached to the frame 6 from above (see FIG. 9B). Furthermore, the clip portion 32 performs similar elastic deformation also when the cover glass 4 is removed from the frame 6. Therefore, the clip portion 32 is formed as a portion having flexibility that allows the clip portion 32 to appropriately bend when the cover glass 4 is attached or detached.

As illustrated in FIG. 5, in the clip portion 32, the size of the dimension B1 in the thickness direction of the support column 41 is set such that the temporary elastic deformation as described above is performed. In the present embodiment, the thickness dimension B1 of the support column 41 of the clip portion 32 is smaller than the thickness dimension B2 of the support column 51 of the hook portion 33. Although it is merely an example, in the example illustrated in FIG. 2, the thickness dimension B2 of the support column 51 is about 1.5 times the thickness dimension B1 of the support column 41.

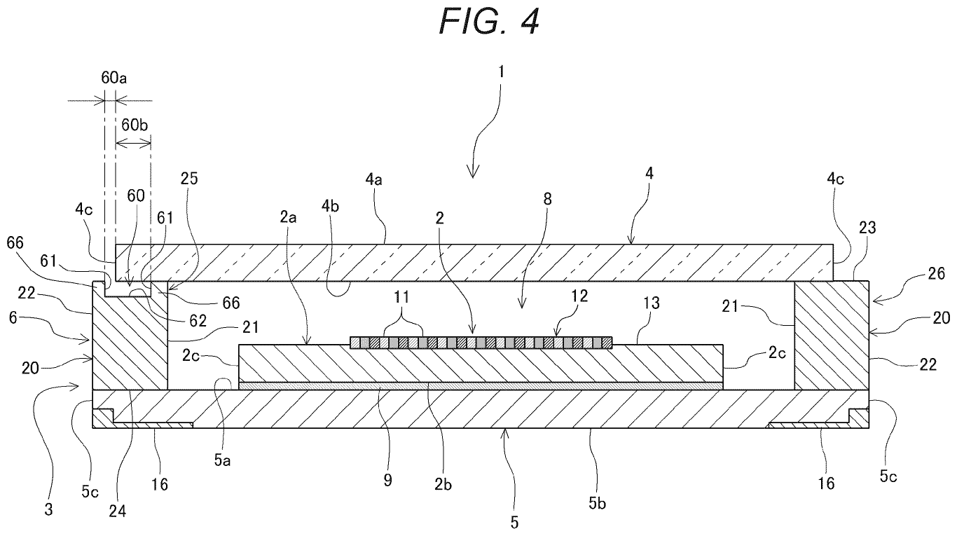

Additionally, as illustrated in FIGS. 1 and 4, the frame main body portion 26 has a recess 60, which opens at the glass support surface 23 and is at least partially covered with the cover glass 4. The recess 60 is formed in the left wall portion 20 on which the clip portions 32 are provided among the four wall portions 20 forming the frame main body portion 26. The recess 60 is formed in a central portion of the left wall portion 20 in the extending direction (Y direction) of the wall portion 20 and in a portion between the two clip portions 32.

The recess 60 is formed in an intermediate portion of the wall portion 20 in the wall thickness direction (X direction). That is, at the formation site of the recess 60, a wall-shaped edge wall portion 66 forming a part of the glass support surface 23 is formed on the inner side and the outer side in the X direction. The recess 60 is a recessed portion having a rectangular opening shape in which the extending direction of the wall portion 20 is the longitudinal direction in plan view, and includes four side surfaces 61 having a vertical surface shape and a bottom surface 62 having a horizontal surface shape.

The recess 60 includes, as region portions in relation to the cover glass 4 supported on the glass support surface 23, an exposed portion 60a exposed to the outside of the cover glass 4 in plan view and a covered portion 60b covered with the cover glass 4. That is, the exposed portion 60a is a portion of the recess 60 on the outer side (the left side in FIG. 1) of the left side surface 4c of the cover glass 4, and the covered portion 60b is a portion of the recess 60 on the inner side (the right side in FIG. 1) of the left side surface 4c of the cover glass 4. In the covered portion 60b of the recess 60, the lower surface 4b of the cover glass 4 faces the bottom surface 62. In the example shown in FIG. 1, most of the inside of the recess 60 is the covered portion 60b.

The recess 60 is used to allow a tool used for removing the cover glass 4 from the frame 6 to act on the cover glass 4. For removing the cover glass 4, for example, a tool such as a precision flathead screwdriver (a flathead screwdriver of a precision screwdriver) is used. For this reason, the recess 60 has a size that secures a space into which a tool such as a precision flathead screwdriver can be inserted into the exposed portion 60a with a certain margin. Note that the shape and size of the recess 60, the formation site on the glass support surface 23, and the like are not particularly limited as long as the recess has the exposed portion 60a and the covered portion 60b in relation to the cover glass 4 and has a space that allows a tool for removing the cover glass 4 to be inserted into the exposed portion 60a.

### 2. Method for Manufacturing Solid-State Imaging Device According to First Embodiment

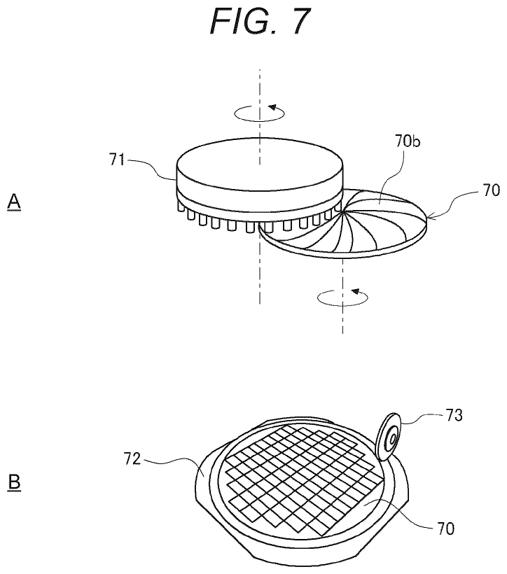

An example of a method for manufacturing the solid-state imaging device 1 according to the first embodiment of the present technology will be described with reference to FIGS. 7 to 9.

First, as illustrated in FIG. 7A, a silicon wafer 70 having the pixel region 12 corresponding to each image sensor 2 formed on the front surface side is prepared. The silicon wafer 70 has undergone various processes for forming the image sensors 2. That is, the silicon wafer 70 is a semiconductor wafer in which multiple portions to be the image sensors 2 each having a pixel group formed on one plate surface side in a predetermined arrangement.

As illustrated in FIG. 7A, for the silicon wafer 70, a back-grinding (BG) step of grinding the silicon wafer 70 from the side corresponding to the back surface 70b is performed to set the silicon wafer 70 to a desired thickness that does not affect device characteristics. In the BG process, for example, a back grinding wheel 71 such as a diamond wheel is used to grind the silicon wafer 70.

Next, as illustrated in FIG. 7B, the silicon wafer 70 is diced along a predetermined dicing line. That is, the step of cutting, in accordance with the predetermined arrangement, the silicon wafer 70 into chips each corresponding to the image sensor 2 is performed. In the dicing process, the silicon wafer 70 set on a chuck table 72 is cut by a dicing blade 73 into separate chips each corresponding to the image sensor 2. As a result, the image sensors 2 as a large number of sensor chips are obtained.

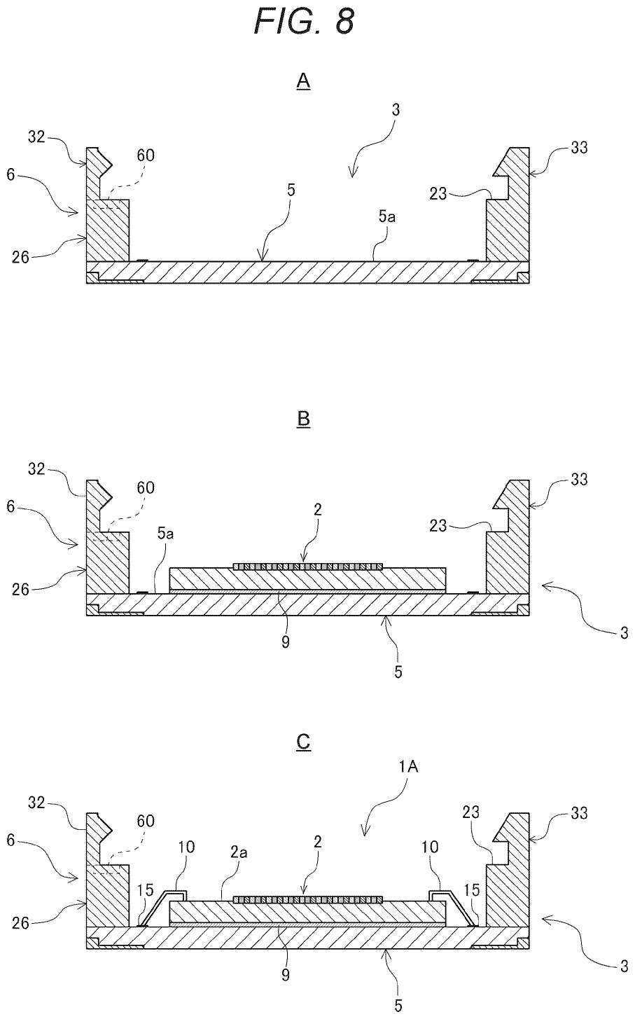

On the other hand, as illustrated in FIG. 8A, the step of manufacturing the package main body portion 3 is performed. In this process, frame mounting in which the frame 6 is provided on the substrate 5 is performed. In the frame mounting process, the frame 6 including the step forming portion 31, the clip portions 32, the hook portions 33, and the recess 60 is prepared in advance by, for example, injection molding using a resin material such as epoxy resin. The frame 6 is fixed to a predetermined portion of the surface 5a of the substrate 5 by an adhesive such as an epoxy resin adhesive. As a result of this process, the package main body portion 3 having a configuration in which the frame 6 is set on the substrate 5 is obtained.

Next, as illustrated in FIG. 8B, the step of setting the image sensor 2 obtained as a result of the dicing process on the substrate 5 is performed. That is, die bonding for die-bonding the image sensor 2 to the substrate 5 is performed. In this process, the image sensor 2 is bonded and fixed to a predetermined mounting portion on the surface 5a of the substrate 5 by the die bonding material 9, which is an adhesive such as an insulating or conductive resin paste.

Next, as illustrated in FIG. 8C, the step of setting the wire 10 that electrically connects the substrate 5 and the image sensor 2 is performed. Here, wire bonding of electrically connecting the electrode 15 of the substrate 5 and the electrode formed on the front surface 2a of the image sensor 2 using the wire 10 is performed.

Through the above process, an image sensor unit 1A as a solid-state imaging device having a configuration in which the image sensor 2 is mounted on the package main body portion 3 is obtained. The step of attaching the cover glass 4 to the image sensor unit 1A is performed. Note that the cover glass 4 is prepared by cutting a glass plate having a predetermined shape into a rectangular shape by dicing.

FIG. 9 is an explanatory diagram of the step of attaching the cover glass 4. In the attachment of the cover glass 4, first, the cover glass 4 is placed in the following attachment set state relative to the clip portions 32 and the hook portions 33. That is, as illustrated in FIG. 9A, the cover glass 4 is placed in a state in which an edge portion on one side (the right side in FIG. 9A) in the X direction is fitted into the recess 50 formed by the hook portions 33, and an edge portion on the other side (the left side in FIG. 9A) in the X direction is brought into contact with the clip portions 32. In this state, the lower corner of the cover glass 4 with respect to the clip portions 32 is brought into contact with the upper inclined surface 47.

From the attachment set state of the cover glass 4 illustrated in FIG. 9A, as illustrated in FIG. 9B, a force is applied to press the cover glass 4 toward the side corresponding to the frame 6 (lower side) (see arrow C1). Here, the pressing force to the cover glass 4 is applied so as to mainly act on, for example, a portion of the cover glass 4 on the contact side with the clip portions 32. The clip portions 32 receiving a downward force from the cover glass 4 elastically deform so as to widen the distance to the hook portions 33 while allowing the corner of the cover glass 4 being pushed down to slide on the upper inclined surface 47 (see arrow C2). That is, the clip portions 32 are bent so as to warp the support columns 41 outward.

Then, when the cover glass 4, with the side that is in contact with the clip portions 32 moved downward, reaches a position beyond the retaining protrusion 42 relative to the clip portions 32, that is, when the upper surface 4a is positioned below the ridge portions 49 of the clip portions 32, the clip portions 32 return from the elastically deformed state. As a result, as illustrated in FIG. 9C, the clip portions 32 returns to the original natural state (see the arrow C3), and a state in which the cover glass 4 is supported on the glass support surface 23 is obtained. That is, a state is obtained in which the cover glass 4 is supported on the glass support surface 23 and is fitted between the pair of step forming portions 31, the clip portions 32, and the hook portions 33, and is retained and fixed to the frame main body portion 26 by these cover fixing portions.

By attaching the cover glass 4 as described above, the solid-state imaging device 1 is obtained. In the solid-state imaging device 1, an adhesive is not used to fix the cover glass 4, and the cover glass 4 is temporarily fixed to the frame 6. Note that in the example of the manufacturing method described above, die bonding and wire bonding are performed on the substrate 5 after the frame mounting process is performed on the substrate 5, but the order of these processes may be reversed. That is, the step of die bonding and wire bonding may be performed first, and then the step of frame mounting on the substrate 5 may be performed.

### 3. Use Example of Solid-State Imaging Device According to First Embodiment

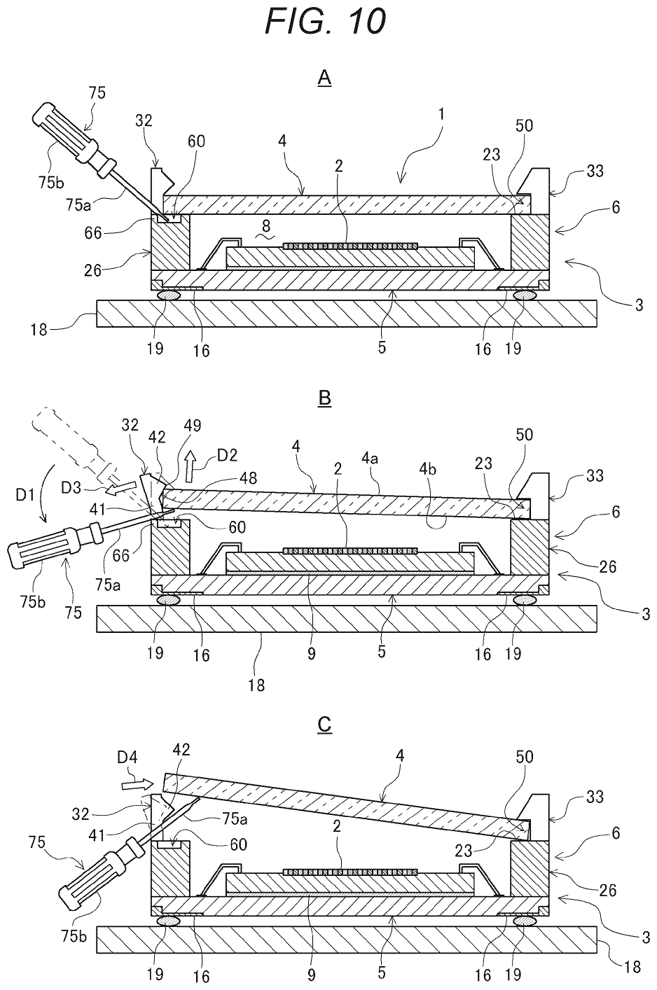

As a use example of the solid-state imaging device 1 according to the first embodiment of the present technology, how to remove the cover glass 4 will be described with reference to FIG. 10.

In a state in which the cover glass 4 is attached to the package main body portion 3, the solid-state imaging device 1 receives an inspection for imaging by the image sensor 2, is transported as a product, or is mounted on a set substrate. Furthermore, the cover glass 4 serves as a member for obtaining good handleability of the solid-state imaging device 1 during the step of mounting a lens unit on the solid-state imaging device 1 or the like, or for preventing foreign matter from entering the inside of the package of the solid-state imaging device 1, for example.

On the other hand, for example, when the solid-state imaging device 1 is incorporated into a predetermined set structure forming an electronic device such as a camera device, the cover glass 4 is removed from the package main body portion 3. That is, as one mode of use of the solid-state imaging device 1, the solid-state imaging device 1 is used with the cover glass 4, which is once attached to the package main body portion 3, removed.

For example, as illustrated in FIG. 10A, the cover glass 4 is removed with the solid-state imaging device 1 installed by reflow soldering on a set substrate 18 that is a circuit board having a predetermined circuit structure. The solid-state imaging device 1 is electrically connected to the set substrate 18 by connecting the terminal electrode 16 to the electrode portion provided on the front surface side of the set substrate 18 by the solder ball 19.

As illustrated in FIG. 10A, the cover glass 4 is removed using a tool 75 such as a precision flathead screwdriver. The tool 75 includes a shaft portion 75a and a grip portion 75b which are main body portions. The tip portion of the shaft portion 75a is inserted into the recess 60, and the cover glass 4 is removed with the tool 75 using the principle of leverage. Details are as follows.

As shown in FIG. 10A, first, the tip portion of the shaft portion 75a of the tool 75 is inserted into the recess 60 of the frame 6 through the exposed portion 60a (see FIG. 1). Here, the tool 75 is inserted obliquely downward from the outside to the inside in the X direction relative to the recess 60.

As shown in FIG. 10B, by operating the tool 75 so as to push down the side corresponding to the grip portion 75b from the state shown in FIG. 10A (see arrow D1), the tool 75 acts to lift the cover glass 4 with its tip portion in contact with the lower surface 4b of the cover glass 4 (see arrow D2). That is, by pushing down the side corresponding to the grip portion 75b of the tool 75, the tip end side of the tool 75 is raised by the principle of leverage with the contact portion of the shaft portion 75a with the edge wall portion 66 on the outer side of the recess 60 as a fulcrum, and the cover glass 4 receives a force to be pushed from the lower side. The cover glass 4 lifted by the tool 75 presses the retaining protrusions 42 of the clip portions 32 from below.

The clip portions 32 receiving the upward force from the cover glass 4 elastically deform so as to widen the distance to the hook portions 33 while allowing the corner of the cover glass 4, which is pushed upward, to slide on the lower inclined surface 48 (see arrow D3). That is, the clip portions 32 are bent so as to warp the support columns 41 outward.

Then, when the cover glass 4, with the side that is in contact with the clip portions 32 moved upward, reaches a position beyond the retaining protrusions 42 relative to the clip portions 32, that is, when the lower surface 4b is positioned above the ridge portions 49 of the clip portions 32, the clip portions 32 return from the elastically deformed state. As a result, as illustrated in FIG. 10C, the clip portions 32 return to the original natural state (see arrow D4), and a state in which the engagement of the cover glass 4 with the clip portions 32 is released is obtained. From this state, the fitting portion of the cover glass 4 with respect to the recesses 50 of the hook portions 33 is pulled out, whereby the cover glass 4 is removed from the frame 6.

As described above, a configuration in which the image sensor unit 1A (see FIG. 8C) is mounted on the set substrate 18 is obtained.

According to the solid-state imaging device 1 according to the present embodiment as described above, it is possible to obtain the attached state of the cover glass 4 in order to obtain good handleability of the solid-state imaging device 1 and to prevent foreign matter from entering the inside of the package, and it is possible to easily remove the cover glass 4 in order to solve problems such as ghost and flare caused by the presence of the cover glass 4.

That is, according to the configuration including the cover holding portion that detachably holds the cover glass 4 relative to the frame 6, the cover glass 4 can be easily removed, for example, when the lens housing is installed in the solid-state imaging device 1 by a set manufacturer without relying on a specialist. As a result, it is possible to prevent occurrence of a defect such as flare due to the cover glass 4 and to secure the function of the image sensor 2. Additionally, when the solid-state imaging device 1 is mounted on the set substrate 18, by attaching the cover glass 4, it is possible to obtain good handleability and prevent foreign matter from entering the inside of the package. As described above, with the solid-state imaging device 1, it is possible to implement an image sensor package in which the cover glass 4 is easily attached and detached.

The solid-state imaging device 1 includes, as the cover holding portion, the cover fixing portion 30 that fixes the cover glass 4 to the frame 6 by restricting movement of the cover glass 4 supported on the glass support surface 23 relative to the frame main body portion 26. According to such a configuration, the cover glass 4 can be fixed without applying an adhesive to the glass support surface 23 for placing and supporting the cover glass 4. As a result, it is not necessary to forcibly peel off the bonding portion, and the cover glass 4 can be easily removed.

Additionally, since an adhesive does not remain on the glass support surface 23, for example, it is possible to prevent an adhesive from adhering to the image sensor 2 inside the package as dust after the image sensor unit 1A is incorporated into the set. This prevents the imaging surface of the image sensor 2 from being contaminated, so that it is possible to secure the performance of the image sensor 2. Additionally, since an adhesive is not used to fix the cover glass 4, it is possible to prevent the image sensor 2 from being contaminated by outgas generated from the organic material contained in an adhesive, and the performance of the image sensor 2 can be secured.

Furthermore, since the cover glass 4 detached from the frame 6 is free of an adhesive or the like adhering to it, the cover glass 4 can be appropriately cleaned and reused. This makes it possible to reduce the material cost.

Additionally, since an adhesive is not applied to the glass support surface 23, no residue of an adhesive is present on the glass support surface 23 in a state in which the cover glass 4 is removed, and the glass support surface 23 can be maintained in a clean state. As a result, in the image sensor unit 1A in a state in which the cover glass 4 is removed, the glass support surface 23 can be used as, for example, a joint surface to be joined to a housing or the like of the set structure, a guide plane used in tilt adjustment (adjustment of the tilt of the imaging surface) when the image sensor unit 1A is attached to the set structure, or a joint surface of a new component to be joined to the package main body portion 3.

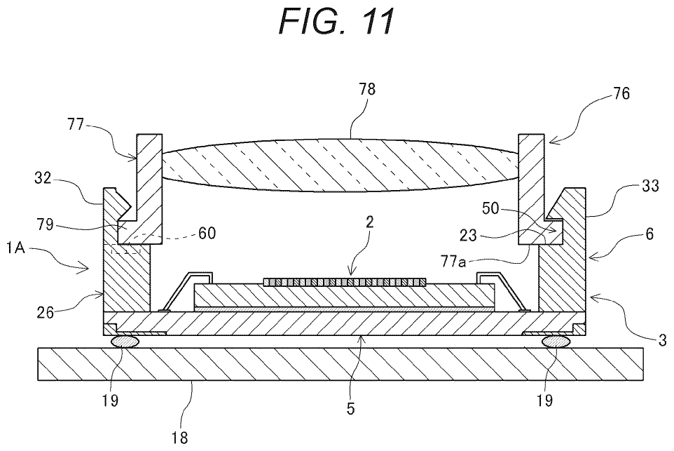

For example, as illustrated in FIG. 11, the glass support surface 23 in the image sensor unit 1A is used as a support surface for a lens housing 76 mounted on the image sensor unit 1A. The lens housing 76 has a support cylinder 77 formed in a cylindrical shape, and supports one or more lenses 78 in the support cylinder 77. The lens housing 76 is provided such that the lens 78 is positioned above the image sensor 2 in an orientation with which the optical axis is in the up-down direction relative to the frame 6. According to the configuration in which the lens housing 76 is installed in the image sensor unit 1A, the light condensed by the lens 78 is incident on the light receiving surface of the image sensor 2.

The lens housing 76 is provided in a state in which the support cylinder 77 is fixed to the frame 6 by the pair of step forming portions 31, the clip portions 32, and the hook portions 33. The lens housing 76 has a flange portion 79 at a lower end portion of the support cylinder 77 in order to receive an engagement action by the pair of step forming portions 31, the clip portion 32, and the hook portion 33. The flange portion 79 is formed so that the shape, dimension, and thickness (dimension in the up-down direction) of the outer shape in plan view are substantially the same as those of the cover glass 4.

The lens housing 76 is fixed to the frame 6 by engaging the flange portion 79 of the support cylinder 77 with the pair of step forming portions 31, the clip portions 32, and the hook portions 33 in the same manner as the cover glass 4. That is, the lens housing 76 is attached to the frame 6 by fitting the edge portion on one side (the right side in FIG. 11) in the X direction of the flange portion 79 into the recesses 50 of the hook portions 33 and retaining the edge portion on the other side in the X direction of the flange portion 79 to the clip portions 32 along with the temporary elastic deformation of the clip portions 32 as described above. In a state in which the lens housing 76 is attached to the frame 6, the lens housing 76 is supported on the frame main body portion 26 with the bottom surface 77a, which is the lower surface of the flange portion 79 and the lower opening end surface of the support cylinder 77, as a contact surface with the glass support surface 23.

As described above, when the lens housing 76 is installed on the image sensor unit 1A in a state in which the cover glass 4 is removed, the glass support surface 23 is used as a support surface for the lens housing 76, and the step forming portions 31, the clip portions 32, and the hook portions 33 provided in the frame 6 can be used to fix the lens housing 76 to the frame 6.

According to such a configuration, for example, as compared with a case where the lens housing 76 is installed on the set substrate 18 to which the image sensor unit 1A is solder-connected by the solder ball 19, the lens housing 76 can be installed on the glass support surface 23 on the package side where the accuracy regarding the optical axis adjustment of the image sensor 2 can be relatively easily obtained. As a result, the glass support surface 23 can be used as a reference surface, and the lens housing 76 can be accurately provided relative to the image sensor 2 without being affected by inclination due to solder connection to the set substrate 18. Note that the lens housing 76 may be installed with respect to the set substrate 18.

Also, the frame 6 includes, as the cover fixing portion, a pair of step forming portions 31 and retaining portions (32, 33) provided to face each other. According to such a configuration, the cover glass 4 can be easily detachably fixed to and held by the frame 6 with a simple configuration. By providing the pair of step forming portions 31 in addition to the retaining portions (32, 33), lateral displacement in the Y direction of the cover glass 4, which is held by the retaining portions (32, 33), relative to the frame main body portion 26 can be prevented by the pair of step forming portions 31, and the cover glass 4 can be efficiently fixed.

The frame 6 includes the clip portions 32 and the hook portions 33 as retaining portions. According to such a configuration, the cover glass 4 can be easily attached to and detached from the frame 6 by utilizing the elastic deformation of the clip portions 32. In particular, according to the retaining structure in which the retaining portions acting on one side of the cover glass 4 are the clip portions 32 and the retaining portions acting on the opposite side are the hook portions 33, it is possible to suppress the force acting on the cover glass 4 at the time of attaching and detaching the cover glass 4, allowing the cover glass 4 to be efficiently attached and detached.

In addition, the frame 6 has the recess 60 opening portion at the glass support surface 23. According to such a configuration, when the cover glass 4 is removed using the tool 75, the tool 75 can easily act on the cover glass 4, and the cover glass 4 can be easily removed. In the tool 75, by covering the contact portion with the cover glass 4 with resin or the like, generation of dust or particles due to contact between the tool 75 and the cover glass 4 can be suppressed. Note that as the tool 75, a dedicated tool for removing the cover glass 4 may be used.

Furthermore, according to the fixing structure of the cover glass 4 according to the present embodiment, since the cover glass 4 does not hermetically seal the opening portion 25 of the frame 6, it is possible to suppress an increase in stress accompanying an increase in the internal pressure of the cavity 8 of the package at the time of reflow or the like in mounting the solid-state imaging device 1 on the set substrate. As a result, deformation such as warpage of the package due to reflow mounting, cracks of the cover glass 4, disconnection of the wire 10, and the like can be suppressed.

### 4. Modification of Solid-State Imaging Device According to First Embodiment

Modifications of the solid-state imaging device 1 according to the first embodiment of the present technology will be described.

### First Modification

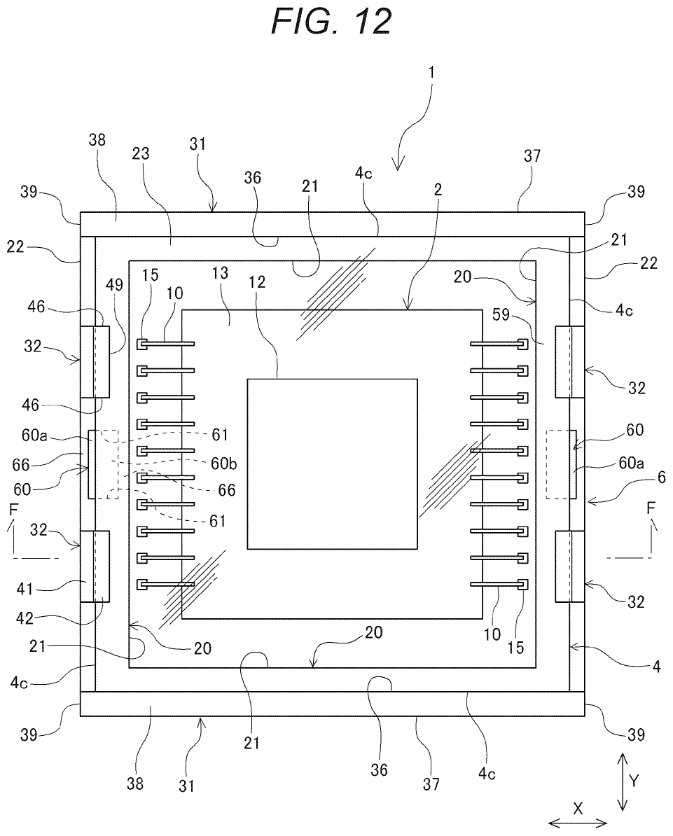

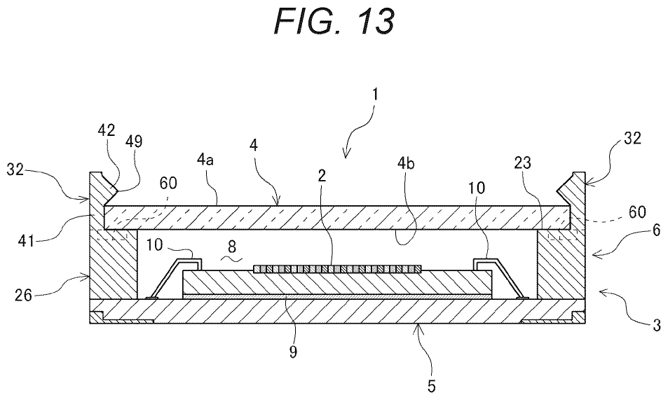

As illustrated in FIGS. 12 and 13, a solid-state imaging device 1 of a first modification includes clip portions 32 instead of the two hook portions 33 provided on the right wall portion 20 of the frame main body portion 26, and a recess 60 between these clip portions 32. That is, the solid-state imaging device 1 of the first modification includes the clip portions 32 and the recess 60 on each of two sides facing each other in the X direction in the frame main body portion 26.

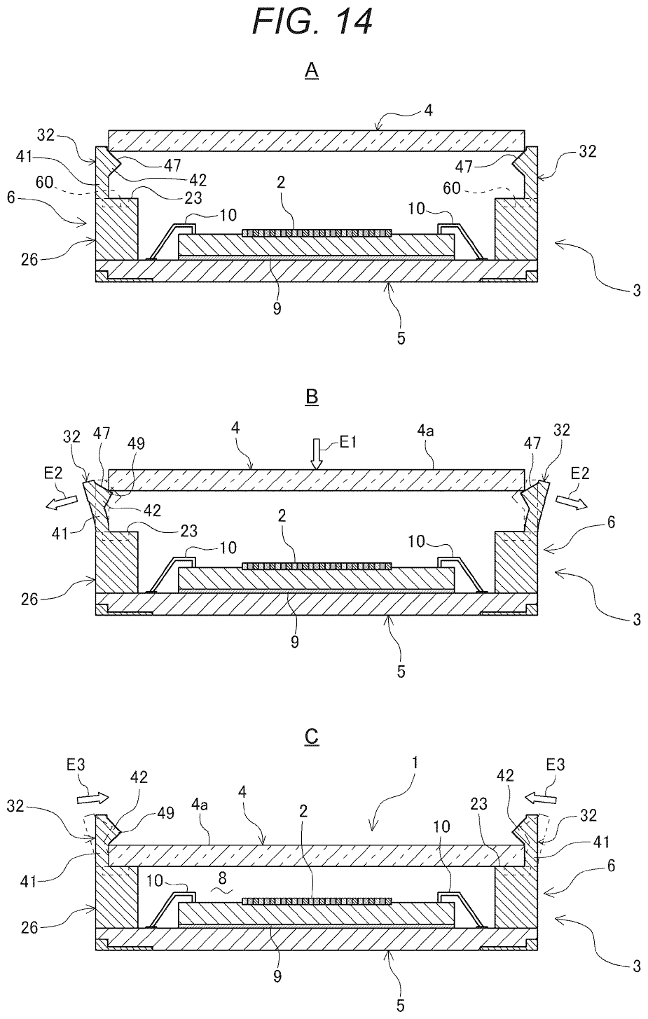

The step of attaching the cover glass 4 in a method for manufacturing the solid-state imaging device 1 according to the first modification will be described with reference to FIG. 14. In the attachment of the cover glass 4, first, the cover glass 4 is placed in the following attachment set state relative to the clip portions 32 on both left and right sides. That is, as illustrated in FIG. 14A, the cover glass 4 is brought into a state in which the edge portions on both sides in the X direction are in contact with the clip portions 32. In this state, the lower corners of the left and right edge portions of the cover glass 4 are brought into contact with the upper inclined surfaces 47 of the clip portions 32.

From the attachment set state of the cover glass 4 illustrated in FIG. 14A, as illustrated in FIG. 14B, a force for pressing the cover glass 4 toward the side corresponding to the frame 6 (lower side) is applied (see arrow E1). The left and right clip portions 32 receiving a downward force from the cover glass 4 elastically deform so as to widen a distance therebetween while allowing the corners of the cover glass 4 being pushed down to slide on the upper inclined surfaces 47 (see arrow E2).

Then, when the cover glass 4, with the side that is in contact with the clip portions 32 moved downward, reaches a position beyond the retaining protrusion 42 relative to the clip portions 32, the clip portions 32 returns from the elastically deformed state. As a result, as illustrated in FIG. 14C, the left and right clip portions 32 return to the original natural state (see arrow E3), and a state in which the cover glass 4 is supported on the glass support surface 23 is obtained. That is, a state is obtained in which the cover glass 4 is supported on the glass support surface 23 and is fitted between the pair of step forming portions 31 and the left and right clip portions 32, and is retained and fixed to the frame main body portion 26 by these cover fixing portions. The cover glass 4 is attached as described above, and the solid-state imaging device 1 is obtained.

In the removal of the cover glass 4 in the solid-state imaging device 1 of the first modification, the recesses 60 formed in the left and right wall portions 20 of the frame main body portion 26 are used by the tool 75 as illustrated in FIG. 10A, and the engagement state of the clip portions 32 is released for the left and right edge portions of the cover glass 4 at the same time or for each of the left and right edge portions. Here, the clip portions 32 release the engagement of the cover glass 4 with the temporary elastic deformation that warps the support columns 41 outward as described above.

According to the configuration of the first modification, as compared with the retaining structure of the cover glass 4 by the clip portions 32 and the hook portions 33 as described above, the cover glass 4 can be firmly fixed and held relative to the frame 6 by the clip portions 32 on both right and left sides. That is, a relatively stable attachment state of the cover glass 4 can be obtained.

Also, according to the configuration of the first modification, in the step of attaching the cover glass 4 to the frame 6, the operation direction of the cover glass 4 to the frame 6 can be only in one direction (downward). Thus, the cover glass 4 can be easily attached to the frame 6 by a relatively simple operation. The simple operation at the time of attaching the cover glass 4 is advantageous, for example, in a case where the attachment of the cover glass 4 is automatically performed by a mechanical device.

### Second Modification

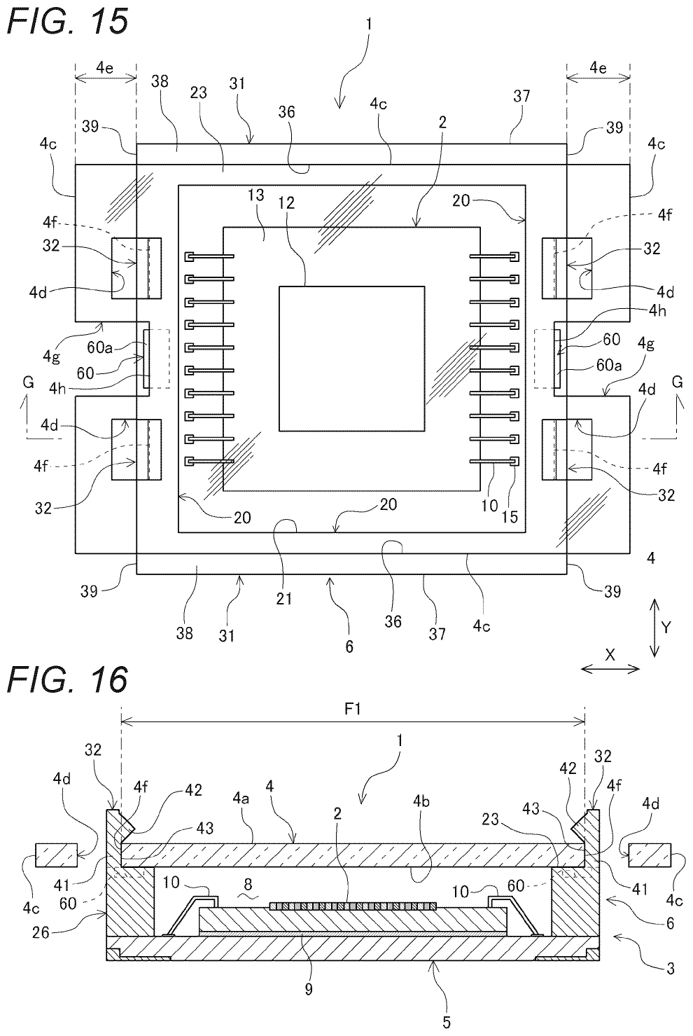

As illustrated in FIGS. 15 and 16, a solid-state imaging device 1 according to a second modification includes the clip portions 32 on the left and right sides as in the first modification, and fixes the cover glass 4 to the frame 6 in a state in which the clip portions 32 extend through holes 4d formed in the cover glass 4.

In the second modification, the cover glass 4 has a larger size than the frame main body portion 26 of the frame 6 in the X direction, and both left and right sides thereof project from the frame 6. That is, the cover glass 4 includes projecting portions 4e projecting to the outer side in the left-right direction from the outer shape of the glass support surface 23 of the frame 6 in plan view.

The cover glass 4 has four holes 4d corresponding to the four clip portions 32. Each hole 4d has a rectangular opening shape along the outer shape of the cover glass 4. The hole 4d corresponds to the outer dimension of the clip portion 32 in plan view, and has an opening dimension allowing the clip portion 32 to extend therethrough. In the example illustrated in FIG. 15, the hole 4d has substantially the same dimension as the clip portion 32 in the Y direction. Additionally, the hole 4d of the cover glass 4 has an opening dimension that does not interfere with the movable range of the elastic deformation of the clip portion 32 so as to allow the elastic deformation of the clip portions 32 when the cover glass 4 is attached to or detached from the frame 6 in the X direction.

In the cover glass 4, a portion between each pair of holes 4d facing each other in the X direction is a portion positioned between the left and right clip portions 32. Therefore, the pair of holes 4d that are opposed to each other in the X direction are formed such that the dimension F1 between the left and right inner side surfaces 4f is substantially the same as the dimension between the inner side surfaces 43 of the clip portions 32 on the left and right sides.

Additionally, the cover glass 4 has cutout portions 4g as shape portions for exposing the recesses 60 for removing the cover glass 4 formed in the glass support surface 23 at the edge portions on both the left and right sides. In the example shown in FIG. 15, the cutout portions 4g have a recessed shape with the outer side in the left-right direction as open sides in plan view, and are formed such that the left and right inner side surfaces 4h are at positions where the exposed portions 60a appear in the recesses 60. Note that, the shape of the portions of the cover glass 4 for exposing the recesses 60 is not limited.

In the second modification, the holes 4d and the cutout portions 4g of the cover glass 4 are formed by cutting a glass plate with a predetermined tool such as a dicing blade, a method using etching, or the like, for example.

As in the second modification, in the configuration having the clip portions 32 on both the left and right sides, it is possible to adopt a configuration in which holes 4d are formed to extend through the left and right edge portions of the cover glass 4, and the holes 4d serve as retaining holes for the clip portions 32. According to such a configuration, for example, the projecting portions 4e of the cover glass 4 can be used to obtain good handleability of the solid-state imaging device 1.

### Other Modifications

Other modifications of the solid-state imaging device 1 according to the present embodiment include the following configurations.

The step forming portions 31, the clip portions 32, and the hook portions 33 of the frame 6 may be portions provided by attaching separate members to the members forming the frame main body portion 26. In the case of such a configuration, the members forming the step forming portions 31 and the like are fixed to the members forming the frame main body portion 26 by a mechanical coupling structure such as fitting or insertion, bonding with an adhesive, or the like. According to the configuration in which the step forming portions 31 and the like are formed as separate members, for example, when the frame 6 is formed by resin molding using a mold, molding for each component can be performed, so that molding can be performed relatively easily.

Additionally, the formation sites and the number of the step forming portions 31, the clip portions 32, the hook portions 33, and the recesses 60 are not particularly limited. For example, the clip portions 32 and the hook portions 33 may be provided at one position, or may be provided at three or more positions. At least one of the clip portions 32 and the hook portions 33 may be provided on the wall portions 20 on all the four sides. Furthermore, the recesses 60 may be formed at two or more positions in the wall portions 20 where the clip portions 32 are provided.

### 5. Configuration Example of Solid-State Imaging Device According to Second Embodiment

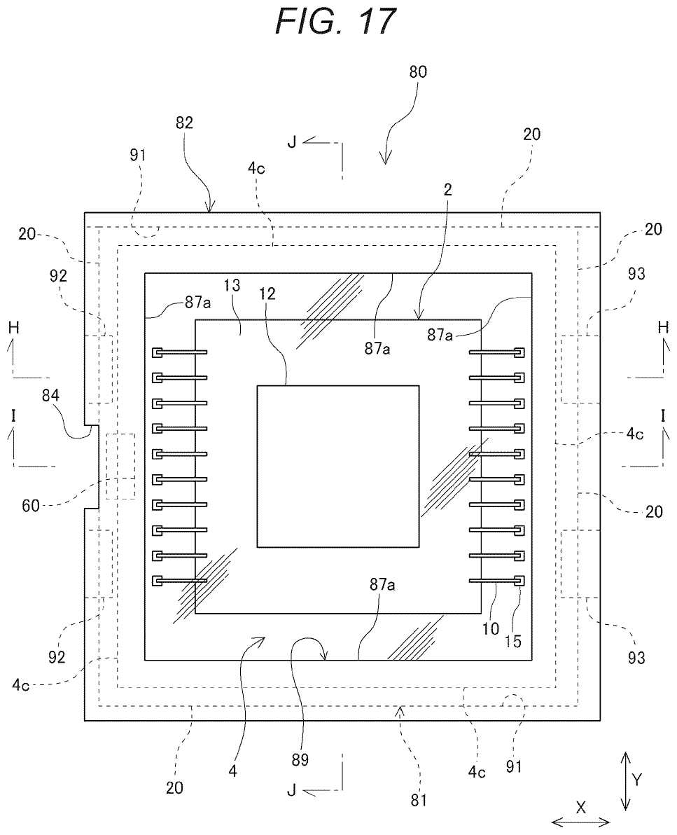

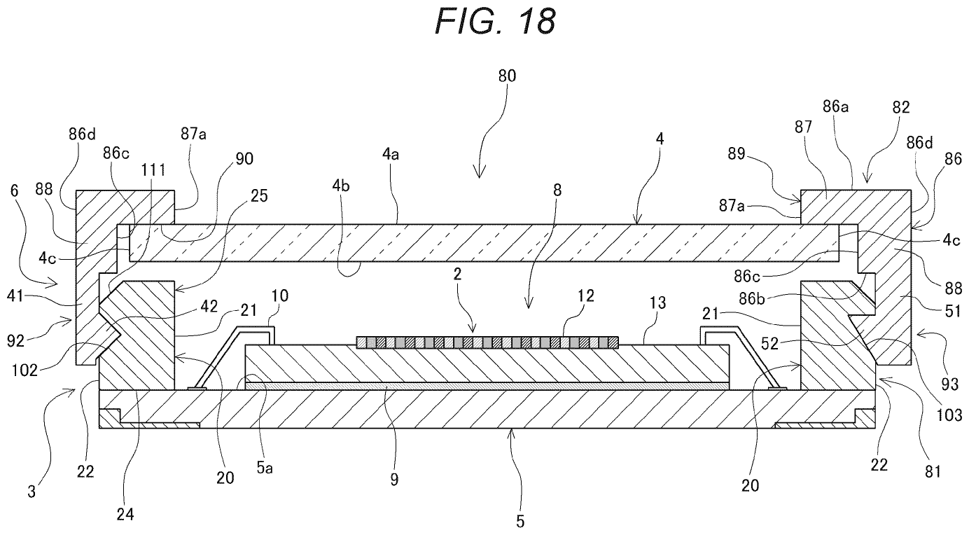

A configuration example of a solid-state imaging device 80 according to a second embodiment of the present technology will be described with reference to FIGS. 17 to 21. In each embodiment to be described below, the same names or the same reference numerals are used for components common to or corresponding to components of the embodiment described above, and the description of the components will be omitted as appropriate.

A solid-state imaging device 80 according to the present embodiment is different from the solid-state imaging device 1 according to the first embodiment in the configuration of the frame 6 that supports the cover glass 4 relative to the substrate 5. In the present embodiment, the configuration corresponding to the clip portions 32 and the hook portions 33 according to the first embodiment is provided on the side corresponding to the cover glass 4, which is to be attached to and detached from the configuration on the side corresponding to the substrate 5, as a part of the frame 6.

As illustrated in FIGS. 17 to 21, the frame 6 according to the present embodiment includes a substrate-side frame 81, which is a first frame portion fixed to the substrate 5, and a glass-side frame 82, which is a second frame portion forming a cover holding portion and detachably attached to the substrate-side frame 81. That is, the solid-state imaging device 80 includes the glass-side frame 82 as a cover holding portion that detachably holds the cover glass 4 relative to the substrate-side frame 81 that is a part of the frame 6.

As described above, the frame 6 according to the present embodiment has a divided structure including the substrate-side frame 81, which is a frame main body portion forming the package main body portion 3 together with the substrate 5, and the glass-side frame 82, which is a glass support portion supporting the cover glass 4. The substrate-side frame 81 and the glass-side frame 82 may be members including the same material or may be members including different materials.

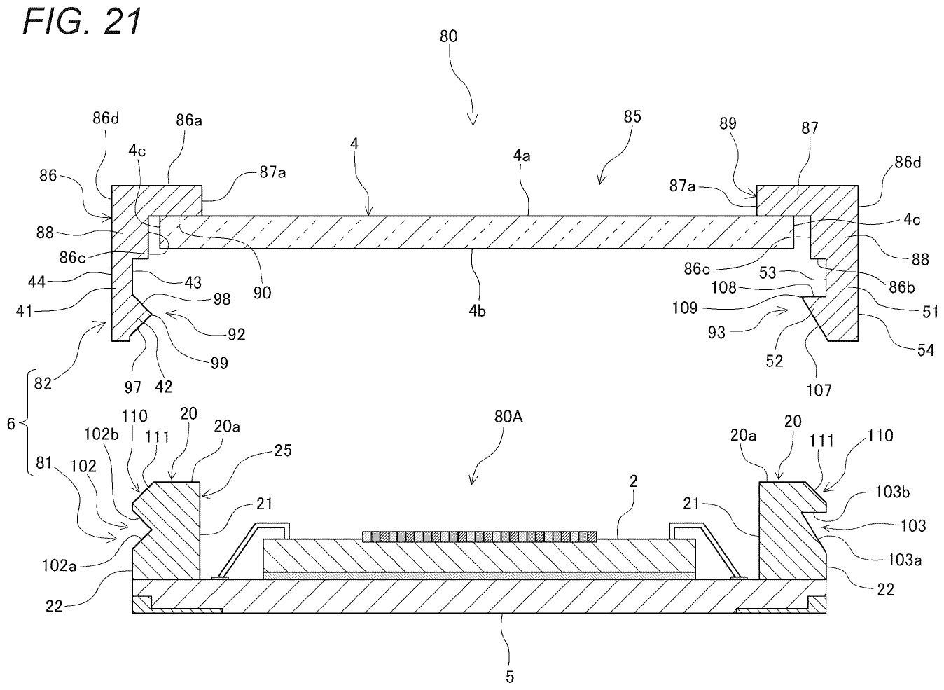

The glass-side frame 82 and the cover glass 4 form a lid body 85 detachably attached to the image sensor unit 80A including the image sensor 2, the substrate 5, and the substrate-side frame 81 (see FIG. 21). The glass-side frame 82 includes clip portions 92 and hook portions 93.

The substrate-side frame 81 is now described. The substrate-side frame 81 is a portion having substantially the same configuration as the frame main body portion 26 according to the first embodiment. The substrate-side frame 81 includes four wall portions 20 forming an opening portion 25, and these wall portions 20 form a frame-shaped frame portion on the substrate 5. The substrate-side frame 81 is fixed to the substrate 5 by an adhesive with a lower surface 24, which is a surface perpendicular to the up-down direction, as a bonding surface to the surface 5a of the substrate 5.

The glass-side frame 82 is now described. The glass-side frame 82 includes a frame-shaped main body portion 86, which is a frame-shaped main body portion that holds the cover glass 4, and clip portions 92 and hook portions 93, which are provided in the frame-shaped main body portion 86 and serve as engagement portions that engage with the substrate-side frame 81 to hold the glass-side frame 82 to the substrate-side frame 81. The glass-side frame 82 includes the clip portions 92 as first engagement portions and the hook portions 93 as second engagement portions as engagement portions for engaging with the substrate-side frame 81.

The frame-shaped main body portion 86 is a member having a rectangular outer shape in plan view, and has an outer dimension larger than the outer shape of the substrate-side frame 81 in plan view. The frame-shaped main body portion 86 includes a plate-shaped base portion 87, which is a horizontal plate-shaped portion, and four outer edge protrusions 88, which are portions formed along the outer edge of the plate-shaped base portion 87 and protruding downward. The frame-shaped main body portion 86 has a transverse cross-sectional shape substantially having the shape of letter “L” at each side portion forming the frame shape formed by the plate-shaped base portion 87 and the outer edge protrusion 88.

The frame-shaped main body portion 86 has an upper surface 86a and a lower surface 86b, which are both horizontal planes. The upper surface 86a is an upper surface of the plate-shaped base portion 87, and the lower surface 86b is a lower surface of the four outer edge protrusions 88. Additionally, the frame-shaped main body portion 86 has four inner side surfaces 86c and four outer side surfaces 86d formed perpendicular to the upper surface 86a and the lower surface 86b at each side portion forming a frame shape. The inner side surfaces 86c are inner side surfaces of the outer edge protrusions 88.

The frame-shaped main body portion 86 has an opening portion 89 for securing a passage for light received by the image sensor 2. The opening portion 89 is a rectangular hole extending through the plate-shaped base portion 87 in the plate thickness direction. The opening portion 89 has an opening dimension smaller than the outer dimension of the cover glass 4. In the illustrated example, the opening portion 89 has substantially the same opening dimension as the opening portion 25 of the substrate-side frame 81. The opening portion 89 is formed by an inner side surface 87a of the plate-shaped base portion 87. Note that the opening portion 89 only needs to be formed so as to include the entire pixel region 12 of the image sensor 2 in the opening region in plan view, and the opening shape and the opening dimension of the opening portion 89 are not limited.

In the glass-side frame 82, the horizontal lower surface of the plate-shaped base portion 87, which is a surface on the opposite side of the upper surface 86a of the frame-shaped main body portion 86, serves as a glass attachment surface 90 to which the cover glass 4 is attached. The glass attachment surface 90 is a stepped surface located on the upper side of the lower surface 86b of the frame-shaped main body portion 86, and is a surface where the lower side of the opening portion 89 is located. The cover glass 4 is fixed to the glass attachment surface 90 with an adhesive such as an ultraviolet (UV) curable resin so as to cover the entire opening portion 89 from below. The left and right side surfaces 4c of the cover glass 4 face the inner side surface 86c of the frame-shaped main body portion 86.

The clip portions 92 and the hook portions 93 are provided below the frame-shaped main body portion 86 as described above. The clip portions 92 and the hook portions 93 are portions having the same shape and dimension as those of the clip portions 32 and the hook portions 33 according to the first embodiment, respectively, and are provided as shape portions in which the clip portions 32 and the hook portion 33 are turned upside down. Furthermore, the clip portions 92 and the hook portions 93 are provided as protruding portions from the lower surface 86b of the frame-shaped main body portion 86 in a similar manner as the clip portions 32 and the hook portions 33 provided as protruding portions from the glass support surface 23 of the frame main body portion 26 in the first embodiment. Therefore, in the description of the clip portions 92 and the hook portions 93, portions corresponding to the clip portions 32 and the hook portions 33 according to the first embodiment are denoted by the same reference numerals, and the description thereof will be omitted as appropriate.

The clip portions 92 and the hook portions 93 are provided in the frame-shaped main body portion 86 at a pair of outer edge protrusions 88 facing each other, and two pairs are provided so as to face each other.

Each clip portion 92 includes a support column 41 protruding from the lower surface 86b and a retaining protrusion 42 formed at the lower part of the support column 41 (see FIG. 21). The clip portion 92 is formed such that the outer side surface 44 is located on the same plane as the outer side surface 86d of the frame-shaped main body portion 86.

As shown in FIG. 21, each retaining protrusion 42 has a lower inclined surface 97 inclined in a direction from the lower side to the upper side from the outer side to the inner side in the left-right direction as a surface corresponding to the upper inclined surface 47 of the clip portion 32 according to the first embodiment. The retaining protrusion 42 has an upper inclined surface 98 that is inclined downward from the outside to the inside in the left-right direction as a surface corresponding to the lower inclined surface 48 of the clip portion 32 according to the first embodiment. The lower inclined surface 97 and the upper inclined surface 98 form a ridge portion 99 in the Y direction as an end portion on the protruding side of the retaining protrusion 42.

Each hook portion 93 includes a support column 51 protruding from the lower surface 86b and a retaining protrusion 52 formed at the lower part of the support column 51 (see FIG. 21). The hook portion 33 is formed such that the outer side surface 54 is located on the same plane as the outer side surface 86d of the frame-shaped main body portion 86.

As shown in FIG. 21, the retaining protrusion 52 has a lower inclined surface 107 inclined in a direction from the lower side to the upper side from the outer side to the inner side in the left-right direction as a surface corresponding to the upper inclined surface 57 of the hook portion 33 according to the first embodiment. Additionally, the retaining protrusion 52 has a horizontal retaining surface 108, which is located below the lower surface 86b of the frame-shaped main body portion 86 and faces the lower surface 86b, as a surface corresponding to the retaining surface 58 of the hook portion 33 according to the first embodiment. The lower inclined surface 107 and the retaining surface 108 form a ridge portion 109 in the Y direction as an end portion on the protruding side of the retaining protrusion 52.

The glass-side frame 82 is fixed to the substrate-side frame 81 in such a manner that the substrate-side frame 81 is held between the clip portions 92 and the hook portions 93 by engaging the clip portions 92 and the hook portions 93 with the outer side of the substrate-side frame 81. Therefore, the clip portions 92 and the hook portions 93 are set such that the dimension between the inner side surfaces 43 and 53 facing each other is substantially the same as or slightly larger than the dimension of the substrate-side frame 81 in the X direction.

On the side of the substrate-side frame 81, engagement recesses 102, 103, which are engaged portions that are individually engaged by the clip portions 92 and the hook portions 93, are formed. The engagement recesses 102 and 103 are formed as recessed portions having a shape corresponding to the retaining protrusions 42 and 52 of the clip portions 92 and the hook portions 93, respectively, at vertical intermediate portions of the outer wall surfaces 22 of the left and right wall portions 20.

Each engagement recess 102 for the clip portion that is engaged by the clip portion 92 is formed as a V-shaped recess by slope portions 102a and 102b corresponding to the lower inclined surface 97 and the upper inclined surface 98, respectively, of the retaining protrusion 42. The engagement recess 102 is formed to have a size that allows the entire retaining protrusion 42 or substantially the entire retaining protrusion to be fitted. Each engagement recess 103 for the hook portion that is engaged by the hook portion 93 is formed as a substantially V-shaped recess by a slope portion 103a and the locking surface 103b corresponding to the lower inclined surface 107 and the retaining surface 108, respectively, of the retaining protrusion 52. The engagement recess 103 is formed to have a size that allows the entire retaining protrusion 52 or substantially the entire retaining protrusion to be fitted.

The engagement recesses 102 and 103 are formed in a range corresponding to at least a portion where the clip portions 92 and the hook portions 93 are formed in the Y direction. The engagement recesses 102 and 103 have substantially the same dimension in the Y direction as the clip portions 92 and the hook portions 93, so that the clip portions 92 and the hook portions 93 can be positioned in the Y direction relative to the engagement recesses 102 and 103, and the action of positioning the glass-side frame 82 in the Y direction relative to the substrate-side frame 81 can be achieved.

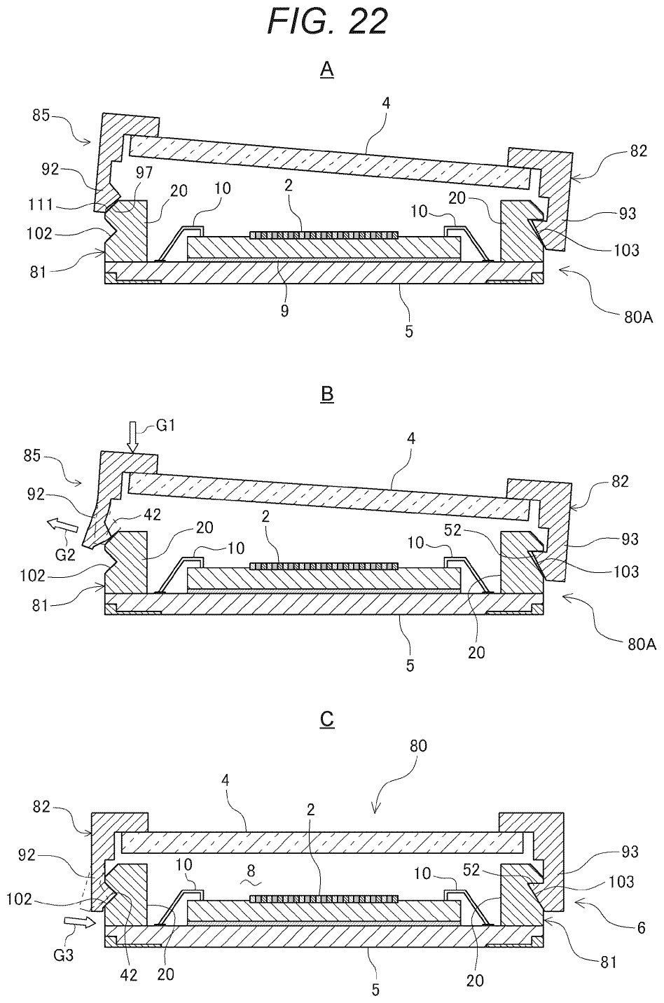

The clip portions 92 attaches and detaches the glass-side frame 82 to and from the substrate-side frame 81 with temporary elastic deformation. Specifically, as temporary elastic deformation, each clip portion 92 deforms to warp outward in the left-right direction so as to widen the distance to the hook portion 93, with respect to the substrate-side frame 81 to which the glass-side frame 82 is attached from above (see FIG. 22B). Furthermore, the clip portion 92 performs similar elastic deformation also when the glass-side frame 82 is removed from the substrate-side frame 81. Therefore, the clip portion 92 is formed as a portion having flexibility that allows the clip portion 92 to appropriately bend when the glass-side frame 82 is attached or detached.

In the substrate-side frame 81, chamfered portions 110 are formed at left and right outer corners of the upper portions of the left and right wall portions 20 that are engaged by the clip portions 92 and the hook portions 93 (see FIG. 21). The chamfered portions 110 are formed in portions of the wall portions 20 that are above the engagement recesses 102 and 103.

Each chamfered portion 110 forms an inclined surface 111 inclined downward from the inside to the outside in the left-right direction at the corner formed by the upper surface 20a and the outer wall surface 22 in the corresponding wall portion 20. Although it is merely an example, the inclination angle of the inclined surface 111 is 45°. The chamfered portions 110 are formed in a range corresponding to at least the formation portion of the clip portions 92 and the hook portions 93 in the Y direction.

Additionally, in the substrate-side frame 81, a recess 60 for causing a tool used for removing the lid body 85 from the substrate-side frame 81 to act on the lid body 85 is formed in the left wall portion 20, which is engaged by the clip portions 92. That is, the substrate-side frame 81 has the recess 60 that opens at the upper surface 20a and is partially covered with the cover glass 4. In the example shown in FIG. 17, the recess 60 is formed in a portion located between the two clip portions 92 in the Y direction in the left wall portion 20.

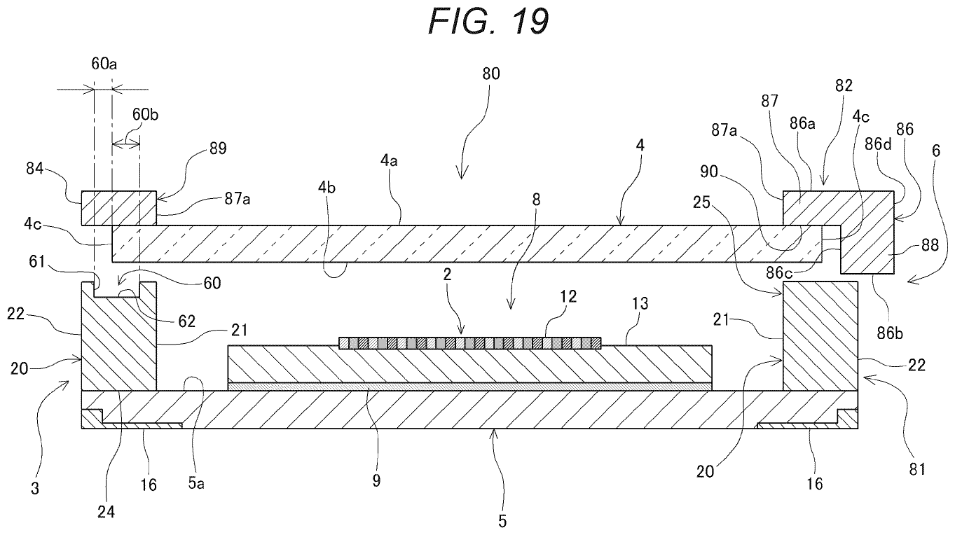

The glass-side frame 82 includes, at its left edge portion, a cutout portion 84 as a shape portion for facilitating access to the exposed portion 60a of the recess 60 formed in the substrate-side frame 81 (see FIG. 17). In the example shown in FIG. 17, the cutout portion 84 has a recessed shape with the outer side in the left-right direction (left side) as the open side in plan view. In the Y direction, the formation site of the cutout portion 84 is a non-formation site of the outer edge protrusions 88 (see FIG. 19).

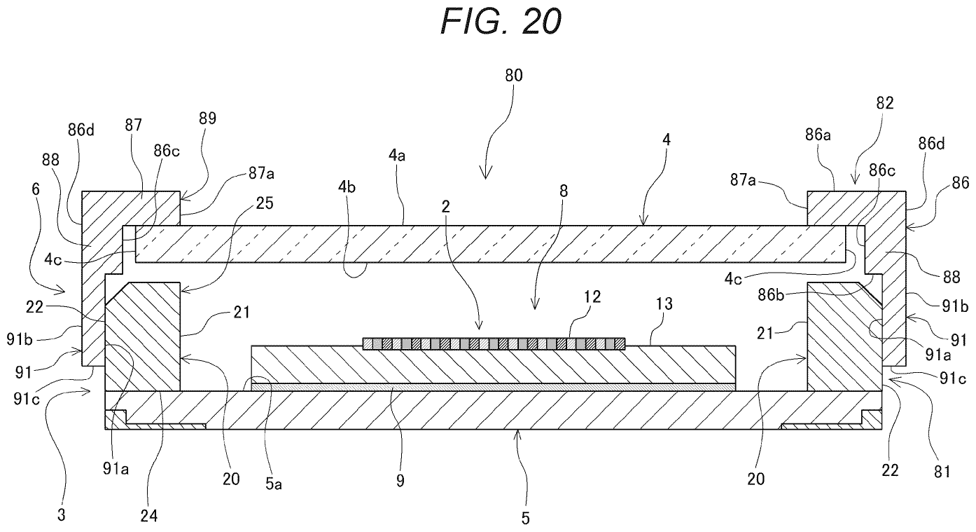

As shown in FIG. 20, in the glass-side frame 82, side wall portions 91 are provided on the outer edge protrusions 88 of a set of opposing side portions that are different from the two sides including the clip portions 92 and the hook portion 93 among the four side portions of the frame-shaped main body portion 86.

The side wall portions 91 are provided as protruding portions extending downward from the lower surface 86b of the frame-shaped main body portion 86. The side wall portions 91 are portions that restrict the movement of the glass-side frame 82 in the Y direction relative to the substrate-side frame 81 by coming into contact with the outer wall surfaces 22 of the wall portions 20. Each side wall portion 91 includes an inner wall surface 91a, which is an inner wall surface and serves as a contact surface with the outer wall surface 22 of the wall portion 20, an outer wall surface 91b, which is a wall surface opposite to the inner wall surface 91a, and a lower surface 91c, which has a horizontal plane shape.

The side wall portions 91 are provided over the entire range in the extending direction (X direction) of the pair of the side portions of the frame-shaped main body portion 86 that face each other in the Y direction. However, the side wall portions 91 may be provided partially or at multiple positions in the extending direction of the side portions of the frame-shaped main body portion 86.

The pair of side wall portions 91 is set such that the dimension between the inner wall surfaces 91a facing each other is substantially the same as or slightly larger than the dimension of the substrate-side frame 81 in the Y direction. The pair of side wall portions 91 comes into contact with the outer wall surfaces 22 of the wall portions 20 at the inner wall surfaces 91a in a state in which the substrate-side frame 81 is fitted between the pair of side wall portions 91, thereby restricting movement (lateral displacement) of the glass-side frame 82 relative to the substrate-side frame 81 in the Y direction.

### 6. Method for Manufacturing Solid-State Imaging Device According to Second Embodiment

An example of a method for manufacturing the solid-state imaging device 80 according to the second embodiment of the present technology will be described with reference to FIG. 22.

In the method for manufacturing the solid-state imaging device 80, first, a die bonding step of providing the image sensor 2 on the substrate 5 and a wire bonding step of connecting the substrate 5 and the image sensor 2 by wires 10 are performed. Next, a frame mounting step of providing the substrate-side frame 81 on the substrate 5 is performed. Through these steps, the image sensor unit 80A is obtained (see FIG. 21).

Next, the step of attaching the cover glass 4 to the image sensor unit 80A is performed. An example of the step of attaching the cover glass 4 will be described with reference to FIG. 22. In the present embodiment, as the attachment of the cover glass 4, a lid body 85 having a configuration in which the cover glass 4 is fixed to the glass-side frame 82 is attached to the substrate-side frame 81.

In attachment of the lid body 85, first, the lid body 85 is placed in the following attachment set state relative to the substrate-side frame 81. That is, as shown in FIG. 22A, the lid body 85 is brought into a state in which the hook portions 93 are engaged with the engagement recesses 103 and the clip portions 92 are in contact with the left wall portion 20. Here, for example, as illustrated in FIG. 22A, the clip portions 92 are supported by the wall portion 20 in a state in which the lower inclined surfaces 97 are in contact with the inclined surface 111 of the chamfered portion 110.

From the attachment set state of the lid body 85 shown in FIG. 22A, as shown in FIG. 22B, a force for pressing the lid body 85 toward the side corresponding to the substrate-side frame 81 (lower side) is applied (see arrow G1). Here, the pressing force to the lid body 85 is applied so as to mainly act on, for example, a side portion of the frame-shaped main body portion 86 of the lid body 85 on the side where the clip portion 92 is formed (left side). When the lid body 85 receives a downward force, the clip portions 92 elastically deform so as to widen the distance to the hook portions 93 while sliding on the inclined surface 111, which is in contact with the lower inclined surface 97 (see an arrow G2).

Then, in the lid body 85, with the side corresponding to the clip portions 92 in left-right direction moved downward, when the retaining protrusions 42 of the clip portions 92 reach the engagement recesses 102 of the substrate-side frame 81, the clip portions 92 return from the elastically deformed state to be fitted into the engagement recesses 102, and the hook portions 93 are fitted in the engagement recesses 103. As a result, as shown in FIG. 22C, the clip portions 92 return to their original natural state (see arrow G3), and a state in which the lid body 85 is attached to the substrate-side frame 81 is obtained. That is, a state in which the cover glass 4 is supported by the substrate-side frame 81 via the glass-side frame 82 is obtained. The cover glass 4 is attached as described above, and the solid-state imaging device 80 is obtained.

In the removal of the cover glass 4 in the solid-state imaging device 80 of the present embodiment, as the removal of the lid body 85, the recess 60 formed in the left wall portion 20 of the substrate-side frame 81 is used by the tool 75 as illustrated in FIG. 10A, and the engagement state of the clip portions 92 is released with respect to the left edge portion of the glass-side frame 82. Here, the clip portions 92 release the engagement with the wall portion 20 with the temporary elastic deformation that warps the support columns 41 outward as described above.

In the solid-state imaging device 80 according to the present embodiment, the frame 6 includes a substrate-side frame 81 and a glass-side frame 82 that supports the cover glass 4 and includes the clip portion 92 and the hook portion 93. According to such a configuration, in the image sensor unit 80A in which the lid body 85 including the cover glass 4 is removed from the solid-state imaging device 80, it is possible not to leave the clip portions 92 and the hook portions 93 in the substrate-side frame 81, so that the clip portions 92 and the hook portions 93 would not be an obstacle.

According to the frame 6 according to the first embodiment, in the image sensor unit 1A from which the cover glass 4 is removed, the clip portions 32 and the hook portions 33 can be used for fixing the lens housing 76 (see FIG. 11). However, in a case where the clip portions 32 and the hook portions 33 are not used for fixing the lens housing 76, the clip portions 32 and the hook portions 33, which are protruding portions on the wall portion 20, sometimes become an obstacle in attachment to a set structure, for example. In this regard, according to the solid-state imaging device 80 according to the present embodiment, since the clip portions 92 and the hook portions 93 do not remain in the substrate-side frame 81, which is the frame 6 after the cover glass 4 is removed, it is possible to obtain the image sensor unit 80A having good handleability.

Furthermore, in the substrate-side frame 81, it is only necessary to form the engagement recesses 102 and 103 as portions that are engaged by the clip portions 92 and the hook portions 93, so that complicated processing can be unnecessary for the frame portion of the image sensor unit 80A. On the other hand, the glass-side frame 82 having a relatively complicated shape relative to the substrate-side frame 81 can be reused after being removed as the lid body 85 including the cover glass 4. Therefore, the frame configuration according to the present embodiment is economical.

Furthermore, by forming the chamfered portions 110 in the wall portions 20 corresponding to the clip portions 92 and the hook portions 93, the lid body 85 can be easily attached to the substrate-side frame 81. Specifically, since a guiding action toward the side where the clip portions 92 are elastically deformed is obtained by the inclined surface 111 of the chamfered portion 110, the clip portions 92 and the hook portions 93 can be smoothly engaged with the engagement recesses 102 and 103, and the lid body 85 can be easily and reliably attached by the pressing operation from above relative to the lid body 85.

Furthermore, the substrate-side frame 81 has the recess 60 that opens at the upper surface 20a of the wall portion 20. According to such a configuration, when the lid body 85 is removed using the tool 75, the tool 75 can easily act on the cover glass 4 or the glass-side frame 82, and the cover glass 4 can be easily removed.

In the present embodiment, as in the modification of the first embodiment, a configuration may be adopted in which the glass-side frame 82 includes the clip portions 92 and the recess 60 on each of two sides facing each other in the X direction. In this case, engagement recesses 102 that are engaged by the clip portions 92 are formed on both sides in the X direction on the side corresponding to the substrate-side frame 81. Furthermore, in the glass-side frame 82, the clip portions 92, the hook portions 93, and the side wall portions 91 may be portions provided by attaching separate members to the member forming the frame-shaped main body portion 86.

Also, the formation positions and numbers of the clip portions 92, the hook portions 93, the side wall portions 91, and the recesses 60 are not particularly limited. For example, the clip portion 92 and the hook portion 93 may be provided at one position, or may be provided at three or more positions. Also, at least one of the clip portions 92 and the hook portions 93 may be provided on all four sides of the frame-shaped main body portion 86. Furthermore, the recesses 60 may be formed at two or more positions on the side portion where the clip portions 92 are provided.

### 7. Configuration Example of Solid-State Imaging Device According to Third Embodiment

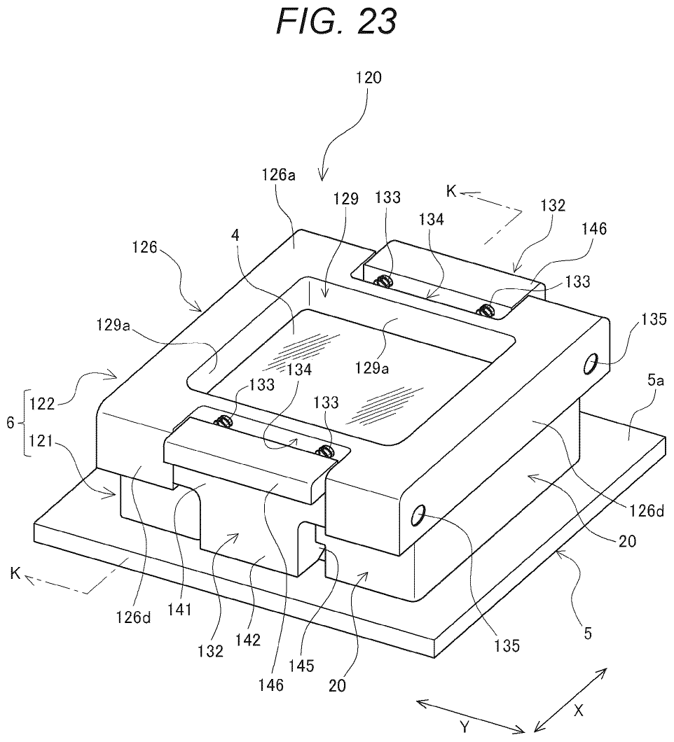

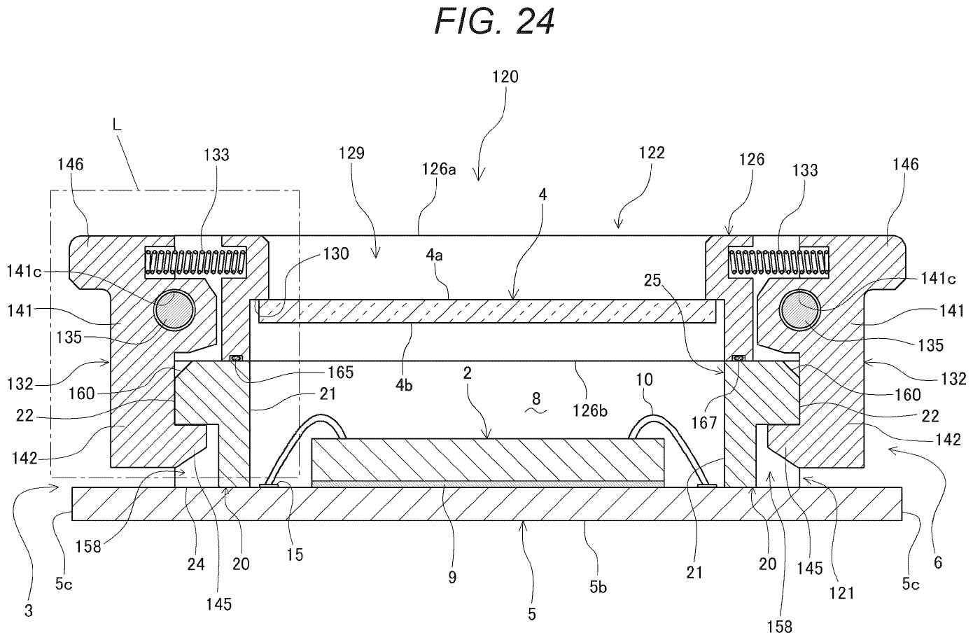

A configuration example of a solid-state imaging device 120 according to a third embodiment of the present technology will be described with reference to FIGS. 23 to 27. The solid-state imaging device 120 according to the present embodiment is different from that of the second embodiment in the configuration of the frame portion that holds a cover glass 4 in a frame 6.

As illustrated in FIGS. 23 to 27, the frame 6 according to the present embodiment includes a substrate-side frame 121, which is a first frame portion fixed to the substrate 5, and a glass-side frame 122, which is a second frame portion forming a cover holding portion and detachably attached to the substrate-side frame 121. That is, the solid-state imaging device 120 includes the glass-side frame 122 as a cover holding portion that detachably holds the cover glass 4 relative to the substrate-side frame 121 forming a part of the frame 6.

As described above, the frame 6 according to the present embodiment has a divided structure including the substrate-side frame 121, which is a frame main body portion forming the package main body portion 3 together with the substrate 5, and the glass-side frame 122, which is a glass support portion supporting the cover glass 4.

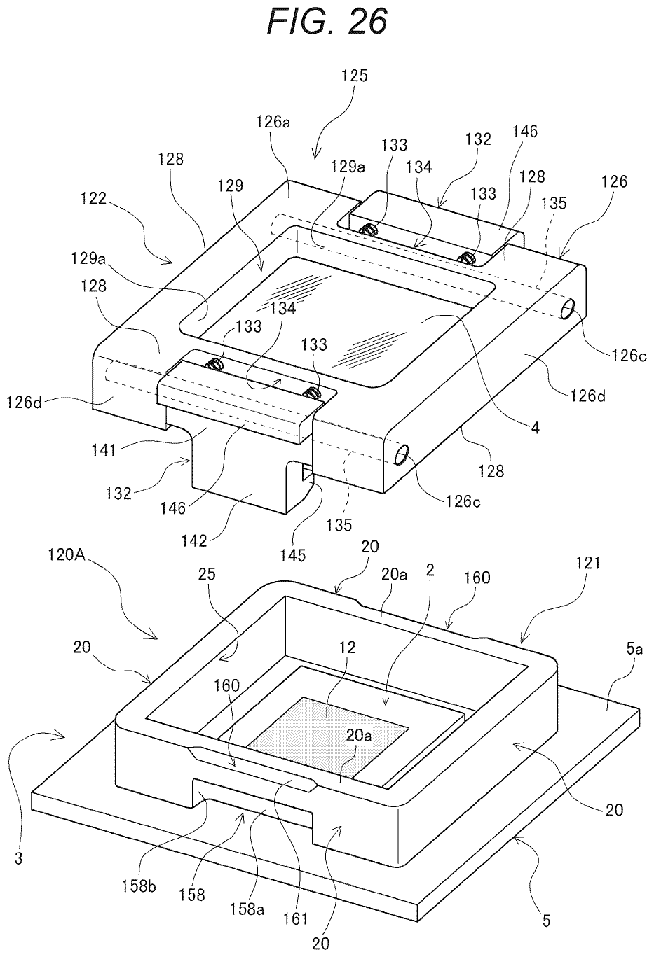

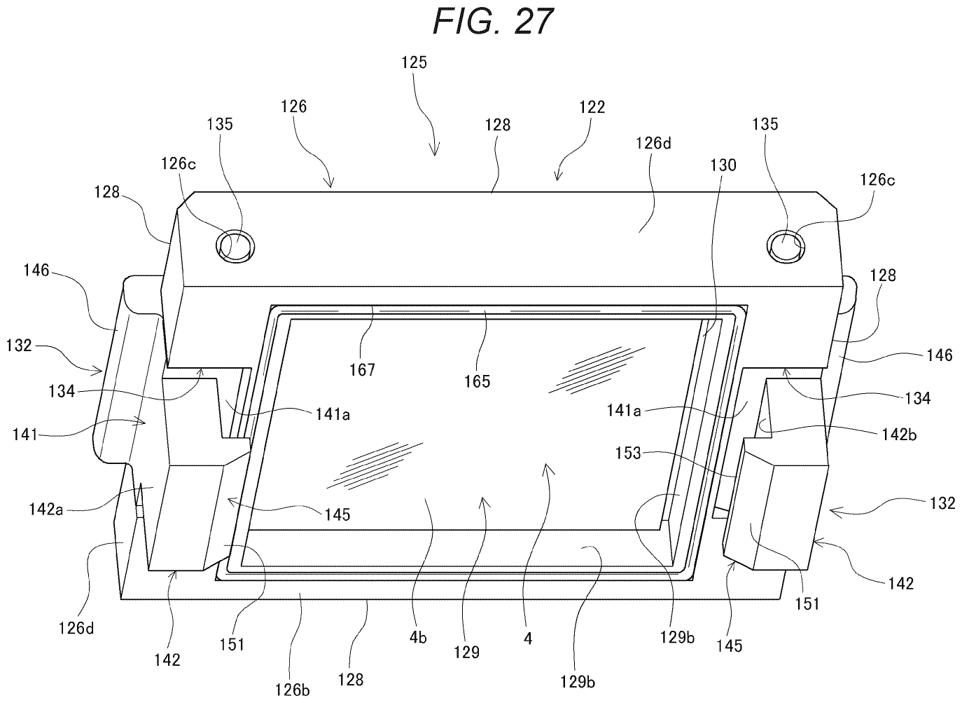

The glass-side frame 122 forms a lid body 125 that is detachably attached to an image sensor unit 120A together with the cover glass 4 (see FIGS. 26 and 27). The image sensor unit 120A includes an image sensor 2, a substrate 5, and the substrate-side frame 121.

The substrate-side frame 121 has four wall portions 20 forming an opening portion 25 similarly to the substrate-side frame 81 according to the second embodiment, and these wall portions 20 form a frame-shaped frame portion on the substrate 5. The substrate-side frame 121 is fixed to the substrate 5 with an adhesive.

The glass-side frame 122 includes a frame-shaped main body portion 126 that is a frame-shaped main body portion holding the cover glass 4, and a pair of clips 132 as engagement portions provided in the frame-shaped main body portion 126 and engaging with the substrate-side frame 121 to hold the glass-side frame 122 to the substrate-side frame 121.

The frame-shaped main body portion 126 is a member having a rectangular outer shape in plan view, has four frame-shaped side portions 128, and has an outer dimension larger than the outer shape of the substrate-side frame 121 in plan view. The frame-shaped main body portion 126 has an upper surface 126a and a lower surface 126b that are both horizontal planes. Additionally, the frame-shaped main body portion 126 has four outer side surfaces 126d formed perpendicular to the upper surface 126a and the lower surface 126b in the side portions 128.

The frame-shaped main body portion 126 has an opening portion 129 for securing a passage for light received by the image sensor 2. The opening portion 129 is a rectangular hole extending through the frame-shaped main body portion 126 in the up-down direction. The frame-shaped main body portion 126 has, as surfaces forming the opening portion 129, four upper inner side surfaces 129a at the upper part of the frame-shaped main body portion 126 and four lower inner side surfaces 129b located outward of the upper inner side surfaces 129a at the lower part of the frame-shaped main body portion 126.

As for the opening portion 129, the opening dimension on the lower side at the lower surface 126b of the frame-shaped main body portion 126 is slightly larger than the opening dimension on the upper side at the upper surface 126a of the frame-shaped main body portion 126. The opening portion 129 has an upper opening dimension smaller than the outer dimension of the cover glass 4, and a lower opening dimension substantially equal to or slightly larger than the outer dimension of the cover glass 4. Note that the opening portion 129 only needs to be formed so as to include the entire pixel region 12 of the image sensor 2 in the opening region in plan view, and the opening shape and the opening dimension of the opening portion 129 are not limited.

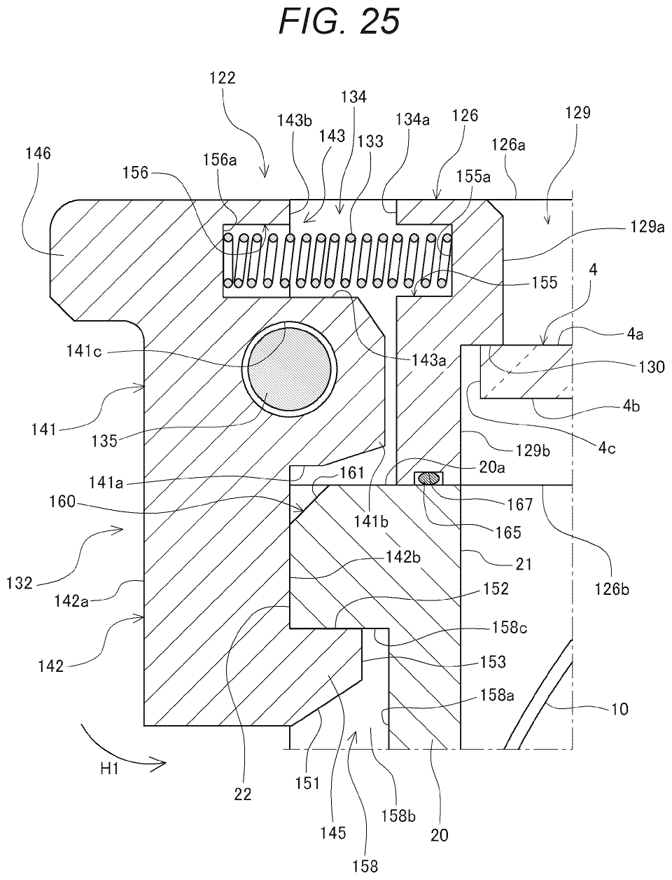

In the glass-side frame 122, a stepped surface, which is a horizontal plane that faces downward between the upper inner side surface 129a and the lower inner side surface 129b, is a glass attachment surface 130. The glass attachment surface 130 is formed substantially at the center of the opening portion 129 in the up-down direction. The cover glass 4 is fixed to the glass attachment surface 130 with an adhesive so as to cover the entire opening portion 129 from below. The left and right side surfaces 4c of the cover glass 4 face the lower inner side surface 129b (see FIG. 25).

The clips 132 are provided with respect to the left and right side portions 128 of the frame-shaped main body portion 126. The clip 132 is an example of a rotation engaging body rotatably supported in a state of being urged in a predetermined direction by coil springs 133 as urging members with respect to the frame-shaped main body portion 126. The substrate-side frame 121 including the frame-shaped main body portion 126 and the left and right clips 132 is configured to be bilaterally symmetrical or substantially bilaterally symmetrical.

Each clip 132 includes a support base portion 141, which has an outer shape along a substantially quadrangular prism shape with the Y direction as a longitudinal direction, and a clip main body portion 142, which protrudes downward from the support base portion 141. The clip 132 is provided in a state in which substantially the entire support base portion 141 is positioned in a recess 134 formed in an intermediate portion in the Y direction of each of the left and right side portions 128 of the frame-shaped main body portion 126. The recesses 134 are cutout portions having a recessed shape with the outer side in the left-right direction as an open side in plan view. The clip 132 is provided in a state in which the clip main body portion 142 protrudes downward from the frame-shaped main body portion 126.

The clip 132 is rotatably supported with respect to the frame-shaped main body portion 126 with the Y direction as a rotation axis direction by a support shaft 135 that extends through the clip 132 with the Y direction as an axial direction and has both end sides inserted into the left and right side portions 128 of the frame-shaped main body portion 126. The support shaft 135 is a linear round bar-shaped member, extends through a shaft support hole 141c formed in the support base portion 141 of the clip 132, and is inserted in shaft support holes 126c formed in portions on both sides in the Y direction of the recess 134 in the side portions 128 of the frame-shaped main body portion 126. The support shaft 135 is provided, for example, in a state of being fixed to one of the clip 132 and the frame-shaped main body portion 126, and rotatably supports the clip 132 with respect to the frame-shaped main body portion 126.

The support base portion 141 has a right-angled cutout portion 143 at the corner on the inner side in the left-right direction and on the upper side (see FIG. 25). The cutout portion 143 is formed by a horizontal lower surface 143a, which is a surface facing upward, and a side surface 143b, which extends upright from the outer side in the left-right direction of the lower surface 143a. The side surface 143b is the surface facing the side wall surface 134a, which is one of the surfaces forming the recess 134 of the frame-shaped main body portion 126 that faces outward in the left-right direction.

The clip main body portion 142 extends downward from the support base portion 141, and has retaining protrusions 145 on the inner side in the left-right direction of the lower end portion. In the clip main body portion 142, the outer side surface 142a, which is the outer surface in the left-right direction, is positioned on the same plane as the side surface on the outer side in the left-right direction of the support base portion 141, and the inner side surface 142b, which is an inner surface in the left-right direction, is positioned outward in the left-right direction of the edge on the inner side in the left-right direction of the support base portion 141. Furthermore, the clip main body portion 142 is formed at an intermediate portion in the Y direction with respect to the support base portion 141. The support base portion 141 has a lower surface 141a, from which the clip main body portion 142 protrudes downward.

As shown in FIG. 25, the retaining protrusion 145 includes a lower inclined surface 151, which is inclined in a direction from the lower side to the upper side from the outer side to the inner side in the left-right direction, a horizontal retaining surface 152, which forms a right angle with the inner side surface 142b, and a vertical end surface 153, which is a surface between the lower inclined surface 151 and the retaining surface 152. The retaining surface 152 is located below the inner portion in the left-right direction of the support base portion 141.

The coil springs 133 are an example of elastic bodies that act on the clips 132, and are provided between the left and right side portions 128 of the frame-shaped main body portion 126 and the clips 132 with their expansion/contraction direction in the left-right direction at positions above the support shafts 135 in the up-down direction. It is structured so that the urging forces of the left and right coil springs 133 close the lower portions of the left and right clips 132, which rotate about the support shafts 135. The coil springs 133 are provided at two positions on both sides of each clip 132 in the Y direction at a predetermined interval in the Y direction (see FIG. 23).

Each coil spring 133 has an inner portion in the left-right direction, which is one end side in the expansion/contraction direction, inserted in an inner spring-support hole 155 formed in each of the left and right side portions 128 of the frame-shaped main body portion 126 (see FIG. 25). The inner spring-support hole 155 is a circular hole opened to face the side wall surface 134a.

On the other hand, the coil spring 133 has an outer portion in the left-right direction, which is the other end side in the expansion/contraction direction, inserted in an outer spring-support hole 156 formed in the support base portion 141 of the clip 132 (see FIG. 25). The outer spring-support hole 156 is a circular hole opening at the side surface 143b of the cutout portion 143. The outer spring-support hole 156 is formed so as to face the inner spring-support hole 155 at a position on the outer side in the left-right direction, and supports the coil spring 133 together with the inner spring-support hole 155.

The coil spring 133 is interposed between the frame-shaped main body portion 126 and the clip 132 in a state in which one end side is in contact with the bottom surface 155a of the inner spring-support hole 155 and the other end side is in contact with the bottom surface 156a of the outer spring-support hole 156, and presses the upper end portion of the clip 132, which is a portion above the support shaft 135, from the inner side to the outer side in the left-right direction with respect to the frame-shaped main body portion 126. That is, the coil spring 133 urges the clip 132, which is rotatably supported by the support shaft 135, in a rotation direction (see FIG. 25, arrow H1) in which the lower end portion of the clip 132 moves to the inner side in the left-right direction relative to the frame-shaped main body portion 126.

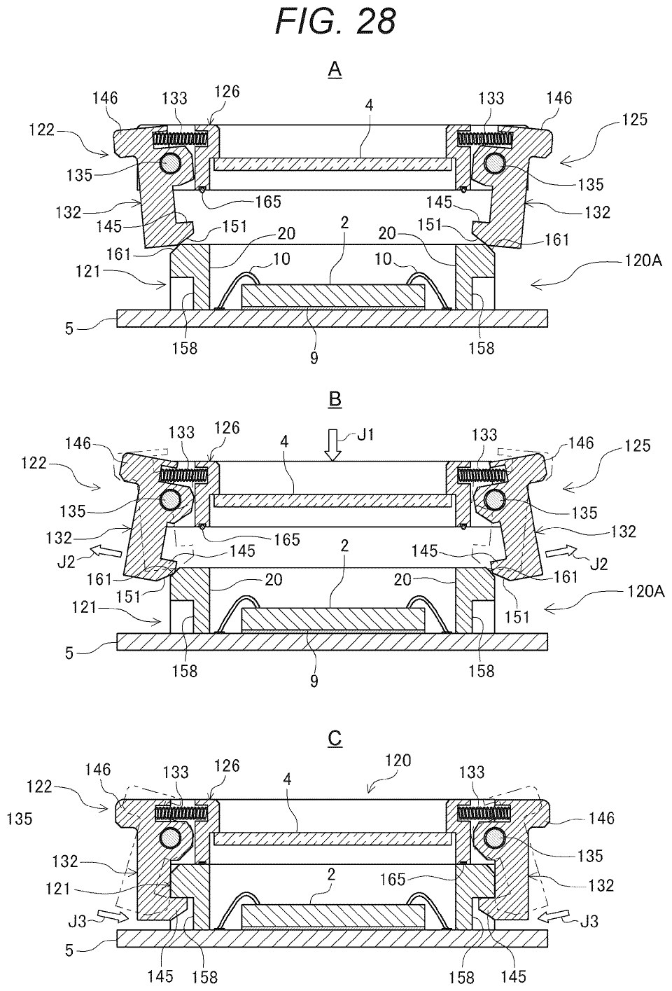

In the lid body 125 removed from the image sensor unit 120A, each clip 132 is restricted from turning in the direction urged by the coil spring 133, for example, by bringing the corner 141b, which is located on the inner side in the left-right direction and on the lower side of the support base portion 141, into contact with the side wall surface 134a of the recess 134 (see FIG. 25 and FIG. 28A). Note that a portion functioning as a stopper may be separately provided for restricting the rotation of the clip 132.

Furthermore, the clip 132 includes a protruding edge portion 146, which is a protruding portion extending outward in the left-right direction, at the upper portion of the support base portion 141. The protruding edge portion 146 is formed over the entire range in the Y direction of the clip 132. The protruding edge portion 146 extends the upper surface 132a of the clip 132 positioned on the same plane as the upper surface 126a of the frame-shaped main body portion 126 to the outer side in the left-right direction, and is formed to protrude to the outer side in the left-right direction with respect to the outer side surface 142a of the clip main body portion 142 so as to have a cross-sectional shape along a substantially rectangular shape. For example, the protruding edge portion 146 is used as a grip portion for rotating the clip 132 when the lid body 125 is attached to and detached from the image sensor unit 120A.

The glass-side frame 122 is fixed to the substrate-side frame 121 in a mode in which the substrate-side frame 121 is held between the left and right clips 132 by engaging the left and right clips 132 with the outer sides in the left-right direction of the substrate-side frame 121.

The substrate-side frame 121 includes engagement recesses 158, which are engaged portion that are engaged by the left and right clips 132 (see FIG. 26). Each engagement recess 158 is a cutout portion formed as a recess with respect to the outer wall surface 22 and the lower surface 24 of the wall portion 20, and is formed by a wall surface 158a located on the inner side in the left-right direction of the outer wall surface 22, side surfaces 158b on both sides in the Y direction, and a horizontal upper surface 158c facing downward.

The engagement recess 158 is formed, in the intermediate portion in the Y direction of each of the wall portions 20 on both left and right sides, in a range including the entire clip main body portion 142 corresponding to the length of the clip main body portion 142 of the clip 132 in the Y direction. The engagement recess 158 is formed in a substantially lower half portion of the wall portion 20 in the up-down direction. The engagement recess 158 is formed to have a size that allows the entire or substantially the entire retaining protrusion 145 of the clip 132 to be fitted. By setting the dimension of the engagement recess 158 in the Y direction, that is, the dimension between the side surfaces 158b to be substantially the same as the dimension of the clip main body portion 142, the clip 132 can be positioned in the Y direction relative to the engagement recess 158, and the action of positioning the glass-side frame 122 in the Y direction relative to the substrate-side frame 121 can be obtained.

The clip 132 is rotatably supported relative to the frame-shaped main body portion 86 in a state of being urged by the coil springs 133 in a direction of engaging with the engagement recess 158 formed in the substrate-side frame 81. When the clip 132 is in a state of engaging with the engagement recess 158, the retaining surface 152 of the retaining protrusion 145 is in contact with the upper surface 158c of the engagement recess 158, and the inner side surface 142b of the clip main body portion 142 is in contact with the outer wall surface 22 of the wall portion 20 (see FIG. 25). Therefore, in a state in which the left and right clips 132 are engaged with the substrate-side frame 121 at the engagement recesses 158, the dimension between the inner side surfaces 142b facing each other in the left-right direction is substantially the same as the dimension of the substrate-side frame 121 in the X direction.

Also, in the substrate-side frame 121, the chamfered portions 160 are formed at left and right outer corners of the upper portions of the left and right wall portions 20 to be engaged by the clips 132. The chamfered portion 160 is formed at a portion above the engagement recess 158 in each wall portion 20.

Each chamfered portion 160 forms an inclined surface 161 inclined downward from the inside to the outside in the left-right direction at the corner formed by the upper surface 20a and the outer wall surface 22 in the corresponding wall portion 20. Although it is merely an example, the inclination angle of the inclined surface 161 is 45°. The chamfered portions 160 are formed in a range corresponding to at least the formation portion of the clips 132 in the Y direction. In the example shown in FIG. 26, the chamfered portion 160 is formed in substantially the same range as the engagement recess 158 in the Y direction.

Additionally, in the frame 6, a gasket 165 as a seal member is provided between the upper surface 20a of each wall portion 20 and the lower surface 126b of the frame-shaped main body portion 126, which are bonding surfaces between the substrate-side frame 121 and the glass-side frame 122. The gasket 165 is an endless quadrangle gasket having a substantially rectangular shape, and is provided in a state of being fitted in a fitting groove 167, which is formed in the lower surface 126b in a substantially rectangular shape so as to follow the opening shape of the opening portion 129 (see FIG. 27).

In a state in which the left and right clips 132 are engaged with the engagement recesses 158, the gasket 165 is sandwiched between the upper surface 20a of each wall portion 20 and the lower surface 126b of the frame-shaped main body portion 126 and is compressed and deformed. Airtightness of the cavity 8 can be obtained by the gasket 165. Note that the fitting groove for fitting the gasket 165 may be formed in the upper surface 20a of the wall portion 20.

### 8. Method for Manufacturing Solid-State Imaging Device According to Third Embodiment

An example of a method for manufacturing the solid-state imaging device 120 according to the third embodiment of the present technology will be described with reference to FIG. 28. Note that, in the method for manufacturing the solid-state imaging device 120, the step of obtaining the image sensor unit 120A is similar to that of the above-described embodiment, and thus description thereof is omitted, and the step of attaching the cover glass 4 to the image sensor unit 120A will be described.

In the present embodiment, as the attachment of the cover glass 4, a lid body 125 having a configuration in which the cover glass 4 is fixed to the glass-side frame 122 is attached to the substrate-side frame 121.

In attachment of the lid body 125, first, the lid body 125 is placed in the following attachment set state relative to the substrate-side frame 121. That is, as shown in FIG. 28A, the lid body 125 is brought into a state in which the left and right clips 132 are in contact with the respective wall portions 20. Here, for example, each clip 132 is supported by the wall portion 20 in a state in which the lower inclined surface 151 is in contact with the inclined surface 161 of the chamfered portion 160.

From the attachment set state of the lid body 125 shown in FIG. 28A, as shown in FIG. 28B, a force for pressing the lid body 125 toward the side corresponding to the substrate-side frame 121 (lower side) is applied (see arrow J1). When the lid body 125 receives a downward force, the clips 132 rotate against the urging forces of the coil springs 133 so as to widen the distance between the clips 132 on both sides in the left-right direction (see arrow J2) while sliding on the inclined surfaces 161, which are in contact with the lower inclined surfaces 151.

Then, in the lid body 125 that moves downward relative to the substrate-side frame 121, when the retaining protrusions 145 of the clips 132 reach the engagement recesses 158 of the substrate-side frame 121, as shown in FIG. 28 C, the left and right clips 132 are rotated by the urging forces of the coil springs 133 from the state of being rotated against the urging forces of the coil springs 133, and are fitted into the engagement recesses 158 (see arrow J3). As a result, a state in which the lid body 125 is attached to the substrate-side frame 121 is obtained. That is, a state in which the cover glass 4 is supported by the substrate-side frame 121 via the glass-side frame 122 is obtained. The cover glass 4 is attached as described above, and the solid-state imaging device 120 is obtained.

Note that the lid body 125 may be attached to the substrate-side frame 121 by, for example, the following method. That is, when the left and right clips 132 are engaged with the engagement recesses 158, the left and right clips 132 are operated and rotated against the urging forces of the coil springs 133 using the protruding edge portions 146 as grip portions or knob portions to be in a widened state in advance, and the rotation operation of the left and right clips 132 is released after the frame-shaped main body portion 126 of the lid body 125 is placed on the substrate-side frame 121, so that the retaining protrusions 145 are directly fitted into the engagement recesses 158.

The cover glass 4 in the solid-state imaging device 120 of the present embodiment is removed as follows, for example, as the removal of the lid body 125. That is, as described above, the engagement with the engagement recesses 158 is released by performing the rotation operation in the direction of widening the left and right clips 132 using the protruding edge portions 146, and the lid body 125 is lifted relative to the substrate-side frame 121 in this state, whereby the lid body 125 is removed.

According to the solid-state imaging device 120 according to the present embodiment, similarly to the solid-state imaging device 80 according to the second embodiment, in the image sensor unit 120A in which the lid body 125 is removed from the solid-state imaging device 120, it is possible to prevent the clips 132 from remaining on the substrate-side frame 121, thereby achieving the image sensor unit 120A having good handling characteristics. Furthermore, in the substrate-side frame 121, it is only necessary to form the engagement recesses 158 as portions that are engaged by the clips 132, so that complicated processing can be unnecessary for the frame portion of the image sensor unit 120A. Also, the glass-side frame 122 can be reused after being detached as the lid body 125 including the cover glass 4.

Furthermore, in the solid-state imaging device 120 according to the present embodiment, the glass-side frame 122 includes the spring-type clips 132, which receive the action of the coil springs 133 as engagement portions relative to the substrate-side frame 121. According to such a configuration, the lid body 125 including the cover glass 4 can be easily removed without using a tool such as a screwdriver. Additionally, the lid body 125 can be easily attached by a pressing operation from above to the lid body 125.

When the cover glass 4 is removed using the principle of leverage using a tool as in the above-described embodiment, a considerable force needs to be applied to the cover glass 4 and the frame 6 by the tool. In this regard, according to the configuration including the spring-type clips 132 according to the present embodiment, the lid body 125 can be removed without a tool acting on the cover glass 4 and the frame 6. As a result, it is possible to suppress chipping of the cover glass 4 and the frame 6, which may be caused by the action of a tool on the cover glass 4 and the frame 6, and generation of dust and the like caused by the chipping.

Furthermore, by forming the chamfered portions 160 in the wall portions 20 corresponding to the left and right clips 132, the lid body 125 can be easily attached to the substrate-side frame 121. Specifically, since the inclined surfaces 161 of the chamfered portions 160 provide a guiding action for rotating the clips 132 outward in the left-right direction, the clips 132 can be smoothly engaged with the engagement recesses 158, and the lid body 125 can be easily and reliably attached.

Also, the substrate-side frame 121 and the frame-shaped main body portion 126 of the glass-side frame 122 are hermetically sealed by the gasket 165. According to such a configuration, it is possible to ensure airtightness of the cavity 8 in a state in which the lid body 125 is attached to the image sensor unit 120A, and it is possible to suppress a decrease in reliability due to moisture absorption and intrusion of dust into the cavity 8. Additionally, since the moisture absorption of the cavity 8 can be suppressed, for example, at the time of reflow, it is possible to suppress generation of a crack or the like in the package due to an increase in internal pressure accompanying evaporation of moisture absorbed by the cavity 8.

### 9. Modification of Solid-State Imaging Device According to Third Embodiment

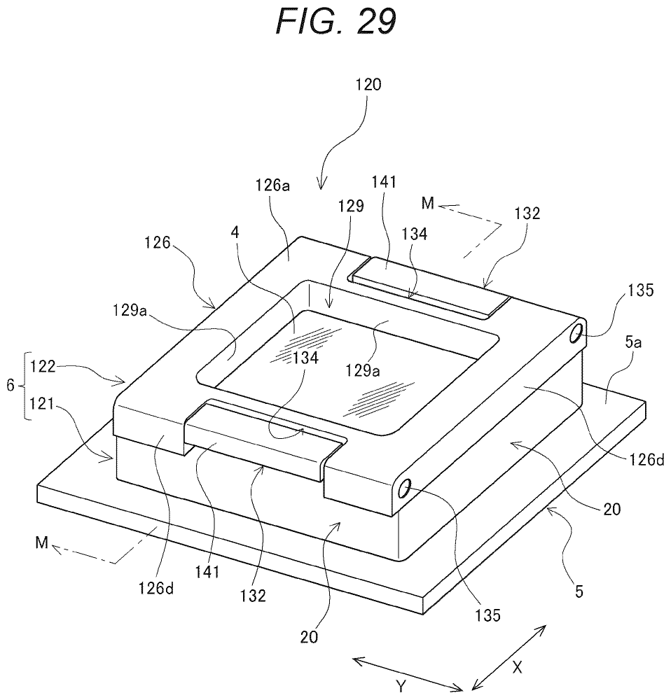

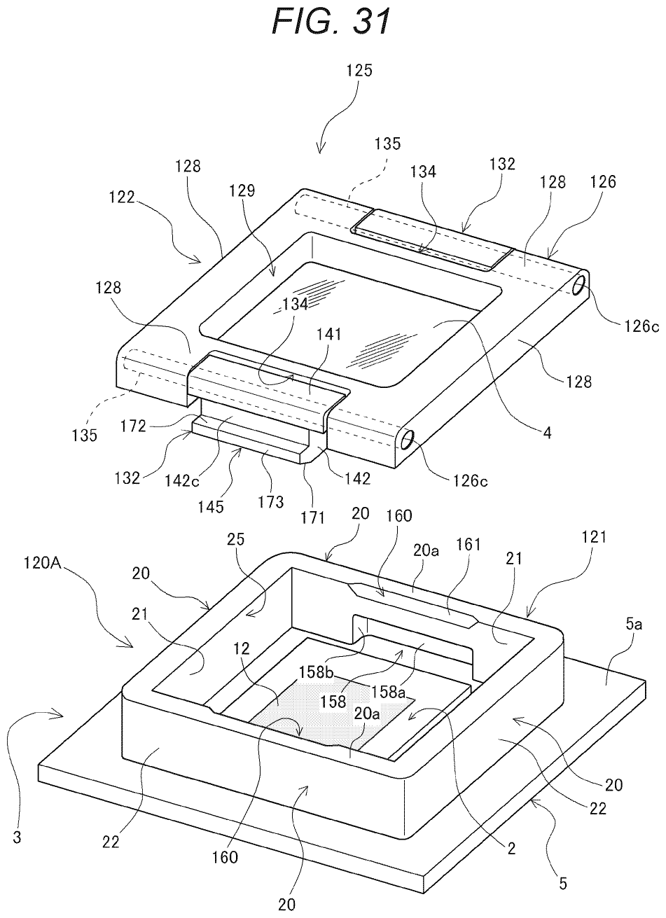

Modifications of the solid-state imaging device 120 according to the third embodiment of the present technology will be described with reference to FIGS. 29 to 31. The solid-state imaging device 120 of this modification has a configuration in which the attachment direction of the clips 132 in the glass-side frame 122 is opposite in the left-right direction, and the clips 132 are engaged with the inner sides of the left and right wall portions 20 of the substrate-side frame 121.

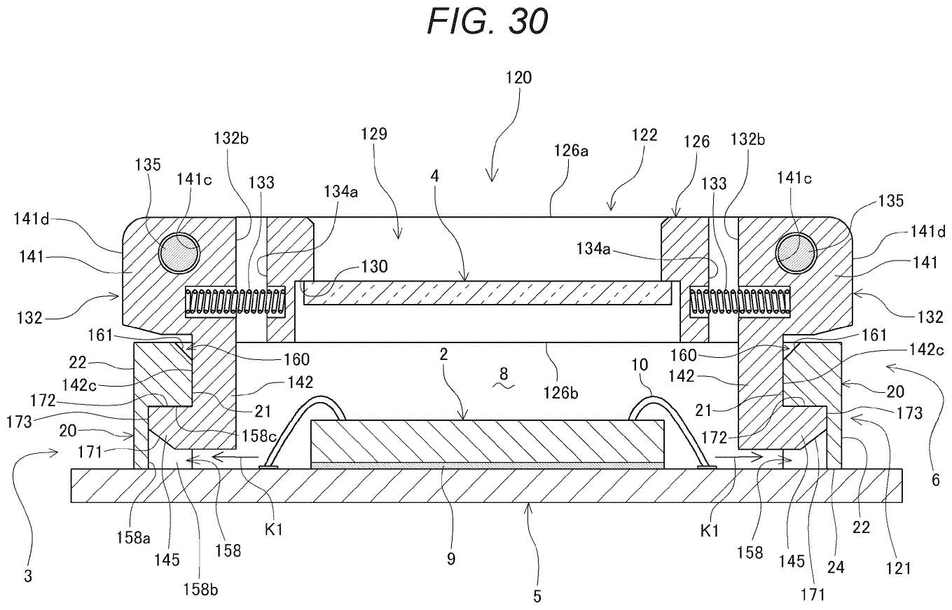

As shown in FIGS. 29 to 31, in the configuration of the present modification, the clip main body portion 142 of each clip 132 has a retaining protrusion 145 on the outer side in the left-right direction of the lower end portion. The clip main body portion 142 has an inner surface in the left-right direction located on the same plane as the side surface on the inner side in the left-right direction of the support base portion 141, and forms the inner side surface 132b of the clip 132 together with the support base portion 141 (see FIG. 30). The inner side surface 132b is a surface facing the side wall surface 134a of the recess 134 in the glass-side frame 122. In the clip main body portion 142, an outer side surface 142c, which is an outer surface in the left-right direction, is located inward in the left-right direction of the side surface 141d of the support base portion 141 in the left-right direction.

The retaining protrusion 145 includes a lower inclined surface 171, which is inclined in a direction from the lower side to the upper side from the outer side to the inner side in the left-right direction, a horizontal retaining surface 172, which forms a right angle with the outer side surface 142c, and a vertical end surface 173, which is a surface between the lower inclined surface 171 and the retaining surface 172. The retaining surface 172 is located below the outer portion in the left-right direction of the support base portion 141.

In the present modification, the support shaft 135 that supports the clip 132 is provided in the upper portion of the support base portion 141.

The coil springs 133 are provided between the left and right side portions 128 of the frame-shaped main body portion 126 and the clips 132 with their extension direction in the left-right direction at positions below the support shafts 135 in the up-down direction. It is structured so that the urging forces of the left and right coil springs 133 open the lower portions of the left and right clips 132, which rotate about the support shafts 135.

Each coil spring 133 presses a lower portion of the support base portion 141 of the clip 132, which is a portion below the support shaft 135, with respect to the frame-shaped main body portion 126 from the inner side in the left-right direction to the outside. That is, the coil spring 133 urges the clip 132, which is rotatably supported by the support shaft 135, in a rotation direction (see FIG. 30, arrow K1) in which the lower end portion of the clip 132 moves to the outer side in the left-right direction relative to the frame-shaped main body portion 126. Note that in the lid body 125 removed from the image sensor unit 120A, a portion functioning as a stopper for restricting the rotation of the clip 132 in the direction urged by the coil spring 133 is appropriately provided in the clip 132 or the like.

The glass-side frame 122 is fixed to the substrate-side frame 121 by engaging the left and right clips 132 with the inner sides in the left-right direction of the substrate-side frame 121. On the side corresponding to the substrate-side frame 121, engagement recesses 158, which are portions engaged by the left and right clips 132, are formed as recesses in the inner wall surface 21 and the lower surface 24 of each wall portion 20. Each engagement recess 158 is formed by a wall surface 158a, which is located outward of the inner wall surface 21 in the left-right direction, side surfaces 158b on both sides in the Y direction, and a horizontal upper surface 158c facing downward. When the clip 132 is in a state of engaging with the engagement recess 158, the retaining surface 172 of the retaining protrusion 145 is in contact with the upper surface 158c of the engagement recess 158, and the outer side surface 142c of the clip main body portion 142 is in contact with the inner wall surface 21 of the wall portion 20.

Also, in the substrate-side frame 121, the chamfered portions 160 are formed at left and right inner corners of the upper portions of the left and right wall portions 20 to be engaged by the clips 132. Each chamfered portion 160 forms an inclined surface 161 inclined downward from the outside to the inside in the left-right direction at the corner formed by the upper surface 20a and the inner wall surface 21 in the corresponding wall portion 20.

According to the configuration of this modification, in attachment of the lid body 125, the clips 132 temporarily rotate against the urging forces of the coil springs 133 so as to narrow the distance between the clips 132 on the opposite sides in the left-right direction. Then, in the lid body 125 that moves downward relative to the substrate-side frame 121, when the retaining protrusions 145 of the clips 132 reach the engagement recesses 158, the left and right clips 132 rotate by the urging forces of the coil springs 133 and are fitted into the engagement recesses 158. The clips 132 also perform a similar rotation operation when the lid body 125 is removed from the substrate-side frame 121. Note that in the rotation operation of the clips 132 against the urging forces of the coil springs 133, for example, an operation of pressing lower portions of the side surfaces 141d of the support base portions 141 of the left and right clips 132 is performed.

With the configuration of such a modification, the above-described operation and effect can also be obtained. Furthermore, other modifications of the solid-state imaging device 120 according to the present embodiment include the following configurations. In the configuration example described above, the clips 132 and the engagement recesses 158 that are engaged by the clips 132 are provided on two sides facing each other in the left-right direction in the frame-shaped package structure, but the combination of the clips 132 and the engagement recesses 158 may be provided on three sides or four sides in the frame-shaped package. Furthermore, multiple sets of combinations of the clips 132 and the engagement recesses 158 may be provided on each side of the frame-shaped package.

### 10. Configuration Example of Solid-State Imaging Device According to Fourth Embodiment

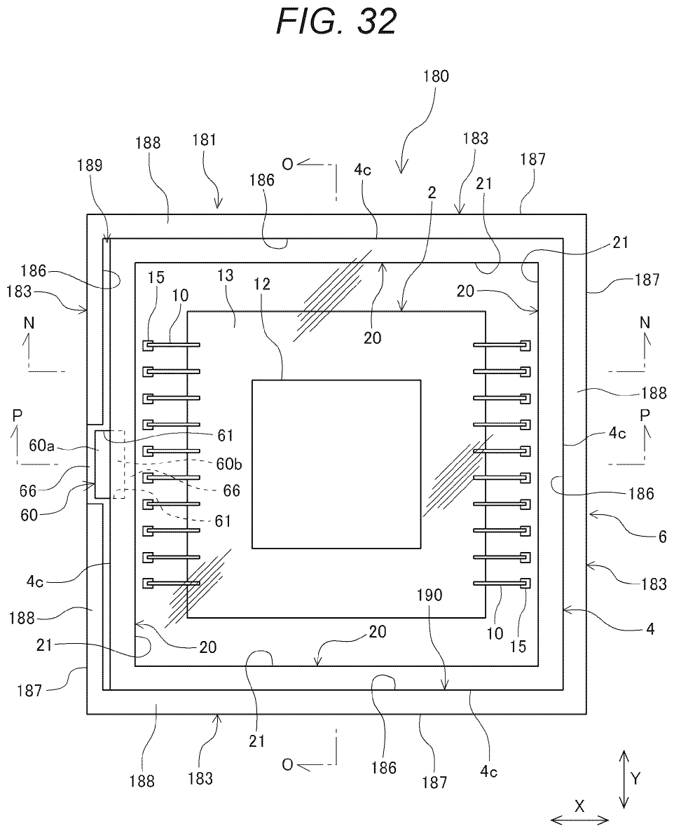

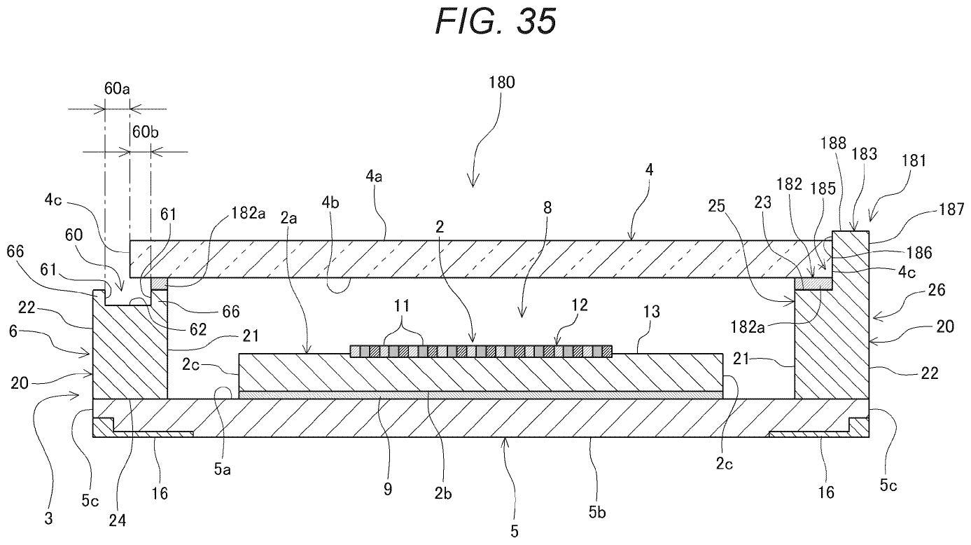

A configuration example of a solid-state imaging device 180 according to a fourth embodiment of the present technology will be described with reference to FIGS. 32 to 35. The solid-state imaging device 180 according to the present embodiment is different from the solid-state imaging device 1 according to the first embodiment in the configuration of the cover holding portion that detachably holds the cover glass 4 relative to the frame 6.

The solid-state imaging device 180 according to the present embodiment includes, as the cover holding portion, a step forming portion 181 provided on the upper side of the frame main body portion 26, and a bonding portion 182 interposed between the frame main body portion 26 and the cover glass 4.

The step forming portion 181 is a portion formed as a part of the frame 6, and is provided as a protruding portion extending upward from the glass support surface 23. The step forming portion 181 is a portion that forms a step portion 185 relative to the glass support surface 23 and is in contact with the side surface 4c of the cover glass 4 to restrict the movement of the cover glass 4 relative to the frame 6.

The step forming portion 181 is a wall-shaped portion formed over substantially the entire periphery along the frame shape of the frame main body portion 26 in plan view relative to the frame main body portion 26 configured in a frame shape by the four wall portions 20. Therefore, the step forming portion 181 includes four step forming wall portions 183 formed on the respective wall portions 20, and these step forming wall portions 183 form a frame shape in plan view.

The step forming portion 181 is provided on the wall portions 20 so that the step forming wall portions 183 are located on the outer side in the wall thickness direction of the wall portions 20 (the side corresponding to the outer wall surface 22), and forms the step portion 185 together with the glass support surface 23. The step forming portion 181 includes an inner side surface 186, which is an inner wall surfaces of the step forming wall portions 183 and serves as a contact surface with the side surface 4c of the cover glass 4, an outer side surface 187, which is a wall surface opposite to the inner side surface 186, and a horizontal upper surface 188. The step forming portion 181 is formed such that the outer side surface 187 is located on the same plane as the outer wall surface 22 of the wall portion 20.

The step forming wall portions 183 are provided at the respective wall portions 20 over the entire ranges of the wall portions 20 in the extending direction in plan view. Note that the step forming wall portion 183 formed on the left wall portion 20 is formed in a range excluding the formation portion of a recess 60 formed in the central portion in the extending direction of the wall portion 20. That is, the step forming wall portion 183 formed on the left wall portion 20 is divided at the formation site of the recess 60 in the Y direction. However, the step forming wall portion 183 may be provided on the corresponding wall portion 20 partially along the extending direction of the wall portion 20 or provided at multiple positions.

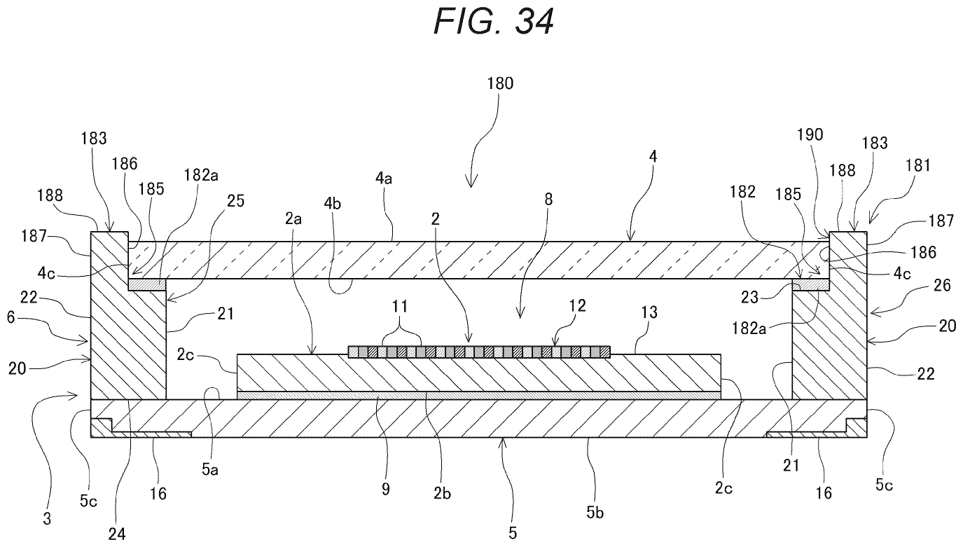

In the step forming portion 181, the upper surface 188 of each step forming wall portion 183 is a step surface that is higher with respect to the glass support surface 23. In the step portion 185, the inner side surface 186 is positioned outside the inner wall surface 21 of the wall portion 20 and is formed as a surface parallel to the inner wall surface 21. In the example illustrated in FIG. 34, the step forming wall portion 183 has a wall thickness of about ½ of the wall thickness of the wall portion 20. However, the dimension of the wall thickness of the step forming wall portion 183 is not particularly limited.

The pair of step forming wall portions 183 facing each other in the Y direction is set such that the dimension between the inner side surfaces 186 facing each other is substantially the same as or slightly larger than the dimension of the cover glass 4 in the Y direction. The pair of step forming wall portions 183 facing each other in the X direction is set such that the dimension between the inner side surfaces 186 facing each other is larger than the dimension of the cover glass 4 in the X direction, and a gap 189 is formed between the left step forming wall portion 183 and the cover glass 4.

The gap 189 is a slit-shaped space portion in the Y direction formed by the inner side surface 186 of the left step forming wall portion 183 and the left side surface 4c of the cover glass 4, which are surfaces facing each other on the glass support surface 23. In the present embodiment, in order to form the gap 189, the wall thickness of the left step forming wall portion 183 is thinned by substantially the same dimension as the width of the gap 189 as compared with the other step forming wall portions 183.

In the step forming portion 181, the four step forming wall portions 183 form a rectangular opening portion 190 opening upward corresponding to the outer shape of the cover glass 4. The step forming portion 181 restricts the movement of the cover glass 4 in the horizontal direction on the glass support surface 23 by coming into contact with the side surfaces 4c of the cover glass 4 at the inner side surfaces 186 in a state in which the cover glass 4 is fitted in the opening portion 190. In a state in which the cover glass 4 is fitted in the opening portion 190, the four side surfaces 4c are contact surfaces or opposing surfaces with respect to the inner side surfaces 186 of the step forming wall portions 183. As described above, the step forming portion 181 is a portion where the step portion 185 for preventing lateral displacement of the cover glass 4 supported on the glass support surface 23 is formed, and functions as a portion for positioning the cover glass 4 relative to the frame main body portion 26.

In the illustrated example, the dimension of the step forming portion 181 in the up-down direction is larger than the plate thickness dimension of the cover glass 4. However, the dimension in the up-down direction of the step forming portion 181 may be about the same as the plate thickness dimension of the cover glass 4, or may be smaller than the plate thickness dimension of the cover glass 4.

The bonding portion 182 is a portion including an adhesive for fixing the cover glass 4 to the frame main body portion 26. As the adhesive forming the bonding portion 182, a pressure-sensitive adhesive that performs temporary adhesion is used. The bonding portion 182 is, for example, a peeling material that changes its state when receiving external energy and thus has peelability so as to easily separate the cover glass 4 from the frame 6.

As the material of the bonding portion 182, for example, a peeling material is used that changes from a state in which the adhesive strength is relatively strong to a state that allows for easy peeling (state in which the adhesive strength is lowered) by a chemical reaction or a physical reaction. The chemical reaction may be, for example, irradiation with light such as ultraviolet (UV) light or laser light, heating to a temperature within a predetermined temperature range, or the like. The peeling material of UV easy peeling type is, for example, a pressure-sensitive adhesive whose adhesive strength is reduced by irradiation with UV. Additionally, the physical reaction is, for example, laser ablation or the like. Furthermore, as a material of the bonding portion 182, for example, a photocurable material such as a UV curable resin, a thermosetting material such as a thermosetting resin, or a material using a mixture thereof as a base material can be used.

Furthermore, as the adhesive forming the bonding portion 182, for example, a polyamide-base or polyester-based hot melt adhesive can be used. Note that the hot melt adhesive is an adhesive containing neither water nor an organic solvent, is solid at room temperature, and becomes liquid when heated.

The bonding portion 182 is interposed between the glass support surface 23 and the peripheral edge portion of the lower surface 4b of the cover glass 4, and bonds these surfaces. The bonding portion 182 is formed so as to entirely cover the glass support surface 23 by applying a pressure-sensitive adhesive to the glass support surface 23, which is a portion inside the step forming wall portion 183 on the upper side of the wall portion 20. Therefore, the bonding portion 182 has four side portions 182a along the frame shape of the frame-shaped main body portion 126 in plan view.

Note that the mode of applying a pressure-sensitive adhesive to the glass support surface 23, that is, the mode of forming the bonding portion 182 is not particularly limited. The pressure-sensitive adhesive may be applied to the glass support surface 23, for example, linearly in a discontinuous manner in the extending direction of the glass support surface 23 in each wall portion 20, may be applied in multiple parallel lines, or may be applied in a dotted manner to multiple positions. Additionally, the application amount and the application area of the pressure-sensitive adhesive may be set according to the size and the like of the cover glass 4 so that the holding force (adhesive strength) required for the cover glass 4 can be secured.

### 11. Method for Manufacturing Solid-State Imaging Device According to Fourth Embodiment

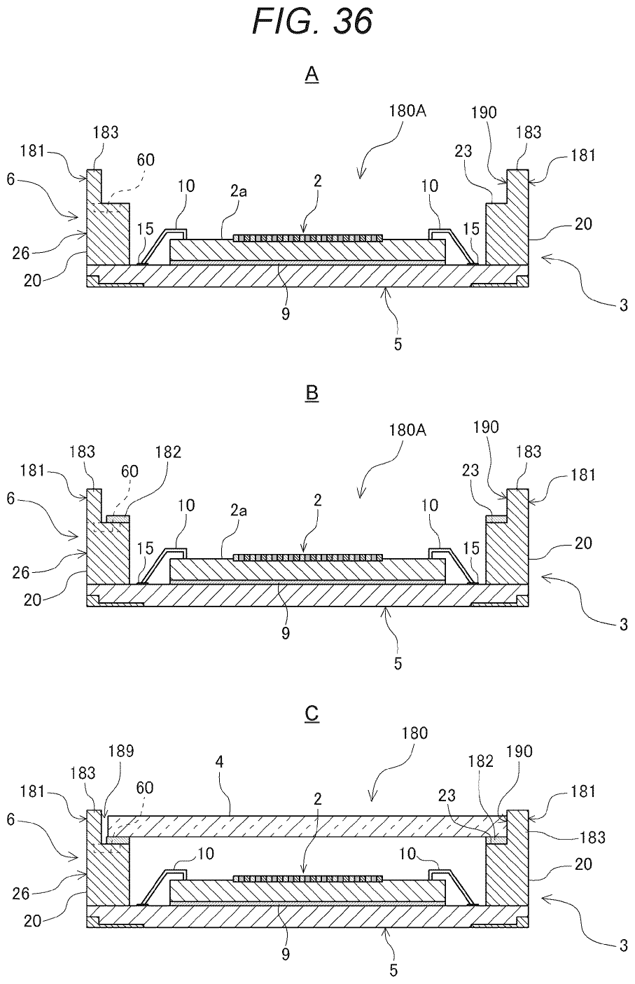

An example of a method for manufacturing the solid-state imaging device 180 according to a fourth embodiment of the present technology will be described with reference to FIG. 36.

As illustrated in FIG. 36A, similarly to the first embodiment, the step of manufacturing the package main body portion 3 is performed by a frame mounting step of providing the frame 6 on the substrate 5. Thereafter, the image sensor unit 180A is obtained by performing the step of die-bonding the image sensor 2 and the step of wire bonding for wires 10 on the package main body portion 3.

Next, as illustrated in FIG. 36B, the step of forming the bonding portion 182 on the glass support surface 23 of the frame 6 is performed. The bonding portion 182 is a peeling layer formed between the glass support surface 23 and the cover glass 4, and is provided for the purpose of separating the cover glass 4 from the frame 6. The bonding portion 182 is formed by applying a pressure-sensitive adhesive for forming the bonding portion 182 on the glass support surface 23 with a dispenser or the like. Note that the bonding portion 182 may be formed by bonding a sheet-shaped member such as a peeling tape to the glass support surface 23.

Then, as illustrated in FIG. 36 C, for example, a chip mounter or the like is used, the cover glass 4 is fitted to the opening portion 190 by the step forming portion 181, and the cover glass 4 is fixed on the glass support surface 23 through the bonding portion 182. Here, a treatment process for curing the bonding portion 182, such as light irradiation or heating, is performed according to the characteristics of the bonding portion 182. Additionally, the position of the cover glass 4 on the glass support surface 23 is adjusted such that the gap 189 is formed on the left side of the cover glass 4 where the recess 60 is located.

By attaching the cover glass 4 as described above, the solid-state imaging device 180 is obtained. In the solid-state imaging device 180, the cover glass 4 is in a state in which the cover glass 4 is temporarily fixed to the frame 6 in a sense by the bonding portion 182, which includes a pressure-sensitive adhesive of a type that is easily peelable by heat, UV, stress, or the like.

### 12. Use Example of Solid-State Imaging Device According to Fourth Embodiment

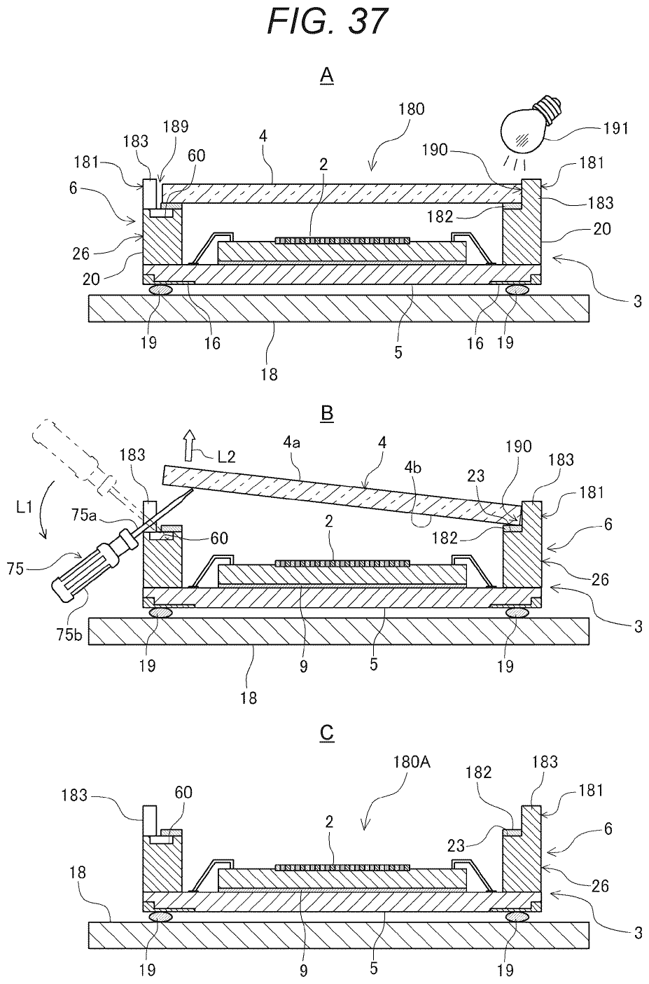

As a use example of the solid-state imaging device 1 according to the first embodiment of the present technology, how to remove the cover glass 4 will be described with reference to FIG. 37. That is, as one mode of use of the solid-state imaging device 180, the solid-state imaging device is used with the cover glass 4, which is once attached to the package main body portion 3, removed.

For example, as illustrated in FIG. 37A, the cover glass 4 is removed in a state in which the solid-state imaging device 180 is reflow-mounted on the set substrate 18 by solder balls 19.

First, by irradiating or heating the bonding portion 182 with light of a predetermined wavelength such as UV light, for example, the bonding portion 182 is brought into a state in which the adhesive strength is reduced, that is, an easily peelable state. As illustrated in FIG. 37A, in a case where the bonding portion 182 is irradiated with light by a light source 191, light applied from the side corresponding to the transparent or translucent cover glass 4 is transmitted through the cover glass 4 and applied to the bonding portion 182. Here, in a case where UV light is used as irradiation light to the bonding portion 182, glass having high transmittance with respect to the wavelength of UV light is used as the cover glass 4.

After the adhesive strength of the bonding portion 182 is reduced, the cover glass 4 is removed using the principle of leverage with the tool 75. As shown in FIG. 37B, the tip of the shaft portion 75a of the tool 75 is inserted into the recess 60 of the frame 6 through the exposed portion 60a (see FIG. 32), and then the tool 75 is operated so as to push down the side corresponding to the grip portion 75b downward (see the arrow L1), whereby the tool 75 acts so as to bring the tip into contact with the lower surface 4b of the cover glass 4 and lift the cover glass 4 using the principle of leverage (see the arrow L2). Since the adhesive strength of the bonding portion 182 is reduced, the cover glass 4 is easily peeled off from the glass support surface 23.

In the operation of removing the cover glass 4 using the tool 75, since there is a gap 189 (see FIG. 37A) between the cover glass 4 and the left step forming wall portion 183, the cover glass 4 is smoothly lifted without interfering with the step forming wall portion 183. Then, the cover glass 4 is removed from the frame 6 by pulling out the cover glass 4 from the opening portion 190 formed by the step forming portion 181.

As described above, as illustrated in FIG. 37C, a configuration in which the image sensor unit 180A is mounted on the set substrate 18 is obtained. Note that in a state in which the cover glass 4 is removed, a part of the bonding portion 182 remains on at least one of the glass support surface 23 and the peripheral edge portion of the lower surface 4b of the cover glass 4.

According to the solid-state imaging device 180 according to the present embodiment as described above, the cover glass 4 can be easily attached and detached similarly to the solid-state imaging device 1 according to the first embodiment. In particular, the solid-state imaging device 180 of the present embodiment includes, as the cover holding portion, the step forming portion 181, which restricts the movement of the cover glass 4, and the bonding portion 182, which fixes the cover glass 4 to the glass support surface 23. According to such a configuration, it is possible to obtain a configuration in which the cover glass 4 can be easily removed without complicating the shape of the frame 6.

Additionally, with the configuration in which the step structure is provided by the step forming portion 181 on the upper outer peripheral portion of the frame 6, when the lens housing is attached to the image sensor unit 180A after the cover glass 4 is removed, the step forming portion 181 is used as a support portion of the lens housing, whereby the bonding portion 182 remaining on the side corresponding to the frame 6 can be prevented from adhering to the lens housing.

That is, according to the configuration including the step forming portion 181, in a state in which the cover glass 4 is removed, the step forming portion 181 exists as a portion where the pressure-sensitive adhesive for fixing the cover glass 4 does not remain at a position above the forming surface of the bonding portion 182. As a result, in the image sensor unit 180A in a state in which the cover glass 4 is removed, the step forming portion 181 can be used as, for example, a bonding portion to a housing or the like having a set structure, a bonding portion of a new component to the package main body portion 3, or the like. Additionally, the upper surface 188 of the step forming portion 181 can be used as a reference surface in, for example, adjustment of tilting when the image sensor unit 180A is attached to a set structure.

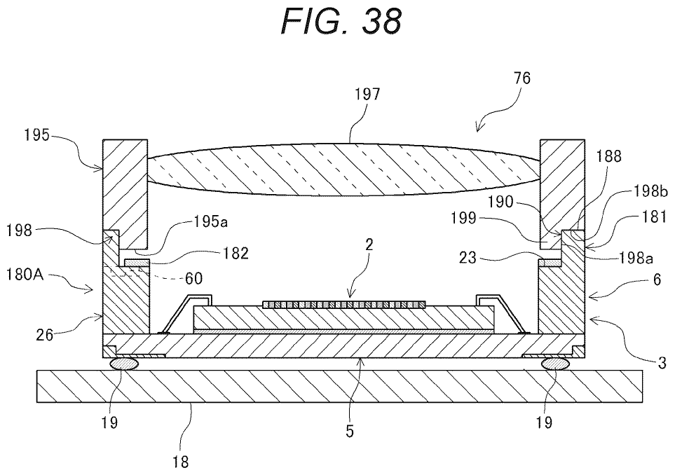

For example, as illustrated in FIG. 38, the step forming portion 181 in the image sensor unit 180A is used as a support portion for the lens housing 76 mounted on the image sensor unit 180A. The lens housing 76 has a support cylinder 195 formed in a quadrangular cylindrical shape corresponding to the shape of the step forming portion 181, and supports one or more lenses 197 in the support cylinder 195. The lens housing 76 is fixed to the frame 6 in a state in which the lower end portion of the support cylinder 195 is fitted to the step forming portion 181.

The lens housing 76 has a step portion 198 at the lower end portion of the support cylinder 195 in order to fit the step forming portion 181. The step portion 198 is a portion formed by cutting out the outer peripheral side of the lower end portion of the support cylinder 195 so as to form a right angle in longitudinal sectional view. The step portion 198 forms, on the inner peripheral side of the lower end portion of the support cylinder 195, a frame-shaped insertion port portion 199 to be inserted into the opening portion 190 formed by the step forming portion 181.

The step portion 198 has a side surface 198a and an outer lower surface 198b, which serve as contact surfaces with the inner side surface 186 and the upper surface 188, respectively, of the step forming wall portion 183, and is formed such that the step forming portion 181 is fitted to these surfaces. The lens housing 76 is fixed to the frame 6 by fitting the upper end portion of the step forming portion 181 to the step portion 198 of the support cylinder 195. That is, the lens housing 76 is attached to the frame 6 by inserting the insertion port portion 199 into the opening portion 190 on the side corresponding to the frame 6.

In a state in which the lens housing 76 is attached to the frame 6, the bottom surface 195a of the lens housing 76, which is a lower end surface of the insertion port portion 199 and is a lower opening end surface of the support cylinder 195, faces the glass support surface 23 at an upper position. That is, the lens housing 76 is provided such that the bottom surface 195a is located above and spaced apart from the bonding portion 182 on the glass support surface 23. Note that in fixing the support cylinder 195 to the step forming portion 181 of the frame 6, an adhesive or a fixing tool such as a bolt is appropriately used.

As described above, when the lens housing 76 is installed on the image sensor unit 180A in a state in which the cover glass 4 is removed, the step forming portion 181 provided on the frame 6 can be used as a fixing portion of the lens housing 76 relative to the frame 6.

According to such a configuration, for example, as compared with a case where the lens housing 76 is installed relative to the set substrate 18, the lens housing 76 can be installed in a portion on the package side where the accuracy regarding the optical axis adjustment of the image sensor 2 can be relatively easily obtained. As a result, the upper surface 188 of the step forming portion 181, for example, can be used as a reference surface, and the lens housing 76 can be accurately provided relative to the image sensor 2 without being affected by inclination due to solder connection to the set substrate 18.

In addition, the frame 6 has the recess 60 opening portion at the glass support surface 23. According to such a configuration, the tool 75 can easily act on the cover glass 4, and the cover glass 4 can be easily removed in a state in which the adhesive strength of the bonding portion 182 is reduced.

Note that in the solid-state imaging device 180, the frame 6 may not form the recess 60. When the recess 60 is not formed in the frame 6, the step forming portion 181 can be formed over the entire periphery so as to form a frame shape in plan view without separating the step forming wall portion 183 on the left side. In this case, the gap 189 between the cover glass 4 and the left step forming wall portion 183 may not be formed.

### 13. Modification of Solid-State Imaging Device According to Fourth Embodiment

Modifications of the solid-state imaging device 1 according to the fourth embodiment of the present technology will be described.

### First Modification

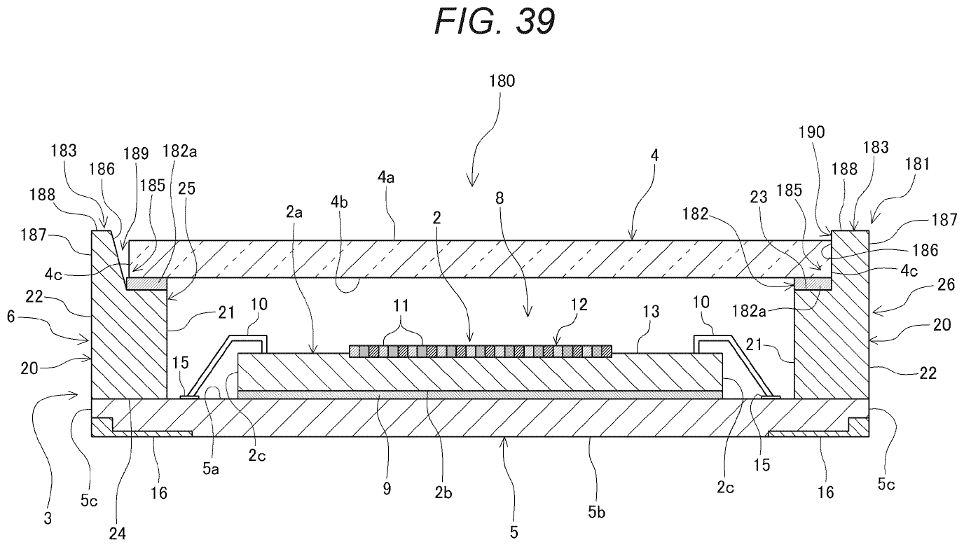

As illustrated in FIG. 39, in a solid-state imaging device 180 of a first modification, the inner side surface 186 forming the gap 189, which is formed between the step forming wall portion 183 and the cover glass 4 on the side of the frame 6 where the recess 60 is formed (left side), is an inclined surface. The inner side surface 186 is an inclined surface descending from the outer side in the left-right direction (left side) to the inner side in the left-right direction (right side).

That is, the inner side surface 186 is inclined such that the step forming wall portion 183 gradually tapers (narrows in width) from the lower side to the upper side in the cross-sectional view as illustrated in FIG. 39. Since the inner side surface 186 is an inclined surface in this manner, the gap 189 is a space portion gradually widened from the lower side to the upper side. In the illustrated example, the inclination angle of the inner side surface 186 with respect to the up-down direction is about 15°. However, the magnitude of the inclination of the inner side surface 186 is not particularly limited.

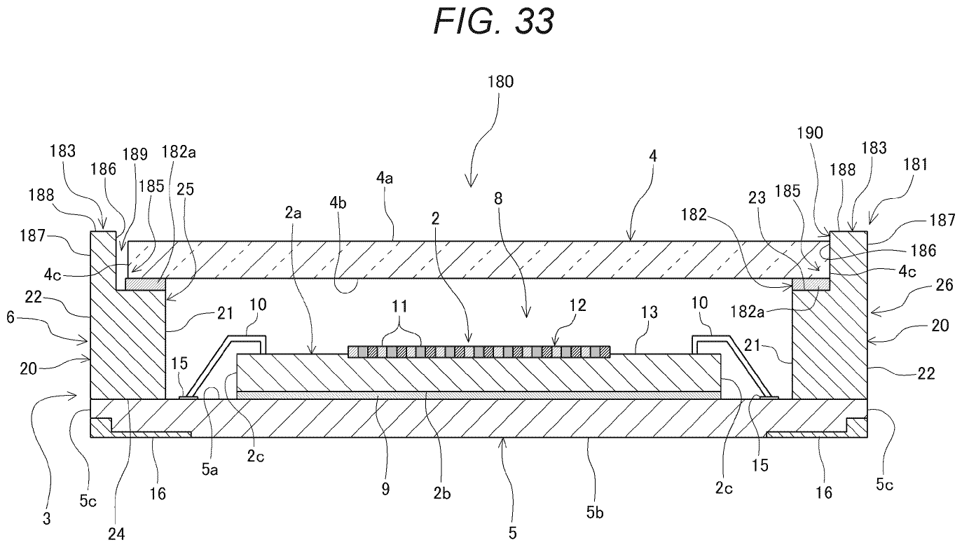

In this manner, the gap 189 may be formed by making the inner side surface 186 of the step forming wall portion 183 an inclined surface. The gap 189 enables the cover glass 4 to be smoothly lifted in the operation of removing the cover glass 4 using the tool 75 as described above. Note that similarly to FIG. 33, FIG. 39 is a diagram corresponding to a cross-sectional end view taken along line N-N in FIG. 32.

### Second Modification

Solid-state imaging devices 180 of second to fifth modifications have configurations that are suitable in a case where a hot melt adhesive is used as an adhesive for forming the bonding portion 182. In the second modification, the solid-state imaging device 180 includes, as a bonding portion formed by an adhesive that fixes the cover glass 4 to the glass support surface 23, a hot melt bonding portion 182B formed by a hot melt adhesive.

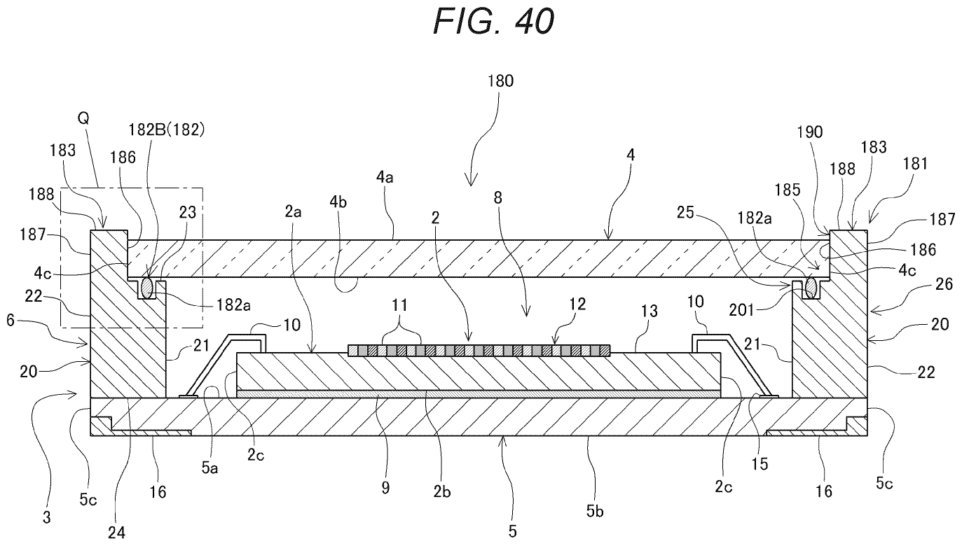

As illustrated in FIGS. 40 to 42, in the second modification, a groove portion 201 as a recessed portion for positioning the hot melt bonding portion 182B is formed in the glass support surface 23.

The groove portion 201 is a recessed portion that has a transverse cross-sectional shape substantially having the shape of letter “U” and has an open side on the upper side, and is formed linearly in the extending direction in plan view in each wall portion 20. The groove portion 201 has four side portions 201a along the plan view shape of the glass support surface 23, and is formed in a frame shape in plan view. However, the groove portion 201 may be partially formed, for example, in an intermittent manner with respect to the frame shape in plan view.

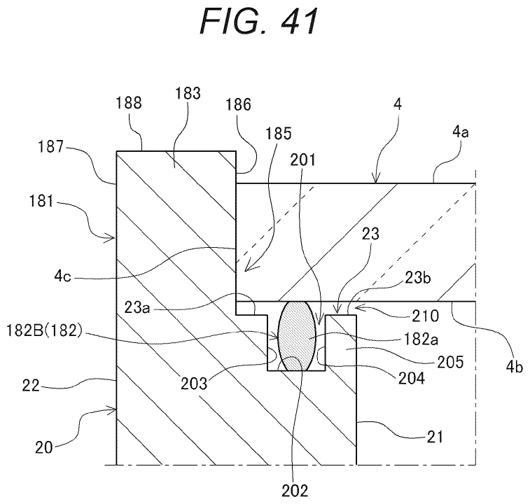

As illustrated in FIG. 41, the groove portion 201 has a bottom surface 202, an outer side surface 203, which is a side surface on the outer peripheral side, and an inner side surface 204, which is a side surface on the inner peripheral side. The bottom surface 202 is a step surface parallel to the glass support surface 23. A space in the groove portion 201 is an application space of the hot melt adhesive, that is, a formation space of the hot melt bonding portion 182B. By covering the groove portion 201 with the cover glass 4 from above, a passage-shaped hollow portion is formed along the extending shape of the groove portion 201.

The cover glass 4 is fixed to the frame 6 by a hot melt bonding portion 182B formed in the groove portion 201 with the lower surface 4b of the peripheral edge portion as an adhesion surface to the bottom surface 202 of the groove portion 201. The hot melt bonding portion 182B for fixing the cover glass 4 to the frame 6 is interposed between the bottom surface 202 of the groove portion 201 and the lower surface 4b of the cover glass 4. By forming the hot melt bonding portion 182B over the entire groove portion 201, which is formed in a frame shape over the entire periphery, the space between the frame 6 and the cover glass 4 is hermetically sealed.

As illustrated in FIG. 41, in the configuration in which the groove portion 201 is formed in the glass support surface 23, the wall portion 205 is formed on the inner peripheral side of the step portion 185. Also, in the configuration in which groove portion 201 is formed, the glass support surface 23 is separated into an outer peripheral support surface 23a, which is a portion on the outer peripheral side of the groove portion 201, and an inner peripheral support surface 23b, which is a portion on the inner peripheral side of the groove portion 201. At least one of the outer peripheral support surface 23a, the inner peripheral support surface 23b, and the bottom surface 202 of the groove portion 201 serves as a support surface that supports the cover glass 4. The bottom surface 202 supports the cover glass 4 through the hot melt bonding portion 182B. The inner peripheral support surface 23b is an upper surface of the wall portion 205. In the wall portion 205, the surface opposite to the inner side surface 204 of the groove portion 201 is an upper edge portion of the inner wall surface 21 of the wall portion 20.

In the example illustrated in FIG. 41, the gap 210 exists between the lower surface 4b of the cover glass 4 and the glass support surface 23, but the gap 210 does not have to exist. The presence or absence of the gap 210 is related to the amount of the adhesive forming the hot melt bonding portion 182B, the size and depth of the groove portion 201, and the like. When there is no gap 210, the cover glass 4 is supported by the frame 6 in a state of being in contact with the outer peripheral support surface 23a and the inner peripheral support surface 23b. In this case, when the heights of the outer peripheral support surface 23a and the inner peripheral support surface 23b are different, the cover glass 4 is in contact with the support surface that is the higher one of the outer peripheral support surface 23a and the inner peripheral support surface 23b.

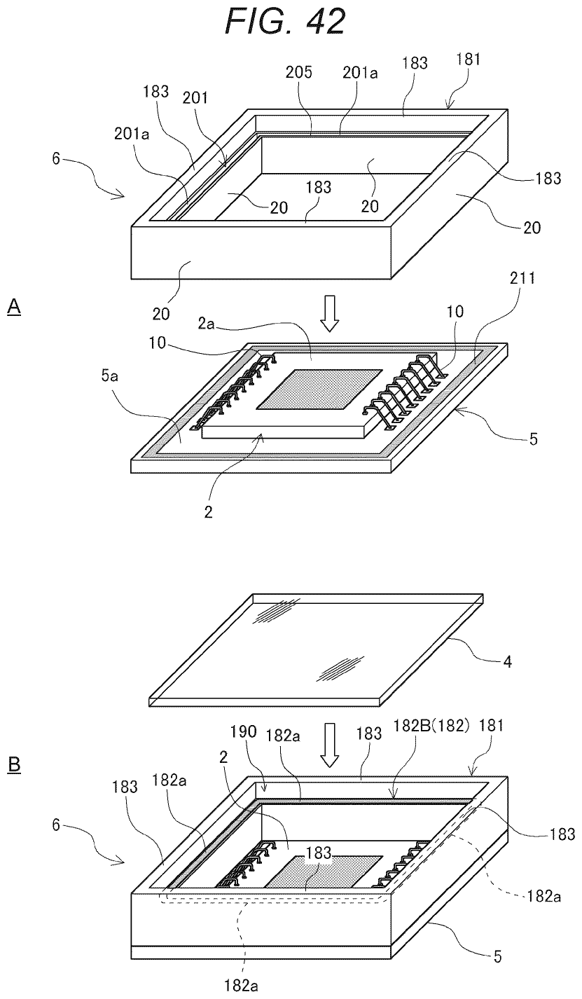

A method for manufacturing the configuration of the second modification will be described with reference to FIG. 42. As for the configuration of the second modification, the frame 6 having the step forming portion 181 and the groove portion 201 is manufactured by, for example, injection molding using a mold such as a transfer mold. Regarding the frame 6, when the frame 6 is a frame including resin, for example, a frame assembly in an assembled state in which multiple frame elements to be the frame 6 are connected is integrally molded by a mold, and the frame assembly is divided into individual pieces for each frame element, thereby manufacturing the frame 6.

As illustrated in FIG. 42A, the frame 6 is fixed to the substrate 5, which is subjected to the step of die-bonding the image sensor 2 and the step of wire bonding for wires 10, with an adhesive 211 such as an epoxy resin adhesive. The adhesive 211 is applied in a frame shape along the outer shape of the substrate 5 on the surface 5a corresponding to the shape of the frame 6 in plan view. Note that the adhesive 211 may be applied to the frame 6.

After the frame mounting step of providing the frame 6 on the substrate 5, the step of attaching the cover glass 4 to the frame 6 is performed. In the step of attaching the cover glass 4, as illustrated in FIG. 42B, the hot melt bonding portion 182B is formed in the groove portion 201 of the frame 6. The hot melt bonding portion 182B is formed by applying a hot melt adhesive in the groove portion 201 over the entire periphery by, for example, a hot melt dispenser. As the hot melt adhesive, for example, a material that melts at a reflow temperature (for example, about 260° C.) when the solid-state imaging device 180 is reflow-mounted on the set substrate 18 (see FIG. 37A) is used.

The hot melt bonding portion 182B may be partially formed with respect to the groove portion 201 having a frame shape in plan view. The hot melt bonding portion 182B may be formed, for example, only at four corner portions of the frame-shaped groove portion 201, or may be formed with respect to a pair of opposing side portions 201a among the four side portions 201a of the groove portion 201.

After the hot melt adhesive is applied into the groove portion 201, the cover glass 4 is fitted to the opening portion 190 formed by the step forming portion 181 by a chip mounter or the like, and the cover glass 4 is fixed by the hot melt bonding portion 182B. As described above, the solid-state imaging device 180 in which the cover glass 4 is fixed to the frame 6 by the hot melt bonding portion 182B is obtained.

When the cover glass 4 is removed, the hot melt bonding portion 182B is heated at a predetermined temperature to convert the hot melt bonding portion 182B into a liquid. The cover glass 4 is removed from the frame 6 in a state in which the hot melt bonding portion 182B is in a liquid state. For example, as described above, the cover glass 4 is removed using the principle of leverage with the tool 75, or is removed by causing a predetermined jig or device to be adsorbed to the upper surface 4a of the cover glass 4 and pulling up the cover glass 4.

According to the configuration of the second modification, since the frame 6 has the groove portion 201 as a formation space of the bonding portion for fixing the cover glass 4, it is possible to suppress protrusion of the molten hot melt material from the glass support surface 23 in the step of forming the hot melt bonding portion 182B, during reflow mounting of the solid-state imaging device 180, or when the cover glass 4 is removed. Additionally, since the frame 6 has the step forming portion 181 that restricts the movement of the cover glass 4 on the glass support surface 23, it is possible to prevent lateral displacement of the cover glass 4 due to a flow of the hot melt bonding portion 182B or the like in a state in which the hot melt bonding portion 182B is melted.

Additionally, by providing the hot melt bonding portion 182B on the entire periphery along the frame shape of the frame 6, airtightness of the cavity 8 can be secured, and a decrease in reliability due to moisture absorption and intrusion of dust into the cavity 8 can be suppressed. Additionally, since moisture absorption in the cavity 8 can be suppressed, it is possible to suppress an increase in the internal pressure of the cavity 8 at the time of reflow or the like.

### Third Modification

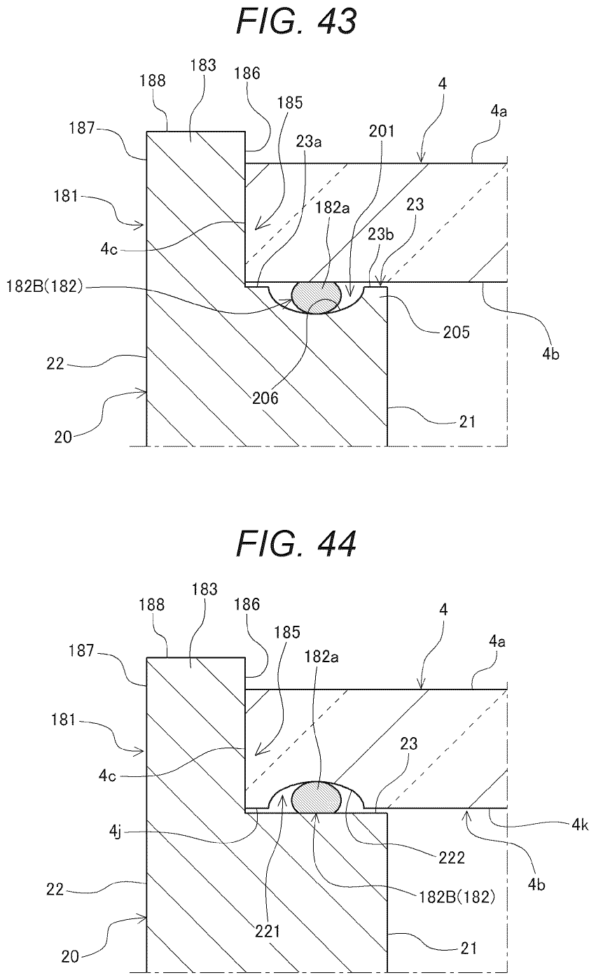

The third modification is a modification regarding the groove portion 201 formed in the frame 6 for arrangement of the hot melt bonding portion 182B. As illustrated in FIG. 43, in the configuration of the third modification, the groove portion 201, in which the hot melt bonding portion 182B is positioned, is formed by a concave curved surface 206 having a curved shape in a side cross-sectional view of the solid-state imaging device 180.

In the example illustrated in FIG. 43, the concave curved surface 206 has a substantially semi-elliptical shape in a side cross-sectional view and is formed substantially symmetrically. In the configuration of the third modification, the wall portion 205 forming the inner peripheral support surface 23b is formed on the inner peripheral side of the concave curved surface 206. At least one of the outer peripheral support surface 23a, the inner peripheral support surface 23b, and the concave curved surface 206 of the groove portion 201 serves as a support surface that supports the cover glass 4. The concave curved surface 206 supports the cover glass 4 through the hot melt bonding portion 182B.

As described above, the groove shape (transverse cross-sectional shape) of the groove portion 201 may be a curved shape or the like, and the groove shape of the groove portion 201 is not particularly limited. However, from the viewpoint of manufacturing the frame 6 by injection molding using a mold, the groove shape of the groove portion 201 is preferably a shape not having a portion that forms an angle less than perpendicular with respect to the moving direction of the mold (negative angle portion).

### Fourth Modification

As illustrated in FIG. 44, in the fourth modification, the groove portion 201 is not formed on the side corresponding to the glass support surface 23 of the frame 6, and the groove portion 221 as a recessed portion for positioning the hot melt bonding portion 182B is formed in the lower surface 4b of the cover glass 4 facing the glass support surface 23. That is, the groove portion 221 is formed in a peripheral edge portion of the lower surface 4b of the cover glass 4, which is a portion facing the glass support surface 23. The groove portion 221 is formed in a frame shape along the outer shape of the cover glass 4. However, the groove portion 221 may be partially formed in an intermittent manner with respect to the frame shape, for example.

In the example illustrated in FIG. 44, the groove portion 221 is formed by a concave curved surface 222 having a curved shape in a side cross-sectional view of the solid-state imaging device 180. The concave curved surface 222 has a substantially semi-elliptical shape in a side cross-sectional view and is formed substantially symmetrically. The groove portion 221 may be a recessed portion that has a transverse cross-sectional shape substantially having the shape of letter “U” and has an open side on the lower side, for example, and the groove shape (transverse cross-sectional shape) of the groove portion 221 is not particularly limited. By covering the groove portion 221 with the glass support surface 23 from below, a passage-shaped hollow portion is formed along the extending shape of the groove portion 221.

In the configuration in which the groove portion 221 is formed in the cover glass 4, the lower surface 4b of the cover glass 4 is separated into an outer side surface portion 4j, which is a portion outward of the groove portion 221, and an inner side surface portion 4k, which is a portion inward of the groove portion 221. At least one of the outer side surface portion 4j, the inner side surface portion 4k, and the concave curved surface 222 of the groove portion 221 is a surface that is supported by the glass support surface 23. The concave curved surface 222 is supported by the glass support surface 23 through the hot melt bonding portion 182B.

As described above, the shape portion forming the arrangement space of the hot melt bonding portion 182B may be formed on the side corresponding to the cover glass 4. The groove portion 221 is formed by, for example, cutting or etching the cover glass 4 with a dicing blade or the like. According to the configuration of the fourth modification, the cover glass 4 can be easily removed from the frame 6 by heating and melting the hot melt bonding portion 182B.

### Fifth Modification

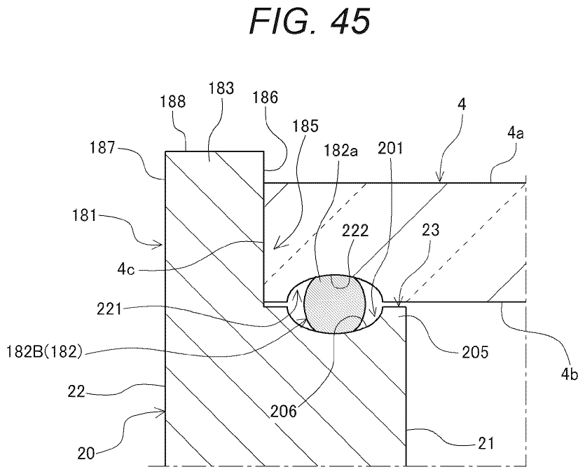

In the fifth modification, a shape portion forming an arrangement space of the hot melt bonding portion 182B is formed on both the side corresponding to the frame 6 and the side corresponding to the cover glass 4. That is, as illustrated in FIG. 45, groove portions 201 and 221, in which the hot melt bonding portion 182B is positioned, are formed on the glass support surface 23 of the frame 6 and the lower surface 4b of the cover glass 4.

In the example illustrated in FIG. 45, the groove portion 201 on the side corresponding to the frame 6 and the groove portion 221 on the side corresponding to the cover glass 4 are formed to be substantially vertically symmetrical. The upper and lower groove portions 201 and 221 form a passage-shaped hollow portion that follows the extending shape of these groove portions and has a horizontally long substantially elliptical transverse cross-sectional shape.

As described above, the shape portion forming the arrangement space of the hot melt bonding portion 182B may be formed on both the side corresponding to the frame 6 and the side corresponding to the cover glass 4. That is, the shape portion forming the arrangement space of the hot melt bonding portion 182B is formed on at least one of the glass support surface 23 of the frame 6 and the lower surface 4b of the cover glass 4.

According to the configuration of the fifth modification, as compared with the configuration in which the groove portion 201, 221 is formed in one of the frame 6 and the cover glass 4, it is easy to secure the volume of the space in which the hot melt bonding portion 182B is arranged. Note that the groove portion 201 on the side corresponding to the frame 6 and the groove portion 221 on the side corresponding to the cover glass 4 may have different shapes, and the shape of each groove portion, the positional relationship between the groove portions, and the like are not particularly limited.

### 14. Configuration Example of Solid-State Imaging Device According to Fifth Embodiment

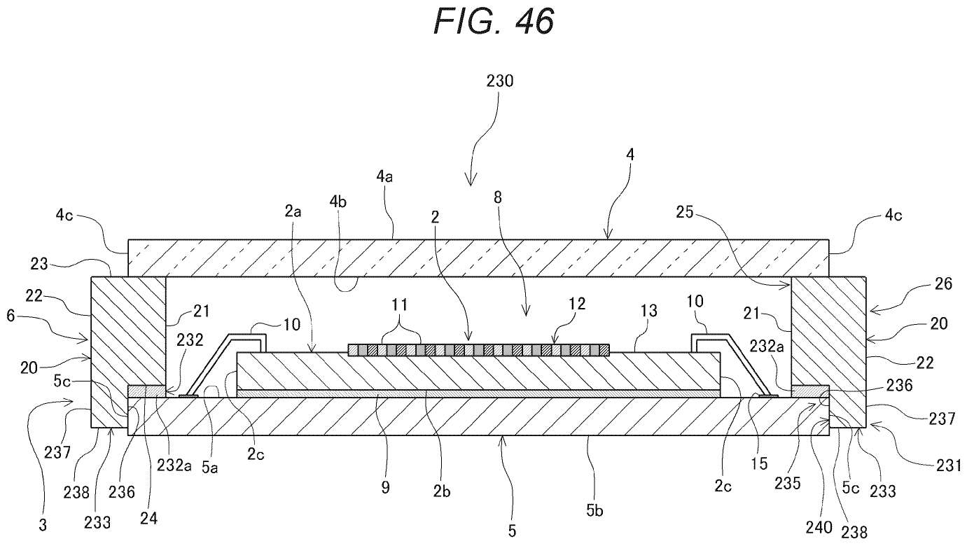

A configuration example of a solid-state imaging device 230 according to a fifth embodiment of the present technology will be described with reference to FIG. 46. In the solid-state imaging device 230 according to the present embodiment, the frame 6 that supports the cover glass 4 is detachably provided relative to the substrate 5. That is, regarding the fixing structure of the frame 6 relative to the substrate 5, the solid-state imaging device 230 includes a frame holding portion that detachably holds the frame 6 relative to the substrate 5.

In the solid-state imaging device 230, the cover glass 4 is fixed to the glass support surface 23 of the frame 6. The cover glass 4 is fixed to the frame 6 by an adhesive including, for example, a photocurable resin such as a thermosetting resin or an ultraviolet (UV) curable resin, with the lower surface 4b of the peripheral edge portion serving as the bonding surface to the glass support surface 23.

The solid-state imaging device 230 includes, as the frame holding portion, a step forming portion 231, which is provided below the frame main body portion 26, and a bonding portion 232, which is interposed between the frame main body portion 26 and the substrate 5.

The step forming portion 231 is a portion formed as a part of the frame 6, and is provided as a protruding portion extending downward from the lower surface 24 of the frame main body portion 26. The step forming portion 231 is a portion that forms a step portion 235 relative to the lower surface 24 of the frame main body portion 26 and is in contact with the side surface 5c of the substrate 5 to restrict the movement of the substrate 5 relative to the frame 6.

The step forming portion 231 is a wall-shaped portion formed over substantially the entire periphery along the frame shape of the frame main body portion 26 in bottom view relative to the frame main body portion 26 configured in a frame shape by the four wall portions 20. Therefore, the step forming portion 231 includes four step forming wall portions 233 formed on the lower sides of the respective wall portions 20, and these step forming wall portions 233 form a frame shape in bottom view.

The step forming portion 231 is provided on the lower sides of the wall portions 20 so that the step forming wall portions 233 are located on the outer side in the wall thickness direction of the wall portions 20 (the side corresponding to the outer wall surface 22), and forms the step portion 235 together with the lower surface 24. The step forming portion 231 includes an inner side surface 236, which is an inner wall surfaces of the step forming wall portions 233 and serves as a contact surface with the side surface 5c of the substrate 5, an outer side surface 237, which is a wall surface opposite to the inner side surface 236, and a horizontal lower surface 238. The step forming portion 231 is formed such that the outer side surface 237 is located on the same plane as the outer wall surface 22 of the wall portion 20.

The step forming wall portions 233 are provided at the respective wall portions 20 over the entire ranges of the wall portions 20 in the extending direction in bottom view. However, the step forming wall portion 183 may be provided on the corresponding wall portion 20 partially along the extending direction of the wall portion 20 or provided at multiple positions.

In the step forming portion 231, the lower surface 238 of each step forming wall portion 233 is a step surface that is lower with respect to the lower surface 24 of the frame main body portion 26. At the step portion 235, the inner side surface 236 is positioned outside the inner wall surface 21 of the wall portion 20 and is formed as a surface parallel to the inner wall surface 21. In the example illustrated in FIG. 46, the step forming wall portion 233 has a wall thickness of about ½ of the wall thickness of the wall portion 20. However, the dimension of the wall thickness of the step forming wall portion 233 is not particularly limited.

The step forming portion 231 has a rectangular opening portion 240, which is formed by the four step forming wall portions 233 and opens downward corresponding to the outer shape of the substrate 5. The opening portion 240 has an opening dimension that is substantially the same as or slightly larger than the outer dimension of the substrate 5 in plan view. The step forming portion 231 restricts the relative movement of the frame 6 in the horizontal direction relative to the substrate 5 by coming into contact with the side surface 5c of the substrate 5 at the inner side surface 236 in a state in which the substrate 5 is fitted in the opening portion 240. In a state in which the substrate 5 is fitted in the opening portion 240, the four side surfaces 5c are contact surfaces or opposing surfaces with respect to the inner side surfaces 236 of the step forming wall portions 233. As described above, the step forming portion 231 is a portion where the step portion 235 for preventing lateral displacement of the substrate 5 relative to the frame 6 is formed, and functions as a portion for positioning the substrate 5 relative to the frame main body portion 26.

In the illustrated example, the dimension of the step forming portion 231 in the up-down direction is smaller than the plate thickness dimension of the substrate 5. However, the dimension in the up-down direction of the step forming portion 231 may be about the same as the plate thickness dimension of the substrate 5, or may be larger than the plate thickness dimension of the substrate 5.

The bonding portion 232 is a portion including an adhesive for fixing the frame main body portion 26 to the substrate 5. As the adhesive forming the bonding portion 232, a pressure-sensitive adhesive that performs temporary adhesion is used. The bonding portion 232 is, for example, a peeling material that changes its state when receiving external energy and thus has peelability so as to easily separate the cover glass 4 from the frame 6. Since the material of the bonding portion 232 is similar to the material of the bonding portion 182 according to the fourth embodiment, the description thereof will be omitted.

The bonding portion 232 is interposed between the lower surface 24 of the frame-shaped main body portion 126 and the peripheral edge portion of the surface 5a of the substrate 5, and bonds these surfaces. The bonding portion 232 is formed so as to entirely cover the lower surface 24 by applying a pressure-sensitive adhesive to the lower surface 24, which is a portion inside the step forming wall portion 233 on the lower side of the wall portion 20. Therefore, the bonding portion 232 has four side portions 232a along the frame shape of the lower surface 24 in bottom view.

Note that a mode of applying a pressure-sensitive adhesive to the lower surface 24 of the frame-shaped main body portion 126, that is, a mode of forming the bonding portion 232 is not particularly limited. The pressure-sensitive adhesive may be applied to the lower surface 24, for example, linearly in a discontinuous manner in the extending direction of the lower surface 24 in each wall portion 20, may be applied in multiple parallel lines, or may be applied in a dotted manner to multiple positions. Additionally, the application amount and the application area of the pressure-sensitive adhesive are set according to the size and the like of the substrate 5 so that the holding force (adhesive strength) required for the substrate 5 can be secured.

### 15. Method for Manufacturing Solid-State Imaging Device According to Fifth Embodiment

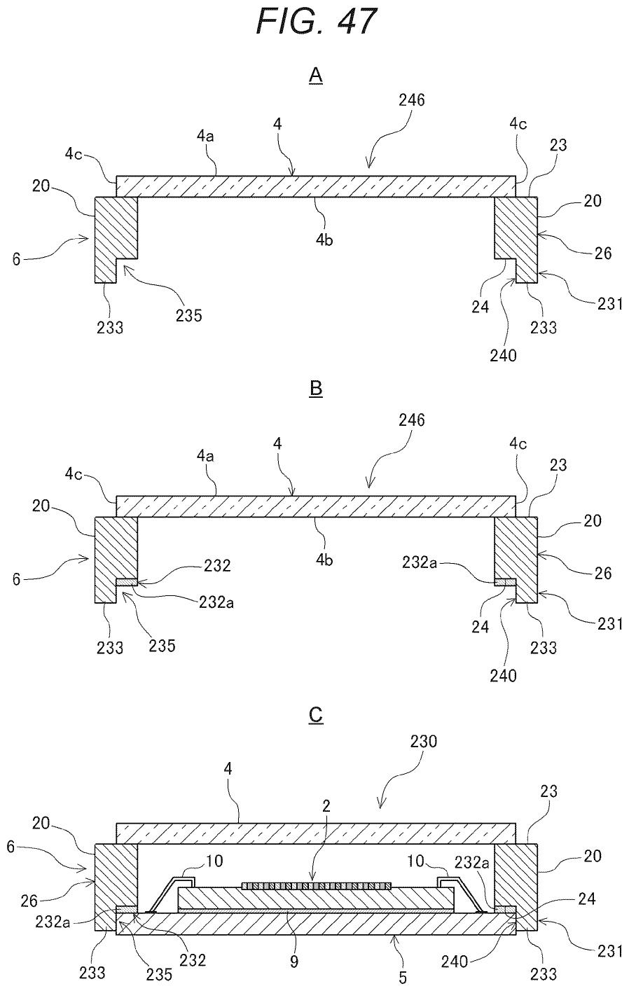

An example of a method for manufacturing the solid-state imaging device 230 according to the fifth embodiment of the present technology will be described with reference to FIG. 47.

As illustrated in FIG. 47A, in the method for manufacturing the solid-state imaging device 230, the step of manufacturing a frame with glass 246 by fixing a cover glass 4 to the glass support surface 23 of a frame 6 is performed. The frame 6 having a step forming portion 231 is manufactured by injection molding using a mold such as a transfer mold. The cover glass 4 is fixed to the glass support surface 23 with an adhesive so as to close the entire opening portion 25 of the frame 6.

Next, as illustrated in FIG. 47B, the step of forming a bonding portion 232 on the lower surface 24 of the frame 6 is performed. The bonding portion 232 is a peeling layer formed between the lower surface 24 and the substrate 5, and is provided for the purpose of separating the frame 6 from the substrate 5. The bonding portion 232 is formed by applying a pressure-sensitive adhesive for forming the bonding portion 232 to the lower surface 24 with a dispenser or the like. The bonding portion 232 may be formed by attaching a sheet-shaped member such as a peeling tape to the lower surface 24.

On the other hand, as the configuration to which the frame with glass 246 is attached, a sensor mounting substrate having a configuration in which the step of die-bonding the image sensor 2 to the substrate 5 and the step of wire bonding for the wire 10 are performed is manufactured.

Then, as illustrated in FIG. 47C, for example, a chip mounter or the like is used to fit the substrate 5 to the opening portion 240 formed by the step forming portion 231, and the frame 6 is fixed on the surface 5a of the substrate 5 through the bonding portion 232. Here, a treatment process for curing the bonding portion 232, such as light irradiation or heating, is performed according to the characteristics of the bonding portion 232.

By attaching the frame with glass 246 as described above, the solid-state imaging device 230 is obtained. In the solid-state imaging device 230, the frame with glass 246 is in a state in which the frame with glass 246 is temporarily fixed to the substrate 5 in a sense by the bonding portion 232, which includes a pressure-sensitive adhesive of a type that is easily peelable by heat, UV, stress, or the like. Note that when the frame with glass 246 is attached to the substrate 5, the bonding portion 232 may be formed on the side corresponding to the substrate 5. Furthermore, the step of fixing the cover glass 4 to the frame 6 after fixing the frame 6 to the substrate 5 may be performed.

In the solid-state imaging device 230 according to the present embodiment, as the removal of the cover glass 4, the frame with glass 246 is removed from the substrate 5. When the frame with glass 246 is removed, the bonding portion 232 is irradiated with light of a predetermined wavelength such as UV light or heated, for example, so that the bonding portion 232 is brought into a state in which the adhesive strength is reduced, that is, an easily peelable state. Then, the frame with glass 246 is removed from the substrate 5 in a state in which the adhesive strength of the bonding portion 232 is reduced. By removing the frame with glass 246 from the solid-state imaging device 230, a sensor mounting substrate is obtained. Note that in a state in which the frame with glass 246 is removed, a part of the bonding portion 232 remains on at least one of the lower surface 24 of the frame 6 and the peripheral edge portion of the surface 5a of the substrate 5.

According to the solid-state imaging device 230 according to the present embodiment as described above, the cover glass 4 can be easily attached and detached together with the frame 6 as the frame with glass 246. In particular, the solid-state imaging device 230 of the present embodiment includes, as the frame holding portion, the step forming portion 231 that restricts the movement of the frame 6 relative to the substrate 5, and the bonding portion 232 that fixes the frame 6 to the substrate 5. According to such a configuration, it is possible to obtain a configuration in which the cover glass 4 can be easily removed without complicating the shape of the frame 6.

### 16. Modification of Solid-State Imaging Device According to Fifth Embodiment

Modifications of the solid-state imaging device 230 according to the fifth embodiment of the present technology will be described. The solid-state imaging device 230 of the modifications described below has a configuration that is suitable in a case where a hot melt adhesive is used as an adhesive for forming the bonding portion 232. In the modifications according to the fifth embodiment, the solid-state imaging device 230 includes a hot melt bonding portion 232B including a hot melt adhesive as a bonding portion including an adhesive for fixing the frame main body portion 26 to the substrate 5.

### First Modification

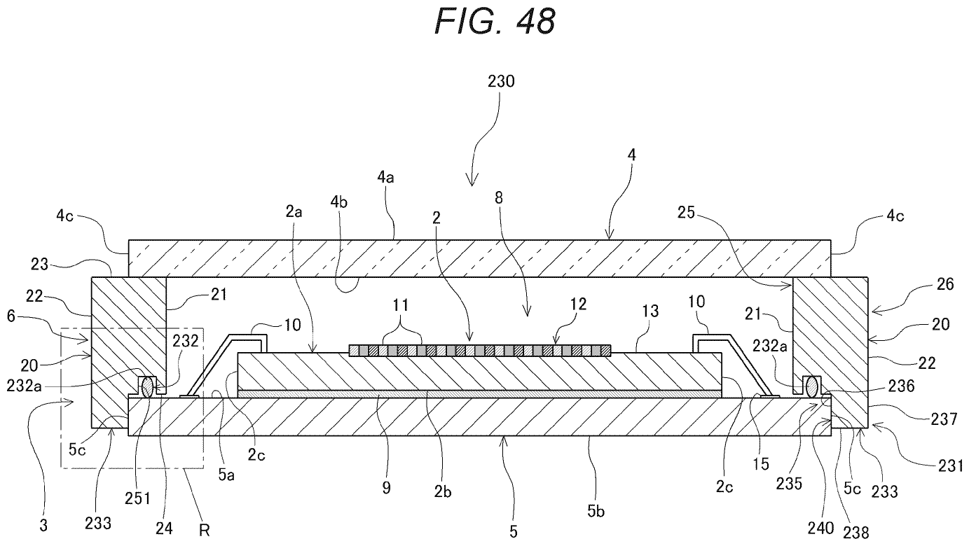

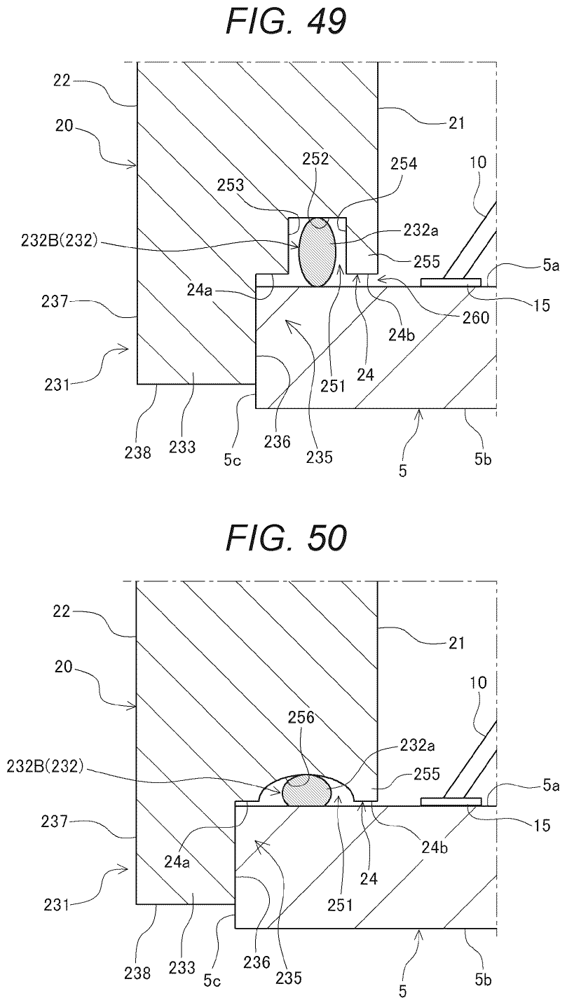

As illustrated in FIGS. 48 and 49, in a first modification, a groove portion 251 as a recessed portion for positioning the hot melt bonding portion 232B is formed on the lower surface 24 of the frame main body portion 26.

The groove portion 251 is a recessed portion that has a transverse cross-sectional shape substantially having the shape of letter “U” and has an open side on the lower side, and is formed linearly along the extending direction in bottom view in each wall portion 20. The groove portion 251 has four side portions along bottom view shape of the lower surface 24, and is formed in a frame shape in bottom view. However, the groove portion 251 may be partially formed, for example, in an intermittent manner with respect to the frame shape in plan view.

As illustrated in FIG. 49, the groove portion 251 has an upper surface 252, which is a bottom surface of the groove, an outer side surface 253, which is a side surface on the outer peripheral side, and an inner side surface 254, which is a side surface on the inner peripheral side. The upper surface 252 is a step surface parallel to the lower surface 24. The space in the groove portion 251 is an application space of the hot melt adhesive, that is, a formation space of the hot melt bonding portion 232B. By covering the groove portion 251 with the substrate 5 from below, a passage-shaped hollow portion is formed along the extending shape of the groove portion 251.

The substrate 5 is fixed to the frame 6 by a hot melt bonding portion 232B formed in the groove portion 251 with the surface 5a of the peripheral edge portion as an adhesion surface to the upper surface 252 of the groove portion 251. The hot melt bonding portion 232B for fixing the frame 6 to the substrate 5 is interposed between the upper surface 252 of the groove portion 251 and the surface 5a of the substrate 5. By forming the hot melt bonding portion 182B over the entire groove portion 251, which is formed in a frame shape over the entire periphery, the space between the substrate 5 and the frame 6 is hermetically sealed.

As illustrated in FIG. 49, in the configuration in which the groove portion 251 is formed in the lower surface 24 of the frame main body portion 26, a wall portion 255 is formed on the inner peripheral side of the step portion 235. Furthermore, in the configuration in which the groove portion 251 is formed, the lower surface 24 is separated into an outer peripheral lower surface 24a, which is a portion on the outer peripheral side of the groove portion 251, and an inner peripheral lower surface 24b, which is a portion on the inner peripheral side of the groove portion 251. At least one of the outer peripheral lower surface 24a, the inner peripheral lower surface 24b, and the upper surface 252 of the groove portion 251 is a surface that is supported by the substrate 5. The upper surface 252 is supported by the substrate 5 through the hot melt bonding portion 232B. The inner peripheral lower surface 24b is the lower surface of the wall portion 255. In the wall portion 255, a surface opposite to the inner side surface 254 of the groove portion 251 is a lower edge portion of the inner wall surface 21 of the wall portion 20.

In the example illustrated in FIG. 49, the gap 260 exists between the surface 5a of the substrate 5 and the lower surface 24 of the frame main body portion 26, but the gap 260 does not have to exist. The presence or absence of the gap 260 is related to the amount of the adhesive forming the hot melt bonding portion 232B, the size and depth of the groove portion 251, and the like. When there is no gap 260, the substrate 5 supports the frame 6 in a state of being in contact with the outer peripheral lower surface 24a and the inner peripheral lower surface 24b. In this case, when the heights of the outer peripheral lower surface 24a and the inner peripheral lower surface 24b are different from each other, the substrate 5 is in contact with the lower one of the outer peripheral lower surface 24a and the inner peripheral lower surface 24b.

According to the configuration of the first modification, since the groove portion 251 is provided as a formation space of the bonding portion for fixing the frame 6 to the substrate 5, it is possible to suppress protrusion of the molten hot melt material from the lower surface 24 of the frame main body portion 26 in the step of forming the hot melt bonding portion 232B, at the time of reflow mounting of the solid-state imaging device 230, or at the time of removing the frame with glass 246. Additionally, since the frame 6 has the step forming portion 231 that restricts the relative movement relative to the substrate 5, it is possible to prevent lateral displacement of the frame 6 due to a flow of the hot melt bonding portion 232B or the like in a state in which the hot melt bonding portion 232B is melted.

Additionally, by providing the hot melt bonding portion 232B on the entire periphery along the frame shape of the frame 6, airtightness of the cavity 8 can be secured, and a decrease in reliability due to moisture absorption and intrusion of dust into the cavity 8 can be suppressed. Additionally, since moisture absorption in the cavity 8 can be suppressed, it is possible to suppress an increase in the internal pressure of the cavity 8 at the time of reflow or the like.

### Second Modification

The second modification is a modification regarding the groove portion 251 formed in the frame 6 for arrangement of the hot melt bonding portion 232B. As illustrated in FIG. 50, in the configuration of the second modification, the groove portion 251, in which the hot melt bonding portion 232B is positioned, is formed by a concave curved surface 256 having a curved shape in a side cross-sectional view of the solid-state imaging device 230.

In the example illustrated in FIG. 50, the concave curved surface 256 has a substantially semi-elliptical shape in a side cross-sectional view and is formed substantially symmetrically. In the configuration of the second modification, the wall portion 255 forming the inner peripheral lower surface 24b is formed on the inner peripheral side of the concave curved surface 256. At least one of the outer peripheral lower surface 24a, the inner peripheral lower surface 24b, and the concave curved surface 256 of the groove portion 251 is a surface that is supported by the substrate 5. The concave curved surface 256 is received by the substrate 5 through the hot melt bonding portion 232B.

As described above, the groove shape (transverse cross-sectional shape) of the groove portion 251 may be a curved shape or the like, and the groove shape of the groove portion 251 is not particularly limited.

### Third Modification

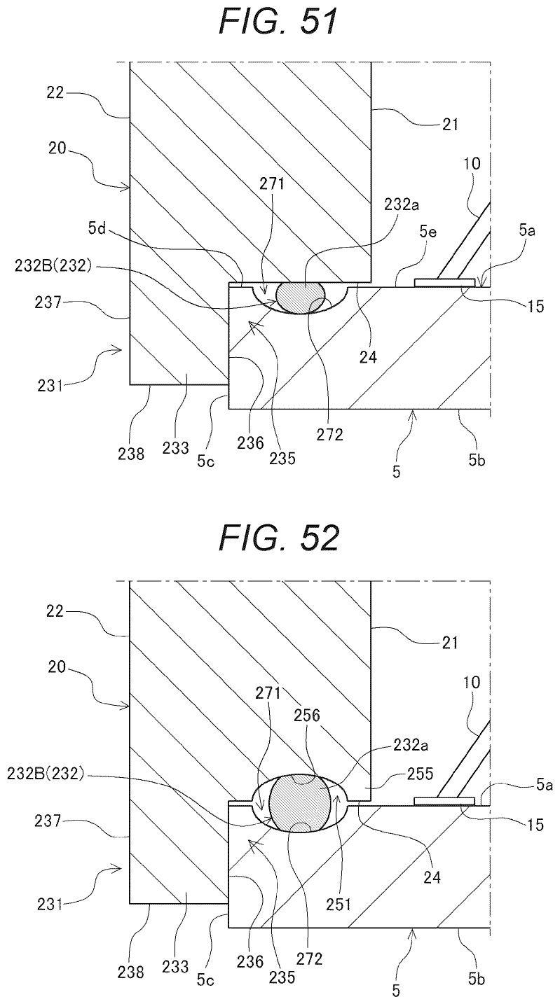

As illustrated in FIG. 51, in the third modification, the groove portion 251 is not formed on the side corresponding to the lower surface 24 of the frame main body portion 26, and a groove portion 271 as a recessed portion for positioning the hot melt bonding portion 232B is formed in the surface 5a, which is the upper surface of the substrate 5 facing the lower surface 24. That is, the groove portion 271 is formed in a peripheral edge portion of the surface 5a of the substrate 5, which is a portion facing the lower surface 24 of the frame main body portion 26. The groove portion 271 is formed in a frame shape along the outer shape of the substrate 5. However, the groove portion 271 may be partially formed in an intermittent manner with respect to the frame shape, for example.

In the example illustrated in FIG. 51, the groove portion 271 is formed by a concave curved surface 272 having a curved shape in a side cross-sectional view of the solid-state imaging device 230. The concave curved surface 272 has a substantially semi-elliptical shape in a side cross-sectional view and is formed substantially symmetrically. Note that the groove portion 271 may be a recessed portion that has a transverse cross-sectional shape substantially having the shape of letter “U” and has an open side on the upper side, for example, and the groove shape (transverse cross-sectional shape) of the groove portion 271 is not particularly limited. The groove portion 271 is covered with the lower surface 24 of the frame main body portion 26 from the upper side, so that a passage-shaped hollow portion is formed along the extending shape of the groove portion 271.

In the configuration in which the groove portion 271 is formed in the substrate 5, the surface 5a of the substrate 5 is separated into an outer side surface portion 5d, which is a portion outward of the groove portion 271, and an inner side surface portion 5e, which is a portion inward of the groove portion 271. At least one of the outer side surface portion 5d, the inner side surface portion 5e, and the concave curved surface 272 of the groove portion 271 is a surface that supports the lower surface 24 of the frame main body portion 26. The concave curved surface 272 supports the lower surface 24 through the hot melt bonding portion 232B.

As described above, the shape portion forming the arrangement space of the hot melt bonding portion 232B may be formed on the side corresponding to the substrate 5. The groove portion 271 of the substrate 5 can be formed by a known method. For example, in a case where the substrate 5 is a ceramic substrate having a multilayer structure in which sheet-shaped members formed of a ceramic material or the like are laminated, the groove portion 271 can be formed on the side corresponding to the surface 5a of the substrate 5 in the laminated state by forming a penetrating opening portion extending through each of the sheet-shaped members to be laminated as a portion forming the groove portion 271. Additionally, the groove portion 271 can be formed by a processing apparatus such as a drill for the substrate 5. Also with the configuration of the third modification, the frame with glass 246 can be easily removed from the substrate 5 by heating and melting the hot melt bonding portion 232B.

### Fourth Modification

In the fourth modification, a shape portion forming an arrangement space of the hot melt bonding portion 232B is formed on both the side corresponding to the frame 6 and the side corresponding to the substrate 5. That is, as illustrated in FIG. 52, a groove portion 251, 271 in which the hot melt bonding portion 232B is positioned is formed on the lower surface 24 of the frame main body portion 26 and the surface 5a of the substrate 5.

In the example illustrated in FIG. 52, the groove portion 251 on the side corresponding to the frame 6 and the groove portion 271 on the side corresponding to the substrate 5 are formed to be substantially vertically symmetrical. The upper and lower groove portions 251, 271 form a passage-shaped hollow portion that follows the extending shape of these groove portions and has a horizontally long substantially elliptical transverse cross-sectional shape.

As described above, the shape portion forming the arrangement space of the hot melt bonding portion 232B may be formed on both the side corresponding to the frame 6 and the side corresponding to the substrate 5. That is, the shape portion forming the arrangement space of the hot melt bonding portion 232B is formed in at least one of the lower surface 24 on the side corresponding to the frame 6 and the surface 5a of the substrate 5.

According to the configuration of the fourth modification, as compared with the configuration in which the groove portion 251, 271 is formed in any one of the frame 6 and the substrate 5, it is easy to secure the volume of the space in which the hot melt bonding portion 232B is arranged. Note that the groove portion 251 on the side corresponding to the frame 6 and the groove portion 271 on the side corresponding to the substrate 5 may have different shapes, and the shape of each groove portion, the positional relationship between the groove portions, and the like are not particularly limited.

### 17. Configuration Example of Solid-State Imaging Device According to Sixth Embodiment

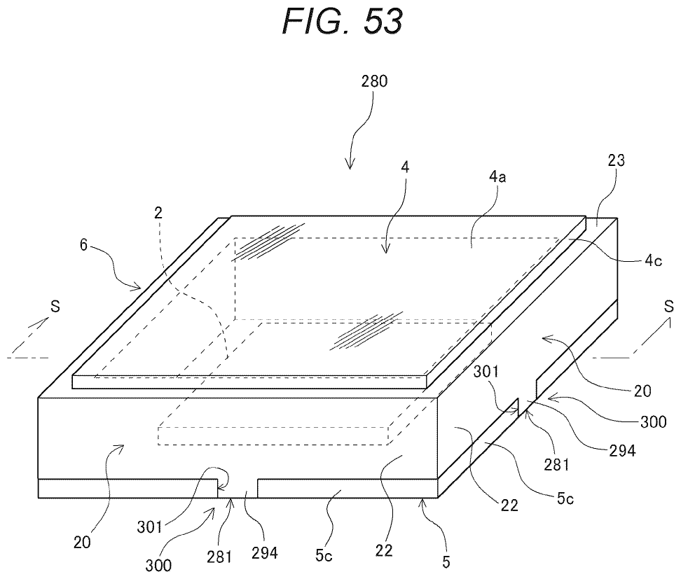

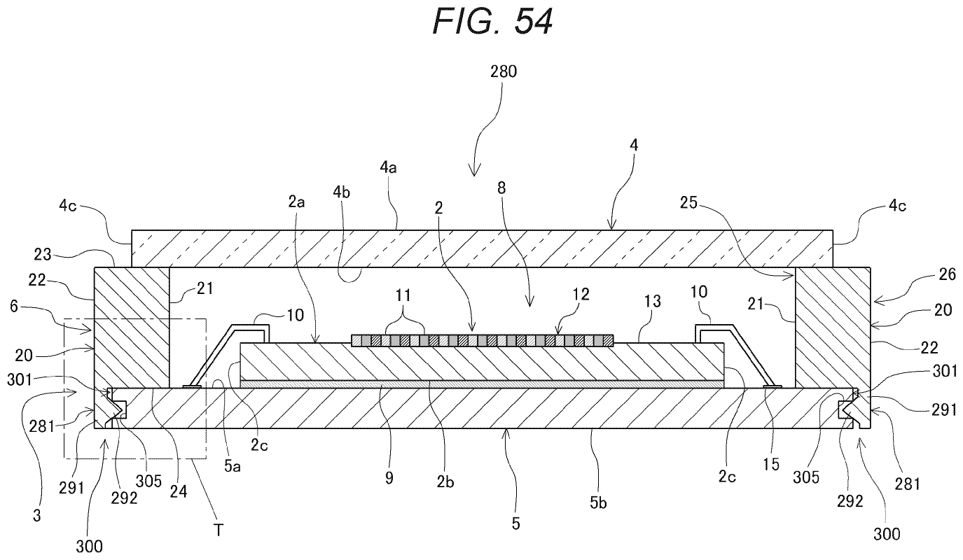

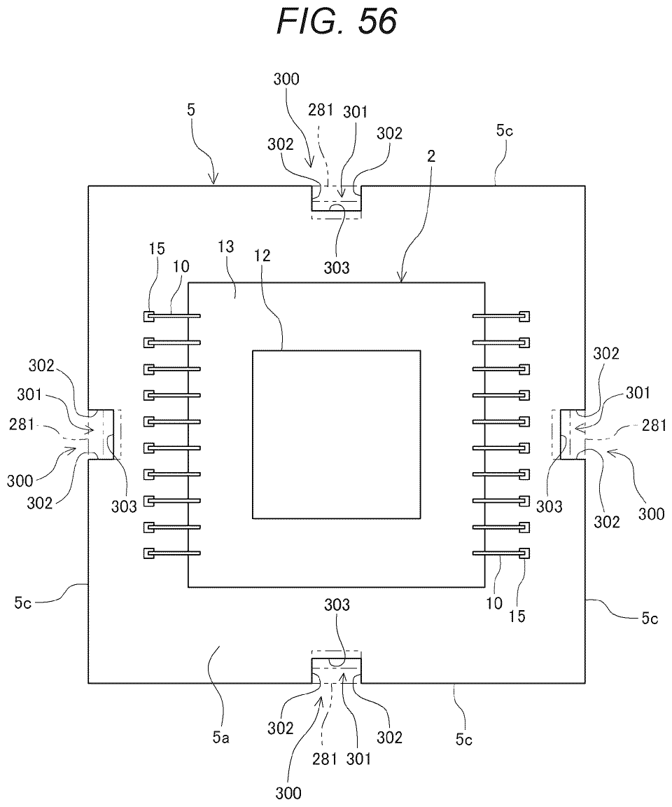

A configuration example of a solid-state imaging device 280 according to a sixth embodiment of the present technology will be described with reference to FIGS. 53 to 57. A solid-state imaging device 280 according to the present embodiment is different from the solid-state imaging device 230 according to the fifth embodiment in the configuration of the frame holding portion that detachably holds the frame 6 relative to the substrate 5.

As illustrated in FIGS. 53 to 57, the solid-state imaging device 280 includes, as the frame holding portion, hook portions 281, which are engagement portions provided on the lower side of the frame main body portion 26 and fix the frame 6 to the substrate 5 by engaging with the substrate 5. Each hook portion 281 is a portion formed as a part of the frame 6 and a retaining protruding piece portion provided as a protruding portion extending downward from the lower surface 24 of the frame main body portion 26.

The hook portion 281 is provided on the lower side of each wall portion 20 forming the frame main body portion 26 at the center portion of the wall portion 20 in the extending direction. Therefore, in the frame 6, the hook portions 281 are provided at a total of four positions, one position for each wall portion 20. The hook portions 281 provided on the wall portions 20 facing each other are provided at positions facing each other. However, the hook portions 281 provided on the wall portions 20 facing each other may be provided at different positions in the extending direction of the wall portion 20.

The hook portion 281 is provided on the outer side (the side corresponding to the outer wall surface 22) of each wall portion 20 in the wall thickness direction of the wall portion 20. The hook portion 281 includes a support column 291, which protrudes from the lower surface 24 of the frame main body portion 26, and a retaining protrusion 292, which protrudes from the inner side of the support column 291. Here, the inner side of the support column 291 is on the center side of the substrate 5 in plan view, and the hook portions 281 provided on the wall portions 20 facing each are set such that the protruding directions of the retaining protrusions 292 are opposite to each other.

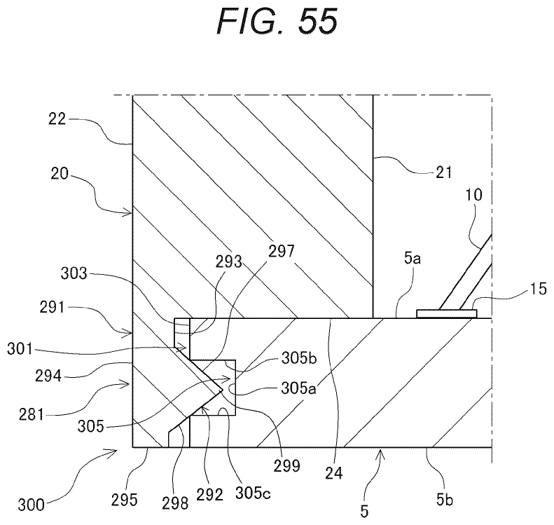

The support column 291 is a wall-shaped portion with the wall thickness direction of the wall portion 20 as the thickness direction, and includes an inner side surface 293, which is an inner wall surface, an outer side surface 294, which is a wall surface opposite to the inner side surface 29, and a horizontal lower surface 295 (see FIG. 55). The hook portion 281 is formed such that the outer side surface 294 is located on the same plane as the outer wall surface 22 of the wall portion 20. Also, the hook portion 281 has side end surfaces 296 on both sides in the extending direction of the wall portion 20, and is formed to have a uniform cross-sectional shape in the entire extending direction of the wall portion 20.

The hook portion 281 is formed such that the dimension in the up-down direction is substantially the same or the same as the plate thickness dimension of the substrate 5. Therefore, the lower surface 295 of the hook portion 281 is located on substantially the same plane or the same plane as the back surface 5b of the substrate 5. In the hook portion 281, the inner side surface 293 is positioned outside the inner wall surface 21 of the wall portion 20 and is formed as a surface parallel to the inner wall surface 21. In the example illustrated in FIG. 55, the thickness dimension of the support column 291 is about ⅙ of the wall thickness of the wall portion 20. However, the thickness dimension of the support column 291 is not particularly limited.

The retaining protrusion 292 is formed at an intermediate portion in the up-down direction of the support column 291. The retaining protrusion 292 includes an upper inclined surface 297, which is inclined downward from the outside to the inside in the wall thickness direction of the wall portion 20, and a lower inclined surface 298, which is inclined in a direction from the lower side to the upper side from the outside to the inside in the wall thickness direction of the wall portion 20 (see FIG. 55).

The retaining protrusion 292 has a crest shape with the peak side on the inner side in side view formed by the upper inclined surface 297 and the lower inclined surface 298. The upper inclined surface 297 and the lower inclined surface 298 form a ridge portion 299 in the extending direction of the wall portion 20 in bottom view as an end portion on the protruding side of the retaining protrusion 292. In the example shown in FIG. 55, the upper inclined surface 297 and the lower inclined surface 298 are formed so as to be vertically symmetrical in side view, and are formed so that an angle formed in the side view is approximately 80°. Note that there is no limitation on the angle formed by the upper inclined surface 297 and the lower inclined surface 298 in side view.

On the side corresponding to the substrate 5, engagement recesses 301, which are engaged portions to be engaged by the respective hook portions 281 are formed. The engagement recesses 301 are formed at the center in the longitudinal direction of the four side surfaces 5c of the substrate 5 so as to correspond to the arrangement of the four hook portions 281. engagement portions of the hook portions 281 relative to the engagement recesses 301 are engagement fixing portions 300 between the substrate 5 and the frame 6. The solid-state imaging device 280 has four engagement fixing portions 300.

The engagement recess 301 is formed such that the outer side surface 294 of the hook portion 281 is flush with the side surface 5c of the substrate 5 in a state in which the hook portion 281 is engaged. The engagement recess 301 is a cutout recessed portion, which is formed by side surfaces 302, 302 facing each other and an engaging surface portion 303 located inside and has an open side on the outer side in plan view, and the hook portion 281 is fitted in this recessed portion.

In the engaging surface portion 303, a groove portion 305, which is a recessed depression portion with which the retaining protrusion 292 is engaged, is formed. The groove portion 305 is formed in the engaging surface portion 303 in the lateral direction in an intermediate portion in the up-down direction. The groove portion 305 is a portion forming a recess having an open side on the outer side in side cross-sectional view of the substrate 5, and is formed by an inner side surface 305a, which is an inner surface and is a surface on a deep side of a recessed shape of the groove portion 305, and an upper surface 305b and a lower surface 305c facing each other in the up-down direction (see FIG. 55).

The frame 6 is fixed to the substrate 5 in a mode in which the substrate 5 is sandwiched between two sets of the hook portions 281 facing each other. The hook portion 281 is fitted in the recess of the engagement recess 301 such that the outer side surface 294 is flush with the side surface 5c of the substrate 5, and the retaining protrusion 292 is engaged in the groove portion 305 so that the hook portion 281 engages with the engagement recess 301. The hook portions 281 facing each other are set such that the dimension between the inner side surfaces 293 facing each other is slightly larger than or substantially equal to the dimension between the engaging surface portions 303 of the engagement recesses 301 located on opposite sides of the substrate 5. In the example shown in FIG. 55, the hook portion 281 is engaged with the engagement recess 301 in a state in which a substantially half portion of the retaining protrusion 292 on the side corresponding to the ridge portion 299 is positioned in the groove portion 305.

Note that the hook portion 281 and the engagement recess 301 may be formed such that the entire retaining protrusion 292 is positioned in the groove portion 305 in the engaged state. Also, engagement shapes of the hook portion 281 and the engagement recess 301 are not particularly limited. For example, the engagement recess 301 may have a V-shaped recess corresponding to the crest shape of the retaining protrusion 292 as a portion to be engaged with the retaining protrusion 292 of the hook portion 281.

The engagement recess 301 is formed in a range corresponding to at least the formation portion of the hook portion 281 in the longitudinal direction of each side surface 5c of the substrate 5. The dimension between the side surfaces 302 of the engagement recess 301 is substantially the same as the dimension between the side end surfaces 296 of the hook portion 281, so that the hook portion 281 can be positioned relative to the corresponding engagement recesses 301 in the longitudinal direction of the side surface 5c of the substrate 5, and the function of positioning the frame 6 relative to the substrate 5 can be obtained.

In the substrate 5, similarly to the groove portion 271 of the substrate 5 according to the fifth embodiment described above, the engagement recess 301 can be formed by a known method such as a method using a laminated structure of the substrate 5 or a method using a processing apparatus.

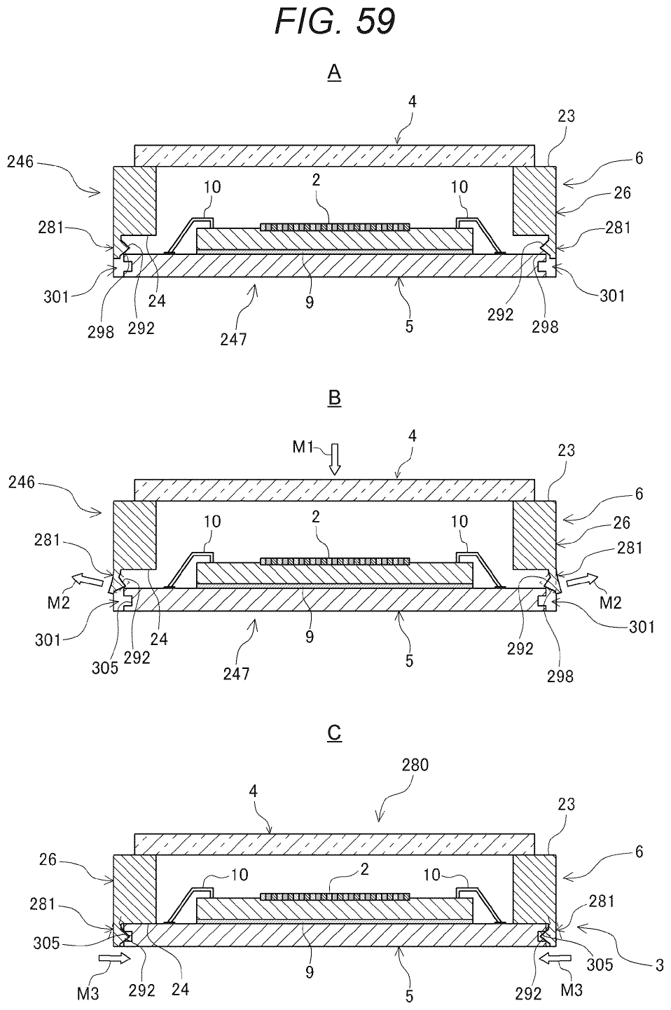

The hook portion 281 is engaged with the engagement recess 301 formed in the substrate 5 with temporary elastic deformation. Specifically, as temporary elastic deformation, the hook portion 281 deforms to warp outward so as to widen the distance to the counterpart hook portion 281 on the opposite side, relative to the substrate 5 to which the frame 6 is attached from above (see FIG. 59B). Also, the hook portion 281 also performs similar elastic deformation when the frame 6 is removed from the substrate 5. Therefore, the hook portion 281 is formed as a portion having flexibility that allows the hook portion 281 to appropriately bend when the frame 6 is attached or detached. Note that in the engagement recess 301, a chamfered portion that guides elastic deformation of the hook portion 281 when the frame 6 is attached to the substrate 5 may be formed on the upper portion of the engaging surface portion 303.

### 18. Method for Manufacturing Solid-State Imaging Device According to Sixth Embodiment

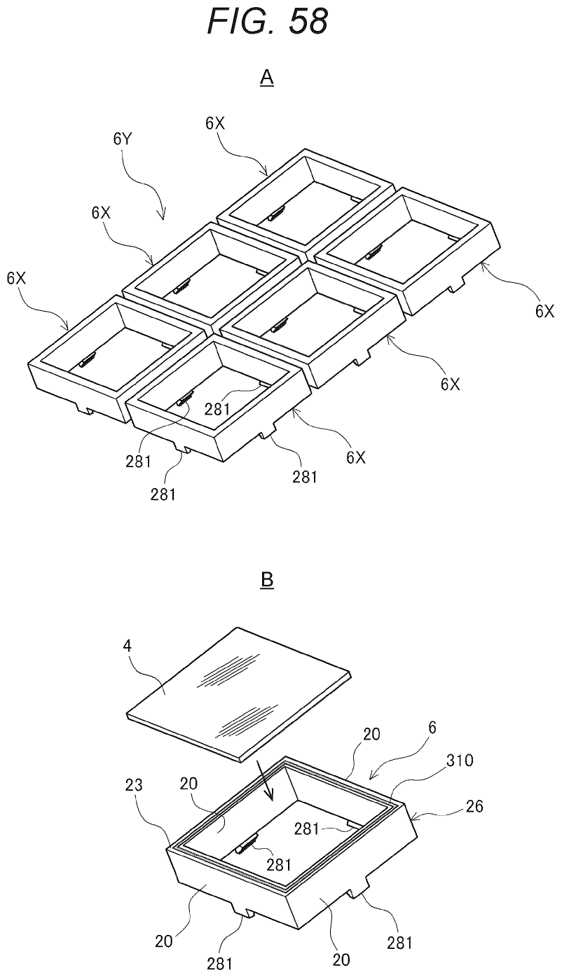

An example of a method for manufacturing the solid-state imaging device 280 according to the sixth embodiment of the present technology will be described with reference to FIGS. 58 and 59.

In the method for manufacturing the solid-state imaging device 280, the step of manufacturing the frame with glass 246 by fixing the cover glass 4 to the glass support surface 23 of the frame 6 is performed. Regarding the frame 6, when the frame 6 is a frame including resin, for example, as shown in FIG. 58A, a frame assembly 6Y in an assembled state in which multiple frame elements 6X to be frames 6 are connected is integrally molded by injection molding or the like using a mold, and the frame assembly 6Y is divided into individual frame elements 6X, whereby the frames 6 are manufactured.

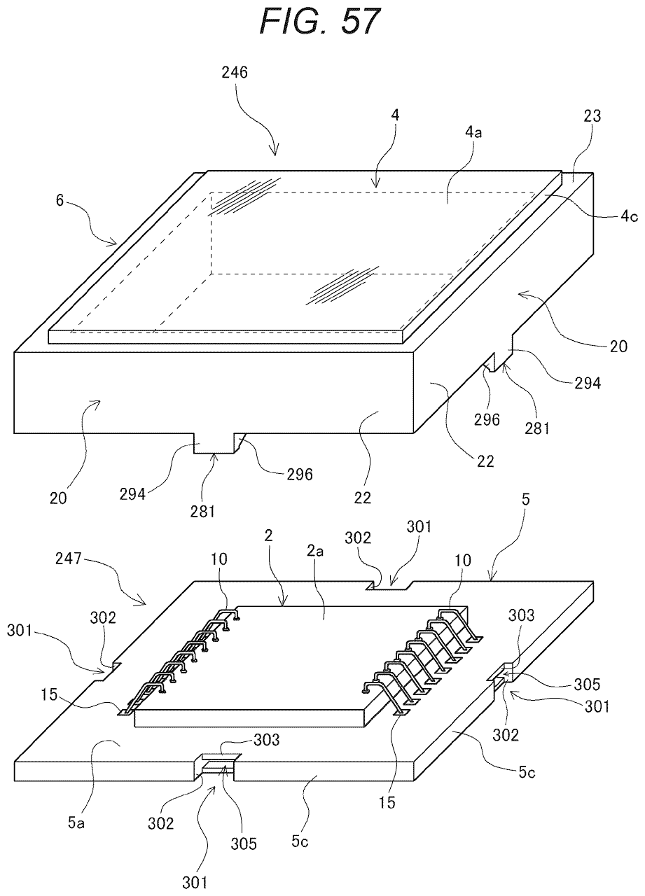

Then, as illustrated in FIG. 58B, the cover glass 4 is attached to the frame 6 so as to close the entire opening portion 25 of the frame 6. The cover glass 4 is fixed by an adhesive 310 applied to the glass support surface 23 of the frame 6. As a result, a frame with glass 246 as shown in FIG. 57 is obtained. The frame with glass 246 is attached to a sensor mounting substrate 247, which is the substrate 5 on which the image sensor 2 is mounted (see FIG. 57).

An example of the step of attaching the frame with glass 246 will be described with reference to FIG. 59. In the attachment of the frame with glass 246, first, the frame with glass 246 is placed in the following attachment set state relative to a sensor mounting substrate 247. That is, as illustrated in FIG. 59A, the frame with glass 246 is placed in a state in which the four hook portions 281 are in contact with the substrate 5 at positions corresponding to the engagement recesses 301 of the substrate 5. Here, each hook portion 281 is supported by the substrate 5 in a state in which the lower inclined surface 298 is in contact with the upper corner portion of the substrate 5.

From the attachment set state of the frame with glass 246 illustrated in FIG. 59A, as illustrated in FIG. 59B, a force for pressing the frame with glass 246 toward the side corresponding to the substrate 5 (lower side) is applied (see arrow M1). When the frame with glass 246 receives a downward force, each hook portion 281 elastically deforms so as to widen the distance to the counterpart hook portion 281 on the opposite side while sliding on the corner of the substrate 5 in contact with the lower inclined surface 298 (see arrow M2).

Then, in the frame with glass 246 that moves downward relative to the substrate 5, when the retaining protrusion 292 of each hook portion 281 reaches the groove portion 305 of the engagement recess 301 of the substrate 5, as illustrated in FIG. 59C, the hook portion 281 returns from the elastically deformed state, and the retaining protrusion 292 is engaged with the groove portion 305 to be engaged with the engagement recess 301 (see arrow M3). As a result, a state in which the frame with glass 246 is attached to the substrate 5 is obtained. By attaching the frame with glass 246 as described above, the solid-state imaging device 280 is obtained.

In the solid-state imaging device 280 according to the present embodiment, as the removal of the cover glass 4, the frame with glass 246 is removed from the substrate 5. The frame with glass 246 is removed from the substrate 5 by releasing the engagement of the hook portions 281 with the engagement recesses 301. Here, the engagement of the hook portions 281 with the engagement recesses 301 is released with temporary elastic deformation such as outward warping as described above. Furthermore, as a method for removing the frame with glass 246, a method may be used that breaks the hook portions 281 to release the engagement of the frame 6 with the substrate 5 and remove the frame with glass 246 from the substrate 5. By removing the frame with glass 246 from the solid-state imaging device 280, the sensor mounting substrate 247 is obtained.

According to the solid-state imaging device 280 according to the present embodiment as described above, the cover glass 4 can be easily attached and detached together with the frame 6 as the frame with glass 246. In particular, the solid-state imaging device 280 of the present embodiment includes the hook portions 281 provided on the lower side of the frame 6 as the frame holding portions. According to such a configuration, it is possible to obtain a configuration in which the cover glass 4 can be easily removed without using a pressure-sensitive adhesive or the like.

Additionally, the hook portions 281 are provided as retaining protruding piece portions that engage with the engagement recesses 301 of the substrate 5 with temporary elastic deformation. According to such a configuration, since the frame with glass 246 can be attached by a simple operation such as a pressing operation on the frame with glass 246 or the like, the cover glass 4 can be easily attached.

Also, the hook portions 281 are provided such that their lower surfaces 295 are flush with the back surface 5b of the substrate 5. According to such a configuration, since the lower portions of the hook portions 281 can be prevented from protruding toward the side corresponding to the back surface 5b of the substrate 5, the substrate 5 can be mounted on the set substrate 18 (the solid-state imaging device 280) while the frame with glass 246 is attached to the substrate 5. From the viewpoint of obtaining such an effect, the hook portions 281 may be provided such that the dimension in the up-down direction, that is, the protruding dimension from the lower surface 24 of the frame main body portion 26 serving as the support surface with respect to the surface 5a of the substrate 5 is less than the plate thickness dimension of the substrate 5.

Also, according to the fixing structure by the hook portions 281, the frame 6 is supported on the substrate 5 without interposing an adhesive or the like between the surface 5a of the substrate 5 and the lower surface 24. Therefore, the cleanliness of the surface 5a of the substrate 5 can be maintained even in a state in which the frame with glass 246 is removed from the sensor mounting substrate 247. Therefore, it is possible to prevent adhesion of an adhesive existing on the surface 5a of the substrate 5 to the image sensor 2 inside the package as dust, and the performance of the image sensor 2 can be secured.

Additionally, according to the configuration in which the cover glass 4 is removed together with the frame 6 relative to the substrate 5, for example, in a case where a lens housing is provided for the image sensor 2 on the sensor mounting substrate 247 in a state in which the frame with glass 246 is removed, a high degree of freedom can be obtained for the distance between the image sensor 2 and the lens of the lens housing. As a result, the degree of freedom in designing the lens housing can be improved.

### 19. Modification of Solid-State Imaging Device According to Sixth Embodiment

Modifications of the solid-state imaging device 280 according to the sixth embodiment of the present technology will be described.

### First Modification

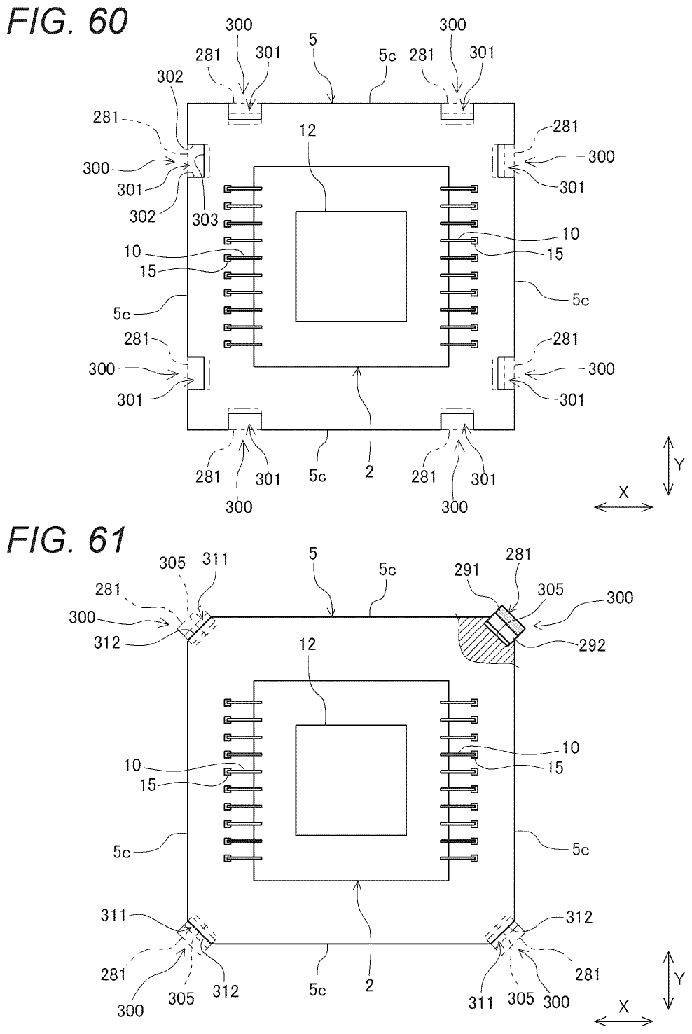

As shown in FIG. 60, in the first modification, two engagement fixing portions 300, each formed by a combination of a hook portion 281 on the side corresponding to the frame 6 and an engagement recess 301 on the side corresponding to the substrate 5, are provided for each side portion of the frame main body portion 26 having a frame shape in plan view. Therefore, in the configuration of the first modification, the frame 6 has the hook portions 281 at eight positions, the substrate 5 has the engagement recesses 301 at eight positions, and the engagement fixing portions 300 are provided at eight positions in total.

In the example illustrated in FIG. 60, in each side surface 5c forming the outer shape of the substrate 5 in plan view, engagement recesses 301, which are engaged by the hook portions 281 of the frame 6, are formed at positions near the left and right end portions of the side surface 5c. The two engagement fixing portions 300 of each side portion are provided in a symmetrical arrangement in each of the X direction and the Y direction.

As described above, according to the configuration in which the engagement fixing portions 300 are provided at two positions for each side portion of the frame main body portion 26, it is possible to improve the fixing action of the frame with glass 246 relative to the substrate 5 and to firmly fix the frame with glass 246 as compared with a configuration in which the engagement fixing portion 300 is provided at one position for each side portion.

### Second Modification

As illustrated in FIG. 61, in a second modification, the engagement fixing portions 300 are provided at four corner portions of the substrate 5. In the second modification, chamfered portions 311 forming inclined surfaces 312 between adjacent side surfaces 5c are formed at four corners of the substrate 5 having a rectangular shape in plan view, and groove portions 305, which are engaged by the retaining protrusions 292, are formed in the inclined surfaces 312. Note that, in FIG. 61, a planar cross section is partially illustrated for convenience.

In this modification, the engagement fixing portions 300 are engagement portions of the retaining protrusions 292 of the hook portions 281 on the side corresponding to the frame 6 relative to the groove portions 305 on the side corresponding to the substrate 5. On the side corresponding to the frame 6, corresponding to the groove portions 305 at the four corners of the substrate 5, the hook portions 281 are provided at the four corners on the lower side of the frame main body portion 26 such that the protruding sides of the retaining protrusions 292 face toward the center of the frame 6 in plan view.

As in the first modification and the second modification, the number and arrangement positions of the engagement fixing portions 300 can be appropriately changed according to the size and use of the package. However, from the viewpoint of obtaining a good fixing action for fixing the frame 6 to the substrate 5, the engagement fixing portions 300 are provided in a symmetrical arrangement at least at two positions in total, one at each of opposing side portions or corner portions.

### Third Modification

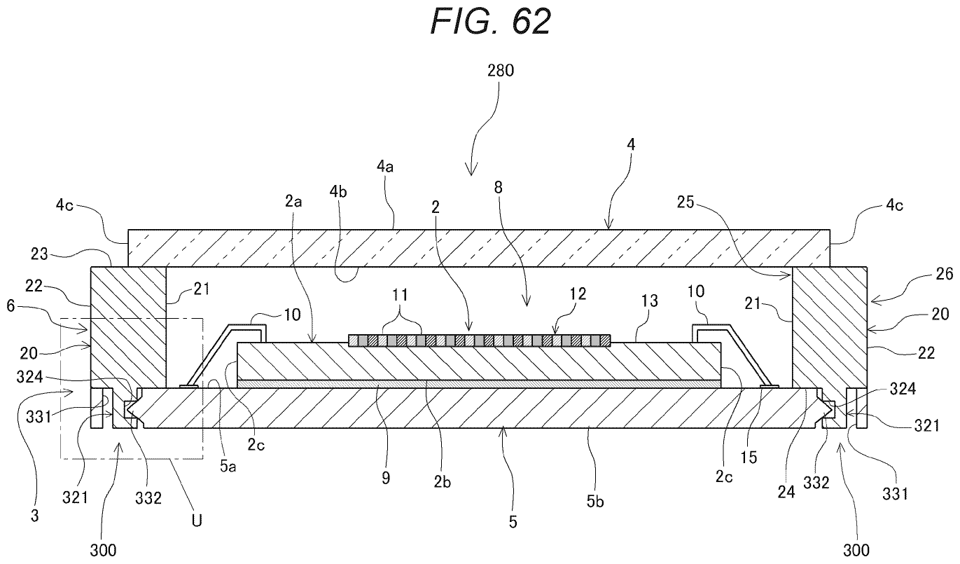

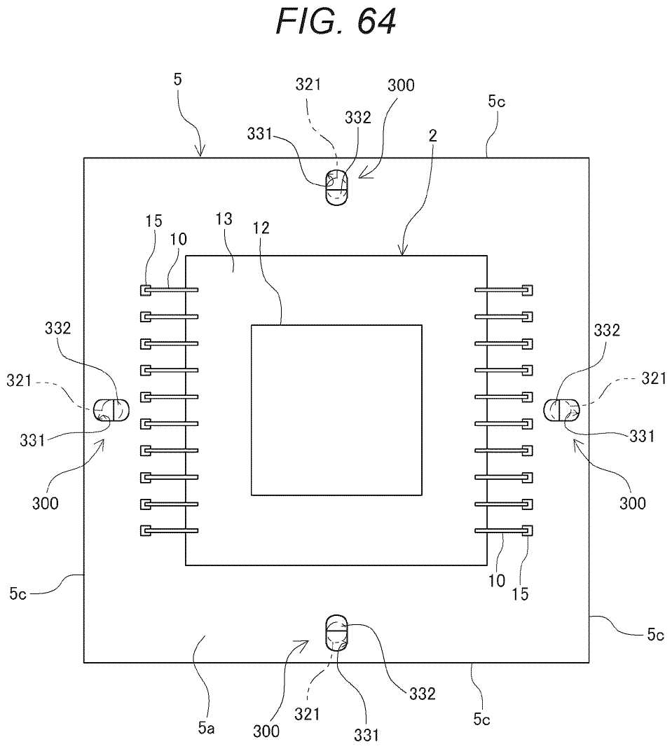

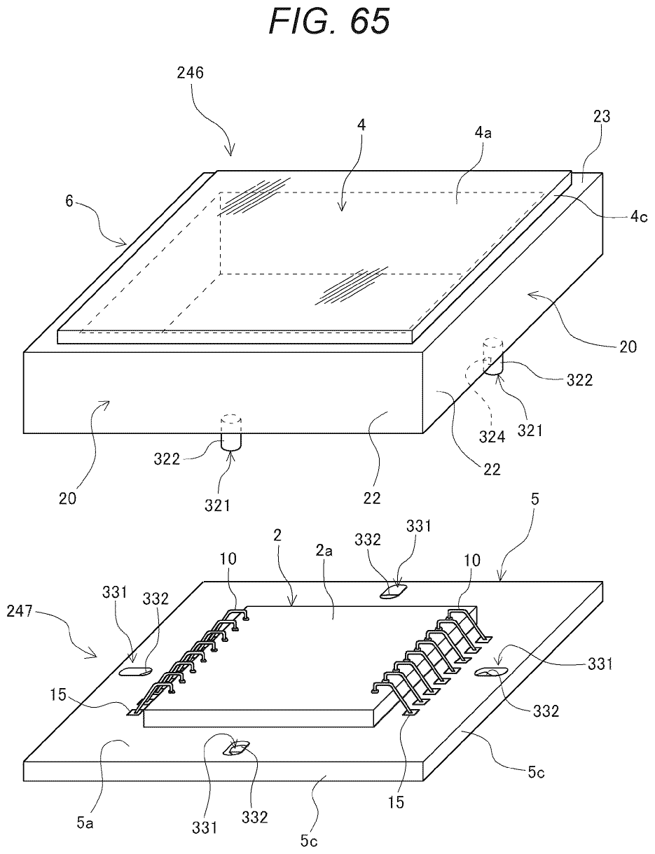

A third modification of the solid-state imaging device 280 according to the sixth embodiment of the present technology will be described with reference to FIGS. 62 to 65. The configuration of the third modification includes, as the frame holding portions, retaining pin portions 321, which are engagement portions provided below the frame main body portion 26 and configured to fix the frame 6 to the substrate 5 by engaging with the substrate 5. Each retaining pin portion 321 is a portion formed as a part of the frame 6 and a retaining protruding piece portion provided as a protruding portion extending downward from the lower surface 24 of the frame main body portion 26.

The retaining pin portion 321 is provided on the lower side of each wall portion 20 forming the frame main body portion 26 at the center portion of the wall portion 20 in the extending direction. Therefore, in the frame 6, the retaining pin portions 321 are provided at a total of four positions, one position for each wall portion 20. The retaining pin portions 321 provided on the wall portions 20 facing each other are provided at positions facing each other. However, the retaining pin portions 321 provided on the wall portions 20 facing each other may be provided at different positions in the extending direction of the wall portion 20.

The retaining pin portion 321 is provided at an intermediate portion of the wall portion 20 in the wall thickness direction of the wall portion 20. The retaining pin portion 321 is a portion having a substantially columnar outer shape, and protrudes perpendicularly from the lower surface 24 of the frame main body portion 26. The retaining pin portion 321 has an outer peripheral surface 322 along the cylindrical outer shape and a horizontal lower surface 323. The retaining pin portion 321 has a cutout retaining recess 324 in the inner side of an intermediate portion in the up-down direction. Here, the inner side of the retaining pin portion 321 is the center side of the substrate 5 in plan view, and the open sides of the retaining recesses 324 of the retaining pin portions 321 provided on the wall portions 20 facing each other face each other.

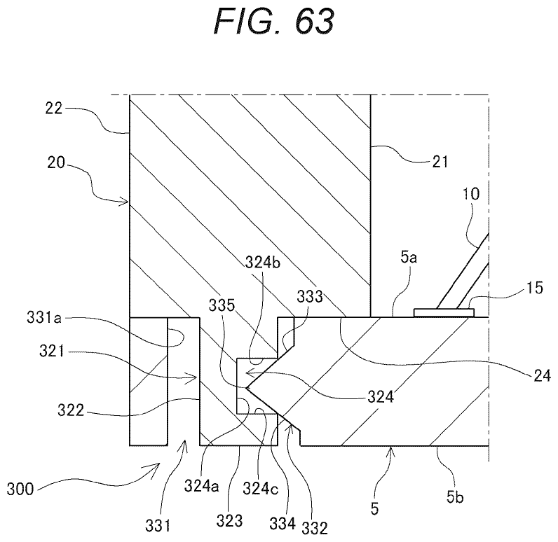

The retaining recess 324 is a cutout portion having an open side on the lateral side in side cross-sectional view of the frame 6 (longitudinal cross-sectional view of the retaining pin portion 321). The retaining recess 324 is formed by an inner side surface 324a that is an outer surface and is a surface on a deep side of the recessed shape of the retaining recess 324, and an upper surface 324b and a lower surface 324c facing each other in the up-down direction (see FIG. 63). The retaining recess 324 is formed in a range forming a substantially semicircular shape in transverse cross-sectional view of the retaining pin portion 321. In the retaining recess 324, the inner side surface 324a is a rectangular surface, and the upper surface 324b and the lower surface 324c are substantially semicircular surfaces.

The retaining pin portion 321 is formed so that the dimension in the up-down direction is substantially the same or the same as the plate thickness dimension of the substrate 5. Therefore, the lower surface 323 of the retaining pin portion 321 is positioned on substantially the same plane or the same plane as the back surface 5b of the substrate 5.

On the side corresponding to the substrate 5, engagement hole portions 331, which are engaged portions that are engaged by the respective retaining pin portions 321, are formed. The engagement hole portions 331 are formed in the vicinity of the center portions in the longitudinal direction of the four side surfaces 5c of the substrate 5 corresponding to the arrangement of the four retaining pin portions 321. The engagement portions of the retaining pin portions 321 relative to the engagement hole portions 331 serve as engagement fixing portions 300 between the substrate 5 and the frame 6.

The engagement hole portions 331 form opening portions extending through the substrate 5 in the plate thickness direction, and have an elongated hole shape with the longitudinal direction in the opposing direction of the retaining pin portions 321 provided on the wall portions 20 facing each other. A retaining protrusion 332, which engages with the retaining recess 324 of the retaining pin portion 321, is formed on the inner side of the inner peripheral surface 331a of the engagement hole portion 331 (on the center side of the substrate 5).

The retaining protrusion 332 is formed at an intermediate portion in the thickness direction of the substrate 5 on the inner side of the engagement hole portion 331. The retaining protrusion 332 has an upper inclined surface 333 inclined downward from the inside (the center side of the substrate 5) to the outside, which is the opposite side, and a lower inclined surface 334 inclined in a direction from the lower side to the upper side from the outside to the inside (see FIG. 63).

The retaining protrusion 332 has a crest shape with the peak side on the outer side in side view formed by the upper inclined surface 333 and the lower inclined surface 334. The upper inclined surface 333 and the lower inclined surface 334 form a ridge portion 335 in the extending direction of the side surface 5c of the substrate 5 in plan view as an end portion on the protruding side of the retaining protrusion 332. In the example shown in FIG. 63, the upper inclined surface 333 and the lower inclined surface 334 are formed so as to be vertically symmetrical in side view, and are formed so that an angle formed in the side view is approximately 80°. Note that there is no limitation on the angle formed by the upper inclined surface 333 and the lower inclined surface 334 in side view.

The frame 6 is fixed to the substrate 5 in a mode in which the substrate 5 is sandwiched between two sets of the retaining pin portions 321 facing each other. The retaining pin portion 321 is inserted into the engagement hole portion 331 and is engaged with the engagement hole portion 331 by engaging the retaining protrusion 332 with the retaining recess 324. The retaining pin portions 321 facing each other are set such that the dimension between the inner side surfaces 324a facing each other is slightly larger than or substantially equal to the dimension between the ridge portions 335 of the retaining protrusions 332 of the engagement hole portions 331 located on opposite sides of the substrate 5. In the example shown in FIG. 63, the retaining pin portion 321 is engaged with the engagement hole portion 331 in a state in which a substantially half portion of the retaining protrusion 332 on the side corresponding to the ridge portion 335 is positioned in the retaining recess 324.

Note that the retaining pin portion 321 and the engagement hole portion 331 may be formed such that the entire retaining protrusion 332 is positioned in the retaining recess 324 in the engaged state. Furthermore, engagement shapes of the retaining pin portion 321 and the engagement hole portion 331 are not particularly limited. For example, the retaining pin portion 321 may have a V-shaped recess corresponding to the crest shape of the retaining protrusion 332 as a portion to be engaged with the retaining protrusion 332 of the engagement hole portion 331.

In the engagement hole portion 331, by setting the dimension in the width direction of the elongated hole shape to be substantially the same as the dimension of the outer diameter of the retaining pin portion 321, the retaining pin portion 321 can be positioned relative to the corresponding engagement hole portion 331 in the width direction of the elongated hole shape, and the function of positioning the frame 6 relative to the substrate 5 can be obtained. Note that the engagement hole portion 331 can be formed by a known method such as a method using a laminated structure of the substrate 5 or a method using a processing apparatus.

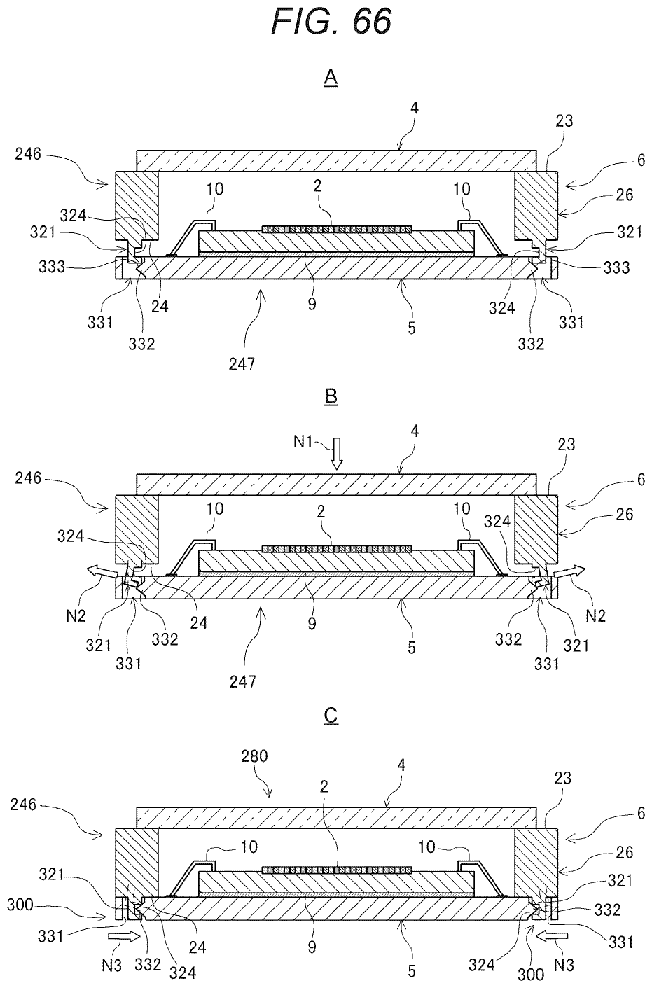

The retaining pin portion 321 is engaged with the engagement hole portion 331 formed in the substrate 5 with temporary elastic deformation. Specifically, as temporary elastic deformation, the retaining pin portion 321 deforms to warp outward so as to widen the distance to the counterpart retaining pin portion 321 on the opposite side, relative to the substrate 5 to which the frame 6 is attached from above (see FIG. 66B). Also, the retaining pin portion 321 also performs similar elastic deformation even when the frame 6 is removed from the substrate 5. Therefore, the retaining pin portion 321 is formed as a portion having flexibility that allows the retaining pin portion 321 to appropriately bend when the frame 6 is attached or detached. Additionally, the engagement hole portion 331 has a length that secures a space that allows elastic deformation of the retaining pin portion 321 in the longitudinal direction of the elongated hole shape. Note that in the engagement hole portion 331, a chamfered portion that guides elastic deformation of the retaining pin portion 321 when the frame 6 is attached to the substrate 5 may be formed on the upper side of the retaining protrusion 332.

An example of a method for manufacturing the configuration of a third modification of the solid-state imaging device 280 according to the sixth embodiment of the present technology will be described with reference to FIG. 66.

The frame 6 having the retaining pin portions 321 is manufactured by injection molding or the like using a mold as described above. Then, by fixing the cover glass 4 to the frame 6 with an adhesive, the frame with glass 246 is obtained. The frame with glass 246 is attached to the sensor mounting substrate 247.

In the attachment of the frame with glass 246, first, the frame with glass 246 is placed in the following attachment set state relative to a sensor mounting substrate 247. That is, as illustrated in FIG. 66A, the frame with glass 246 is placed in a state in which the four retaining pin portions 321 are in contact with the substrate 5 at positions corresponding to the engagement hole portions 331 of the substrate 5. Here, the retaining pin portions 321 are supported by the substrate 5 in a state in which their lower end portions are in contact with the upper inclined surfaces 333 of the retaining protrusions 332 in the engagement hole portions 331.

From the attachment set state of the frame with glass 246 illustrated in FIG. 66A, as illustrated in FIG. 66B, a force for pressing the frame with glass 246 toward the side corresponding to the substrate 5 (lower side) is applied (see arrow N1). When the frame with glass 246 receives a downward force, each retaining pin portion 321 elastically deforms so as to widen the distance to the counterpart hook portion 281 on the opposite side while sliding on the upper inclined surface 333 in contact with the lower end portion (see arrow N2).

Then, in the frame with glass 246 moving downward relative to the substrate 5, when the insertion of the retaining pin portion 321 into the engagement hole portion 331 progresses and the retaining recess 324 of the retaining pin portion 321 reaches the retaining protrusion 332 of the engagement hole portion 331 of the substrate 5, as illustrated in FIG. 66C, the retaining pin portion 321 returns from the elastically deformed state, and the retaining recess 324 is engaged with the retaining protrusion 332 and engaged with the engagement hole portion 331 (see arrow N3). As a result, a state in which the frame with glass 246 is attached to the substrate 5 is obtained. By attaching the frame with glass 246 as described above, the solid-state imaging device 280 is obtained.

In the configuration of the third modification, the frame with glass 246 is detached from the substrate 5 by releasing the engagement of the retaining pin portion 321 with the engagement hole portion 331. Here, the engagement of the retaining pin portion 321 with the engagement hole portion 331 is released with temporary elastic deformation such as outward warping as described above. Furthermore, as a method for removing the frame with glass 246, a method may be used that breaks the retaining pin portions 321 to release the engagement of the frame 6 with the substrate 5 and remove the frame with glass 246 from the substrate 5.

### Fourth Modification

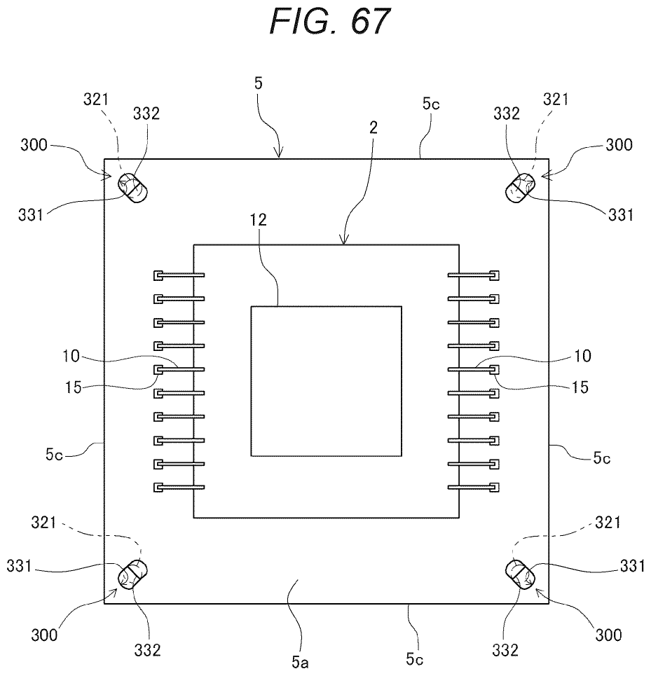

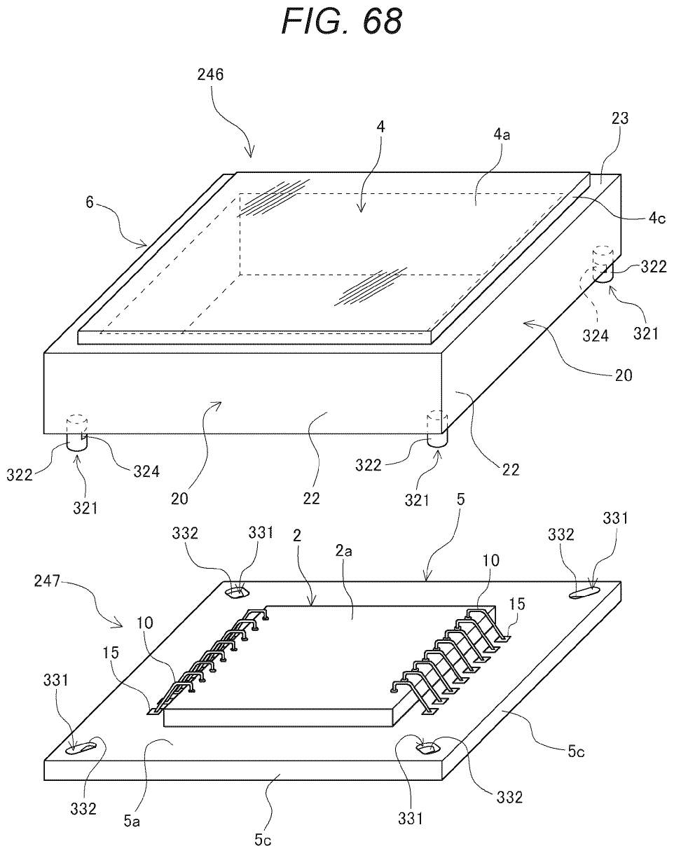

As illustrated in FIGS. 67 and 68, in a fourth modification, engagement fixing portions 300, each formed by a combination of a retaining pin portion 321 on the side corresponding to the frame 6 and an engagement hole portion 331 on the side corresponding to the substrate 5, are provided at four corner portions of the substrate 5. The engagement hole portions 331 are formed such that the longitudinal direction of the elongated hole shape, which is the shape in plan view, is along a diagonal line of the substrate 5. In each engagement hole portion 331, a retaining protrusion 332 is formed on the inner side in the longitudinal direction of the elongated hole shape (the center side of the substrate 5).

In the fourth modification, on the side corresponding to the frame 6, the retaining pin portions 321 are provided at the four corners on the lower side of the frame main body portion 26 so as to correspond to the engagement hole portions 331 at the four corners of the substrate 5, with the open sides of the retaining recesses 324 facing the center side of the frame 6 in plan view.

As in the fourth modification, the number and arrangement positions of the engagement fixing portions 300 can be appropriately changed according to the size and use of the package.

### 20. Configuration Example of Solid-State Imaging Device According to Seventh Embodiment

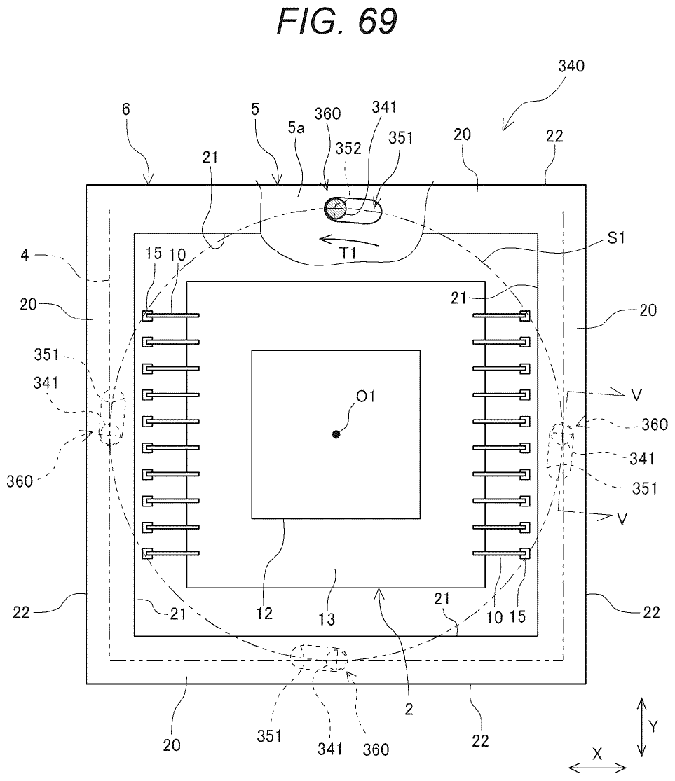

A configuration example of a solid-state imaging device 340 according to a seventh embodiment of the present technology will be described with reference to FIGS. 69 to 71. A solid-state imaging device 340 according to the present embodiment is different from the solid-state imaging device 280 according to the sixth embodiment in the engagement structure between an engagement portion as a frame holding portion that detachably holds the frame 6 relative to the substrate 5 and an engaged portion on the side corresponding to the substrate 5.

As illustrated in FIGS. 69 to 71, the solid-state imaging device 340 includes, as the frame holding portions, retaining pin portions 341, which are engagement portions provided on the lower side of the frame main body portion 26 to fix the frame 6 to the substrate 5 by engaging with the substrate 5. Each retaining pin portion 341 is a portion formed as a part of the frame 6, and is provided as a protruding portion extending downward from the lower surface 24 of the frame main body portion 26.

The retaining pin portion 341 is provided on the lower side of each wall portion 20 forming the frame main body portion 26 at the center portion of the wall portion 20 in the extending direction. Therefore, in the frame 6, the retaining pin portions 341 are provided at a total of four positions, one position for each wall portion 20.

The retaining pin portion 341 is provided at an intermediate portion of the wall portion 20 in the wall thickness direction of the wall portion 20. The retaining pin portion 341 has a similar shape as the retaining pin portion 321 according to the sixth embodiment. That is, the retaining pin portion 341 is a substantially columnar portion protruding perpendicularly from the lower surface 24 of the frame main body portion 26, and has an outer peripheral surface 342 along a columnar outer shape and a horizontal lower surface 343.

The four retaining pin portions 341 are provided so as to be positioned on the circumference of a virtual circle S1 centered on the center position O1 of the frame 6 in plan view (see FIG. 69). Specifically, each of the four retaining pin portions 341 is provided so as to position the center position of the circumferential shape, which is the outer shape in plan cross-sectional view, on the virtual circle S1. In the example illustrated in FIG. 69, the four retaining pin portions 341 are arranged at equal angular intervals (90° intervals) in the circumferential direction of the virtual circle S1, and are provided at symmetrical positions in each of the X direction and the Y direction in the frame 6. In the present embodiment, the center position O1 of the frame 6 coincides with the center position of the substrate 5 in plan view, and is the center position of the solid-state imaging device 340.

Each retaining pin portion 341 has a cutout retaining recess 344 in an intermediate portion in the up-down direction. The retaining recesses 344 of the four retaining pin portions 341 are formed such that the open sides are on the same side in the direction along the virtual circle S1. In the present embodiment, the retaining recesses 344 are formed in the retaining pin portions 341 such that the open sides are front sides in the left rotation direction (see FIG. 69, arrow T1) in plan view in the direction along the virtual circle S1.

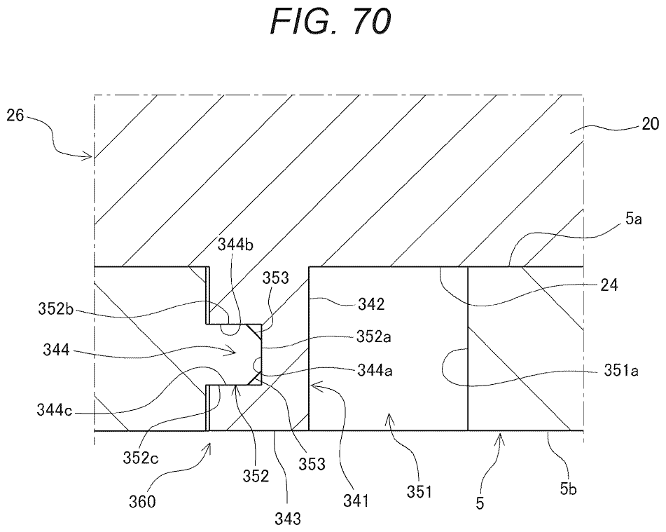

The retaining recess 344 is a cutout portion having an open side on the lateral side in side cross-sectional view of the frame 6 (longitudinal cross-sectional view of the retaining pin portion 341). The retaining recess 344 is formed by an inner side surface 344a that is a surface on a deep side of the recessed shape of the retaining recess 344, and an upper surface 344b and a lower surface 344c facing each other in the up-down direction (see FIG. 70). The retaining recess 344 is formed in a range forming a substantially semicircular shape in transverse cross-sectional view of the retaining pin portion 341. In the retaining recess 344, the inner side surface 344a is a rectangular surface, and the upper surface 344b and the lower surface 344c are substantially semicircular surfaces.

The retaining pin portion 341 is formed so that the dimension in the up-down direction is substantially the same or the same as the plate thickness dimension of the substrate 5. Therefore, the lower surface 343 of the retaining pin portion 341 is positioned on substantially the same plane or the same plane as the back surface 5b of the substrate 5.

On the side corresponding to the substrate 5, engagement hole portions 351, which are engaged portions that are engaged by the respective retaining pin portions 341, are formed. The engagement hole portions 351 are formed in the vicinity of the center portions in the longitudinal direction of the four side surfaces 5c of the substrate 5 corresponding to the arrangement of the four retaining pin portions 321. The engagement portions of the retaining pin portions 341 relative to the engagement hole portions 351 serve as engagement fixing portions 360 between the substrate 5 and the frame 6.

The engagement hole portion 351 forms an opening portion extending through the substrate 5 in the plate thickness direction, and has an elongated hole shape in plan view. The engagement hole portion 351 is formed such that the longitudinal direction of the elongated hole shape is along the circumferential direction of the virtual circle S1 in the substrate 5 in plan view. Specifically, the four engagement hole portions 351 are provided such that the center position of the elongated hole shape in the width direction is along the virtual circle S1. In the example illustrated in FIG. 69, the four engagement hole portions 351 are arranged at equal angular intervals in the circumferential direction of the virtual circle S1 corresponding to the arrangement of the four retaining pin portions 341. On the inner peripheral surface 351a of the engagement hole portion 351, a fitting protrusion 352 to be fitted into the retaining recess 344 of the retaining pin portion 341 is formed.

In the four engagement hole portions 351, the fitting protrusions 352 are provided at the end portions on the same side in the direction along the virtual circle S1. In the present embodiment, the fitting protrusion 352 is formed at the front end portion in the left rotation direction (see FIG. 69, arrow T1) in plan view in the direction along the virtual circle S1 in each engagement hole portion 351.

The fitting protrusion 352 is formed at an intermediate portion in the thickness direction of the substrate 5 inside the engagement hole portion 351. The fitting protrusion 352 is a portion having a protruding shape along a rectangular shape with respect to the inner peripheral surface 351a of the engagement hole portion 351 in a side cross-sectional view. The fitting protrusion 352 is formed by a protruding end surface 352a, which is an end surface on the protruding side, and an upper surface 352b and a lower surface 352c parallel to each other (see FIG. 70). In the fitting protrusion 352, the protruding end surface 352a is a rectangular surface, and the upper surface 352b and the lower surface 352c are substantially semicircular surfaces.

The frame 6 is fixed to the substrate 5 in a state in which the four retaining pin portions 341 are engaged with the respective engagement hole portions 351. The retaining pin portion 341 is inserted into the engagement hole portion 351 and is engaged with the engagement hole portion 351 by fitting the fitting protrusion 352 into the retaining recess 344. The distance between the upper surface 344b and the lower surface 344c of the retaining recess 344 of the retaining pin portion 341 is substantially the same as the dimension between the upper surface 352b and the lower surface 352c of the fitting protrusion 352, that is, the dimension in the up-down direction of the fitting protrusion 352.

The retaining pin portion 341 and the engagement hole portion 351 are configured such that the fitting protrusion 352 is fitted into the retaining recess 344 by a relative sliding movement in the lateral direction relative to the substrate 5 in a state in which the lower surface 24 of the frame main body portion 26 of the frame 6 is in contact with the surface 5a of the substrate 5. That is, the retaining recess 344 and the fitting protrusion 352 are provided so as to be fitted to each other by being relatively close to each other by the sliding movement of the frame 6 on the substrate 5. In the fitting between the retaining recess 344 and the fitting protrusion 352, the upper surface 344b and the lower surface 344c of the retaining recess 344 serve as sliding surfaces with respect to the upper surface 352b and the lower surface 352c of the fitting protrusion 352, respectively.

The retaining recess 344 and the fitting protrusion 352 are formed such that the fitted state is maintained by friction or the like between contact surfaces, which become sliding surfaces at the time of fitting. Regarding the dimension in the up-down direction, for example, the retaining recess 344 and the fitting protrusion 352 have a dimensional relationship that allows the retaining pin portion 341 in the fitted state to provide the action of sandwiching the fitting protrusion 352 in the up-down direction. In the example shown in FIG. 70, the retaining pin portion 341 is engaged with the engagement hole portion 351 in a state in which substantially the entire fitting protrusion 352 is positioned in the retaining recess 344.

Furthermore, as shown in FIG. 70, chamfered portions 353 for obtaining a guiding action for insertion and fitting may be formed on the upper and lower sides of the protruding side end portion of the fitting protrusion 352, which is to be inserted into the retaining recess 344. The chamfered portions for obtaining a guide action for insertion and fitting may be formed on the upper and lower sides of the opening edge portion of the retaining recess 344 of the retaining pin portion 341.

Note that the engagement shapes of the retaining pin portion 341 and the engagement hole portion 351 are not particularly limited. For example, the fitting protrusion 352 of the engagement hole portion 351 may be a portion having a tapered shape in which the dimension in the up-down direction is gradually reduced toward the protruding tip side. For example, the fitting protrusion 352 of the engagement hole portion 351 may be a crest-shaped protruding portion like the retaining protrusion 332 according to the sixth embodiment. The engagement shapes of the retaining pin portion 341 and the engagement hole portion 351 may be any shapes as long as they can be engaged with each other by sliding movement of the frame 6 on the substrate 5, and an engagement action capable of holding the mutual engagement state in a normal use environment of the solid-state imaging device 340 (not easily removed) can be obtained.

In the engagement hole portion 351, by setting the dimension in the width direction of the elongated hole shape to be substantially the same as the dimension of the outer diameter of the retaining pin portion 341, the retaining pin portion 341 can be positioned relative to the corresponding engagement hole portion 351 in the width direction of the elongated hole shape, and the function of positioning the frame 6 relative to the substrate 5 can be obtained. The engagement hole portion 351 can be formed by a known method such as a method using a laminated structure of the substrate 5 or a method using a processing apparatus.

The retaining pin portions 341 of the frame 6 and the substrate 5 including the engagement hole portions 351, which are engaged by the retaining pin portions 341, are configured such that the retaining pin portions 341 are engaged with the engagement hole portions 351 formed in the substrate 5 by relative rotation between the frame 6 and the substrate 5 with the up-down direction as the rotation axis direction.

As described above, a straight line in the up-down direction passing through the center positions O1 of the frame 6 and the substrate 5, which coincide with each other, or the position in the vicinity thereof serves as a rotation axis of the relative rotation of the frame 6 and the substrate 5. Also, the four retaining pin portions 341 and the four engagement hole portions 351 are arranged on the circumference of the common virtual circle S1, and are provided so that, with the circumference direction along the virtual circle S1 as a relative movement direction in the relative rotation between the frame 6 and the substrate 5, engagement by movement in a direction in which the frame 6 and the substrate 5 move toward each other and release of the engagement by movement in a direction in which the frame 6 and the substrate 5 move away from each other are performed.

### 21. Method for Manufacturing Solid-State Imaging Device According to Seventh Embodiment

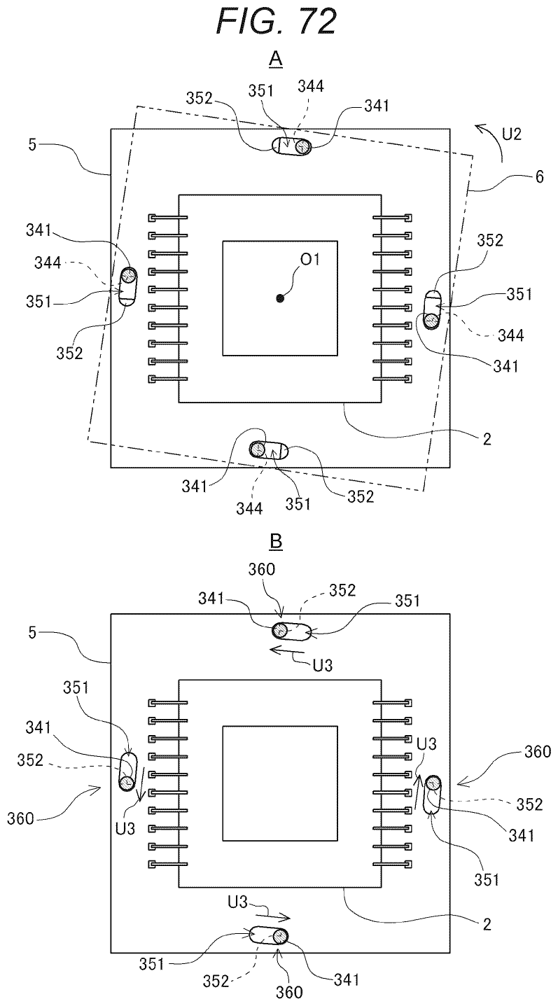

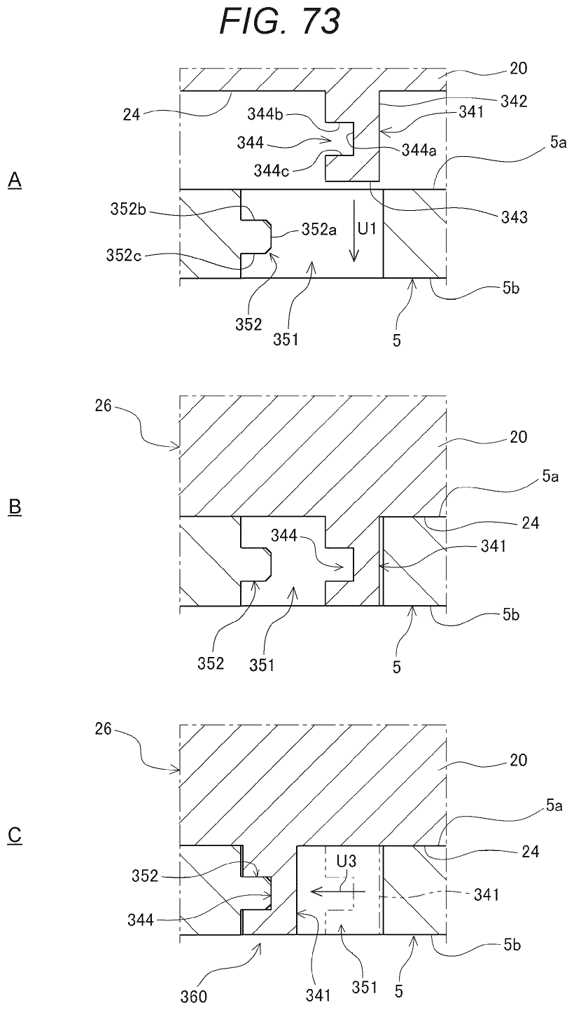

An example of a method for manufacturing the solid-state imaging device 340 according to the seventh embodiment of the present technology will be described with reference to FIGS. 72 and 73.

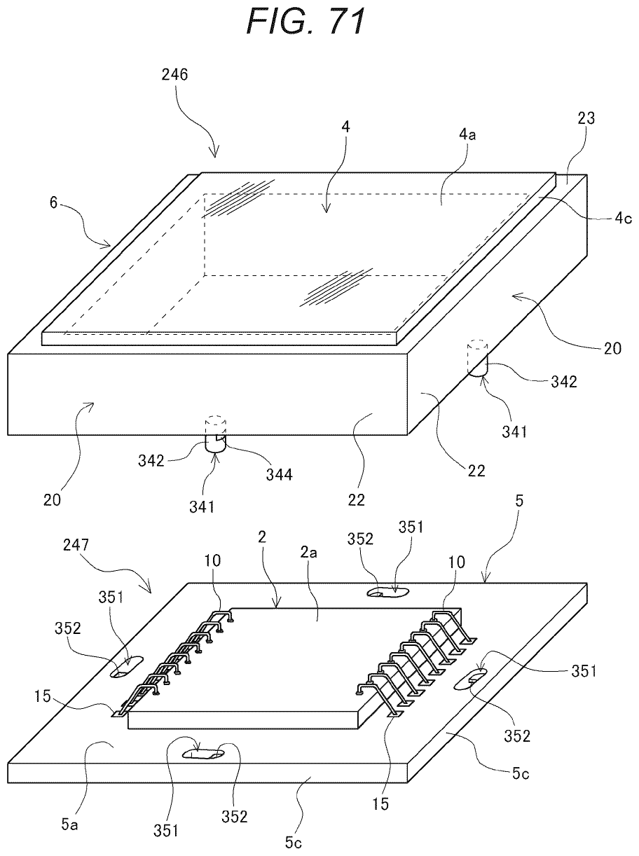

The frame 6 having the retaining pin portions 341 is manufactured by injection molding or the like using a mold as described above. Then, by fixing the cover glass 4 to the frame 6 with an adhesive, the frame with glass 246 is obtained (see FIG. 71). The frame with glass 246 is attached to the sensor mounting substrate 247.

In attaching the frame with glass 246, first, the frame with glass 246 is set relative to the sensor mounting substrate 247 in a state in which the four retaining pin portions 341 are inserted in the space portions opposite to the fitting protrusions 352 in the engagement hole portions 351 of the substrate 5. That is, first, as illustrated in FIG. 73A, the frame with glass 246 is placed in a state in which each retaining pin portion 341 is positioned above the space portion opposite to the side corresponding to the fitting protrusion 352 in the longitudinal direction of the elongated hole shape in the corresponding engagement hole portion 351. From this state, the frame with glass 246 and the substrate 5 are relatively moved in the up-down direction so as to move toward each other, the retaining pin portions 341 are inserted into the engagement hole portions 351 (see the arrow U1), and the frame 6 is placed on the substrate 5.

As a result, as illustrated in FIGS. 72A and 73B, the lower surface 24 of the frame 6 is in contact with the surface 5a of the substrate 5, and the retaining recess 344 of each retaining pin portion 341 located in the engagement hole portion 351 faces the fitting protrusion 352. As shown in FIG. 72A, in a state in which the frame with glass 246 is set on the substrate 5, the rectangular outer shapes of the frame 6 and the substrate 5 are offset from each other in a rotation direction around the center position O1 in plan view. Note that in FIG. 72A, the outer shape of the frame 6 is indicated by a two-dot chain line.

Then, from the state in which the frame with glass 246 is set relative to the substrate 5, an operation of relatively rotating the frame with glass 246 and the substrate 5 so as to be turned around a rotation axis in the up-down direction is performed. Here, the direction of the relative rotation of the frame with glass 246 and the substrate 5 is the direction in which the frame with glass 246 rotates in the left-handed direction (counterclockwise direction) relative to the substrate 5 in plan view (see FIG. 72A, arrow U2).

As illustrated in FIGS. 72B and 73C, the retaining pin portions 341 move toward the fitting protrusions 352 in the engagement hole portions 351 along with the relative rotation of the frame with glass 246 and the substrate 5, the fitting protrusions 352 are fitted into the retaining recesses 344 (see arrow U3), and the retaining pin portions 341 are engaged with the engagement hole portions 351. As a result, a state in which the frame with glass 246 is attached to the substrate 5 is obtained.

In a state in which the retaining pin portions 341 are engaged with the engagement hole portions 351, the outer shapes of the frame 6 and the substrate 5 coincide with each other in plan view. In the present embodiment, the angle of relative rotation of the frame with glass 246 relative to the substrate 5 from the set state of the frame with glass 246 relative to the substrate 5 to the state in which the retaining pin portions 341 are engaged with the engagement hole portions 351 is about 10°. However, the angle of the relative rotation varies depending on the length of the elongated hole shape of the engagement hole portions 351, the outer diameter of the retaining pin portions 341, and the like. By attaching the frame with glass 246 as described above, the solid-state imaging device 340 is obtained.

In the present embodiment, the frame with glass 246 is removed from the substrate 5 by releasing the engagement of the retaining pin portions 341 with the engagement hole portions 351. The engagement of the retaining pin portions 341 with the engagement hole portions 351 is released by relatively rotating the frame with glass 246 and the substrate 5 in a direction opposite to the attachment of the frame with glass 246 (right rotation direction in plan view). Also, as a method for removing the frame with glass 246, a method may be used that breaks the retaining pin portions 341 to release the engagement of the frame 6 with the substrate 5 and remove the frame with glass 246 from the substrate 5. By removing the frame with glass 246 from the solid-state imaging device 340, the sensor mounting substrate 247 is obtained.

According to the solid-state imaging device 340 according to the present embodiment as described above, since the retaining pin portions 341 provided on the lower side of the frame 6 is provided as the frame holding portions, it is possible to easily attach and detach the cover glass 4 together with the frame 6 as the frame with glass 246 without using a pressure-sensitive adhesive or the like, similarly to the solid-state imaging device 280 according to the sixth embodiment.

Furthermore, in the solid-state imaging device 340, the engagement fixing portions 360 formed by the retaining pin portions 341 and the engagement hole portions 351 are configured to be engaged and released by relative rotation of the frame 6 and the substrate 5. According to such a configuration, according to such a configuration, the frame with glass 246 can be attached and detached by a simple operation such as a rotation operation on the frame with glass 246 or the like, so that the cover glass 4 can be easily attached and detached. Other operational effects are similar to those of the sixth embodiment.

### 22. Modifications of Solid-State Imaging Device According to Seventh Embodiment

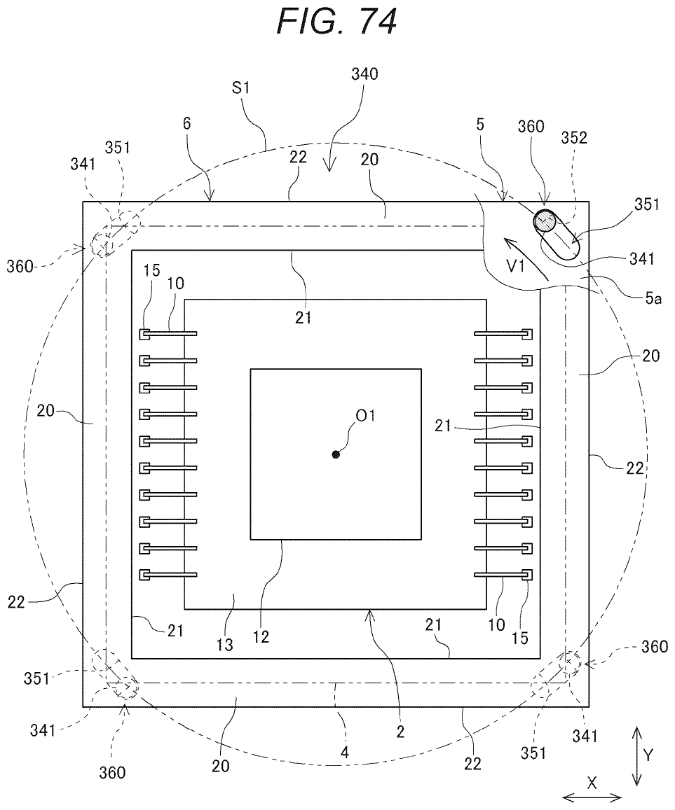

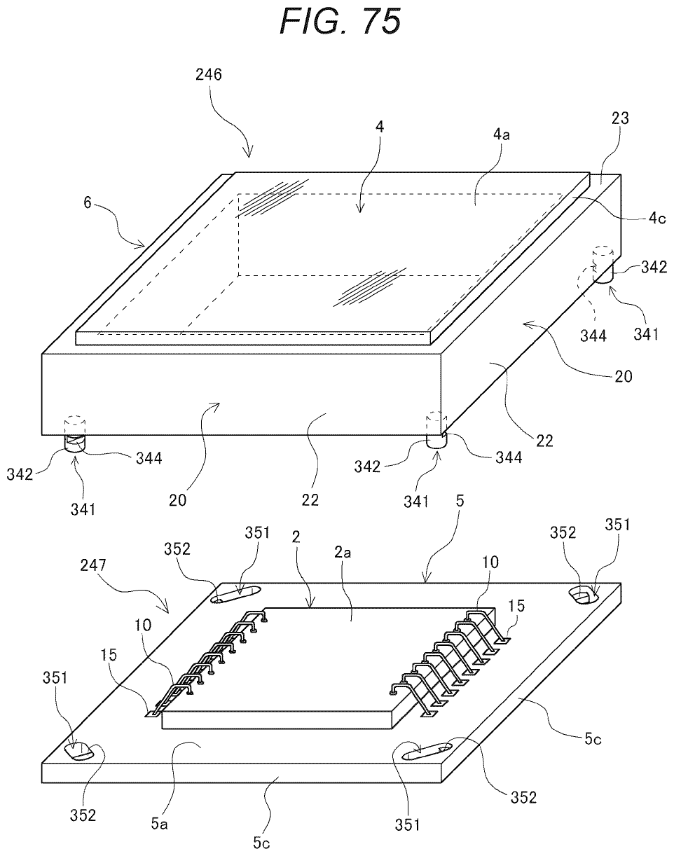

Modifications of the solid-state imaging device 340 according to the seventh embodiment of the present technology will be described. As illustrated in FIGS. 74 and 75, in the present modification, engagement fixing portions 360, each formed by a combination of a retaining pin portion 341 on the side corresponding to the frame 6 and an engagement hole portion 351 on the side corresponding to the substrate 5, are provided at four corner portions of the substrate 5. In the present modification, the retaining pin portions 341 and the engagement hole portions 351 are provided so as to be located on the circumference of the virtual circle S1 centered on the center position O1 of the solid-state imaging device 340 as described above.

In the present modification, on the side corresponding to the frame 6, the retaining pin portions 341 are provided at the four corners on the lower side of the frame main body portion 26 so as to correspond to the engagement hole portions 351 at the four corners of the substrate 5. In the retaining pin portions 341, the retaining recesses 344 are formed such that the open sides are front sides in the left rotation direction (see FIG. 74, arrow V1) in plan view in the direction along the virtual circle S1. Also, in the engagement hole portions 351, the fitting protrusions 352 are formed at the front end portions in the left rotation direction in plan view in the direction along the virtual circle S1.

Also in the configuration of the present modification, in a state in which the four retaining pin portions 341 are inserted in the engagement hole portions 351, the frame with glass 246 is rotated in the left rotation direction in plan view about the axis in the up-down direction relative to the substrate 5, whereby the retaining pin portions 341 are engaged with the engagement hole portions 351, and the frame with glass 246 is fixed to the substrate 5. Additionally, by rotating the frame with glass 246 in the right rotation direction in plan view relative to the substrate 5, the engagement between the retaining pin portions 341 and the engagement hole portions 351 is released, and the frame with glass 246 is removed. As in the present modification, the number and arrangement positions of the engagement fixing portions 360 can be appropriately changed according to the size and use of the package.

### 23. Configuration Example of Electronic Device

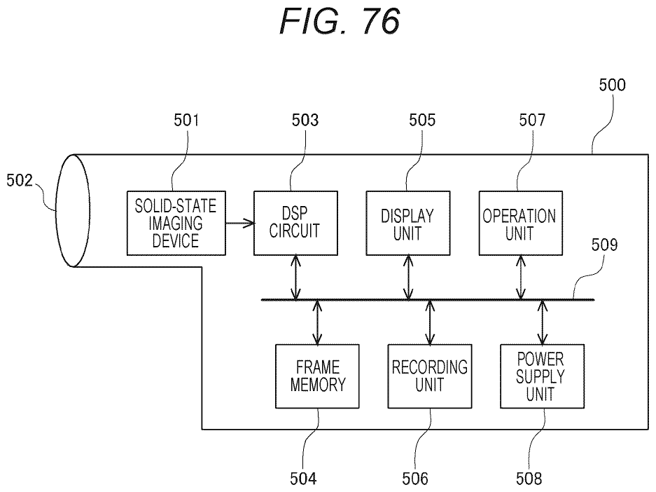

An application example of the semiconductor device according to the above-described embodiments to an electronic device will be described with reference to FIG. 76.

The semiconductor device (solid-state imaging device) according to the present technology can be used as various types of devices that sense light such as visible light, infrared light, ultraviolet light, and X-rays, for example. The solid-state imaging device according to the present technology is applicable to all electronic devices using a solid-state imaging element as an image capturing unit (photoelectric converter), such as a camera device such as a digital still camera or a video camera, a mobile terminal device having an imaging function, a copying machine using a solid-state imaging element as an image reading unit, an in-vehicle sensor that captures images of the front, rear, surroundings, inside, and the like of an automobile, and a ranging sensor that measures a distance between vehicles and the like. Furthermore, the solid-state imaging device may be formed as one chip, or may be in the form of a module having an imaging function in which an imaging unit and a signal processing unit or an optical system are packaged together.

As illustrated in FIG. 76, a camera device 500 as an electronic device includes an optical unit 502, a solid-state imaging device 501, a digital signal processor (DSP) circuit 503, which is a camera signal processing circuit, a frame memory 504, a display unit 505, a recording unit 506, an operation unit 507, and a power supply unit 508. The DSP circuit 503, the frame memory 504, the display unit 505, the recording unit 506, the operation unit 507, and the power supply unit 508 are appropriately connected via a connection line 509 such as a bus line. The solid-state imaging device 501 is any one of the solid-state imaging devices according to the above-described embodiments. Furthermore, the solid-state imaging device 501 may be a solid-state imaging device in a state in which the cover glass 4 is removed, such as the image sensor unit 1A from which the cover glass 4 is removed (see FIG. 8C), the image sensor unit 80A from which the lid body 85 is removed (see FIG. 21), or the sensor mounting substrate 247 in which the frame with glass 246 is removed from the solid-state imaging device 280 (see FIG. 57).

The optical unit 502 includes multiple lenses, and captures incident light (image light) from a subject to form an image on an imaging surface of the solid-state imaging device 501. The solid-state imaging device 501 converts the light amount of the incident light imaged on the imaging surface by the optical unit 502 into an electrical signal for each pixel and outputs the electrical signal as a pixel signal.

The display unit 505 includes, for example, a panel type display device such as a liquid crystal panel or an organic electro luminescence (EL) panel, and displays a moving image or a still image captured by the solid-state imaging device 501. The recording unit 506 records the moving image or the still image captured by the solid-state imaging device 501 on a recording medium such as a hard disk or a semiconductor memory.

The operation unit 507 issues operation commands for various functions of the camera device 500 under operation by the user. The power supply unit 508 appropriately supplies various power sources serving as operation power sources of the DSP circuit 503, the frame memory 504, the display unit 505, the recording unit 506, and the operation unit 507 to these supply targets.

According to the camera device 500 as described above, regarding the solid-state imaging device 501, it is possible to obtain the attached state of the cover glass 4 in order to obtain good handleability and to prevent foreign matter from entering the inside of the package, and it is possible to easily remove the cover glass 4 in order to solve problems such as ghost and flare caused by the presence of the cover glass 4.

The description of the above-described embodiments is an example of the present technology, and the present technology is not limited to the above-described embodiments. For this reason, it is a matter of course that various modifications can be made according to the design and the like without departing from the technical idea according to the present disclosure even in a case other than the above-described embodiments. Furthermore, the effects described in the present disclosure are merely examples and are not limited, and other effects may be provided. Furthermore, the configurations of the above-described embodiments and the configuration of each modification can be appropriately combined.

In the above-described embodiments, the semiconductor element is the image sensor 2 that is a light receiving element, but the semiconductor element according to the present technology is not limited to an image sensor. The semiconductor element according to the present technology may be, for example, a light emitting element such as a vertical cavity surface emitting laser (VCSEL), a laser diode, or a light emitting diode (LED). Furthermore, the imaging device as a semiconductor device may have a configuration where multiple semiconductor elements are provided in one chip or a configuration where multiple semiconductor elements are provided as multiple chips.

Furthermore, in the above-described embodiments, the transparent cover glass 4 has been given as an example of the cover member according to the present technology, but the cover member according to the present technology is not limited to a transparent member, and may be a translucent or opaque cover body. Furthermore, the shape of the cover member according to the present technology is not limited to the rectangular plate shape, and may be another shape such as a disk shape, for example.

Note that the present technology can also employ the following configurations.

(1)

A semiconductor device including:
a substrate;
a semiconductor element mounted on the substrate;
a cover member covering the semiconductor element from above;
a frame supporting the cover member relative to the substrate; and
a cover holding portion detachably holding the cover member relative to at least a part of the frame.
   (2)

The semiconductor device according to (1), in which
the frame includes a frame main body portion that surrounds the semiconductor element and forms a support surface supporting the cover member, and
the semiconductor device further includes, as the cover holding portion, a cover fixing portion that is provided on an upper side of the frame main body portion and fixes the cover member to the frame by restricting movement of the cover member supported on the support surface relative to the frame main body portion.
   (3)

The semiconductor device according to (2), in which
the cover member is a member having a shape of a flat plate, and
the frame includes, as the cover fixing portion, a step forming portion that forms a step portion relative to the support surface and comes into contact with a side surface of the cover member to restrict movement of the cover member, and a retaining portion that comes into contact with the side surface of the cover member and restricts movement of the cover member in a direction away from the support surface.
   (4)

The semiconductor device according to (3), in which
the frame includes, as the retaining portion,
a clip portion configured to attach and detach the cover member to and from the frame main body portion with temporary elastic deformation, and
a hook portion provided on an opposite side of the cover member from the clip portion, the hook portion allowing an edge portion of the cover member to be fitted between the hook portion and the support surface.
   (5)

The semiconductor device according to any one of (2) to (4), in which
the frame main body portion has a recess that opens at the support surface and is partially covered with the cover member.
   (6)

The semiconductor device according to (1), in which
the frame includes
a first frame portion fixed to the substrate, and
a second frame portion that forms the cover holding portion and is detachably attached to the first frame portion.
   (7)

The semiconductor device according to (6), in which
the second frame portion includes
a frame-shaped main body portion holding the cover member, and
an engagement portion that is provided in the main body portion and engages with the first frame portion such that the second frame portion is held by the first frame portion.
   (8)

The semiconductor device according to (7), in which
the engagement portion is a rotation engaging body rotatably supported relative to the main body portion in a state of being urged by an urging member in a direction of engaging with an engaged portion formed in the first frame portion.
   (9)

The semiconductor device according to any one of (6) to (8), in which
the first frame portion includes a recess that opens at an upper surface and is partially covered with the cover member.
   (10)

The semiconductor device according to (1), in which
the frame includes a frame main body portion that surrounds the semiconductor element and forms a support surface that supports the cover member, and
the semiconductor device further includes, as the cover holding portion,
a step forming portion that is provided on an upper side of the frame main body portion, forms a step portion relative to the support surface, and comes into contact with a side surface of the cover member to restrict movement of the cover member, and
a bonding portion that is interposed between the frame main body portion and the cover member and includes an adhesive for fixing the cover member to the frame main body portion.
   (11)

The semiconductor device according to (10), in which
the frame main body portion has a recess that opens at the support surface and is partially covered with the cover member.
   (12)

The semiconductor device according to (10) or (11), in which
the adhesive includes a hot melt adhesive, and
a recess for positioning the bonding portion is formed in at least one of the support surface and a lower surface of the cover member facing the support surface.
   (13)

A semiconductor device including:
a substrate;
a semiconductor element mounted on the substrate;
a cover member covering the semiconductor element from above;
a frame supporting the cover member relative to the substrate; and
a frame holding portion detachably holding the frame relative to the substrate.
   (14)

The semiconductor device according to (13), in which
the frame includes a frame main body portion that surrounds the semiconductor element and forms a support surface that supports the cover member,
the cover member is fixed to the support surface, and
the semiconductor device further includes, as the frame holding portion,
a step forming portion that is provided on a lower side of the frame main body portion, forms a step portion relative to a lower surface of the frame main body portion, and comes into contact with a side surface of the substrate to restrict movement of the substrate, and
a bonding portion that is interposed between the frame main body portion and the substrate and includes an adhesive for fixing the frame main body portion to the substrate.
   (15)

The semiconductor device according to (14), in which
the adhesive includes a hot melt adhesive, and
a recess for positioning the bonding portion is formed in at least one of a lower surface of the frame main body portion and an upper surface of the substrate facing the lower surface.
   (16)

The semiconductor device according to (13), in which
the frame includes a frame main body portion that surrounds the semiconductor element and forms a support surface supporting the cover member,
the cover member is fixed to the support surface, and
the semiconductor device further includes, as the frame holding portion, an engagement portion that is provided on a lower side of the frame main body portion and fixes the frame to the substrate by engaging with the substrate.
   (17)

The semiconductor device according to (16), in which
the engagement portion includes a retaining protruding piece portion that is configured to be in a state of being retained to an engaged portion formed in the substrate with temporary elastic deformation.
   (18)

The semiconductor device according to (16), in which
the engagement portion and the substrate are configured such that relative rotation of the frame and the substrate with an up-down direction as a rotation axis direction causes a state in which the engagement portion engages with an engaged portion formed in the substrate.
   (19)

An electronic device including
a semiconductor device including:
a substrate;
a semiconductor element mounted on the substrate;
a cover member covering the semiconductor element from above;
a frame supporting the cover member relative to the substrate; and
a cover holding portion detachably holding the cover member relative to at least a part of the frame.
   (20)

An electronic device including
a semiconductor device including:
a substrate;
a semiconductor element mounted on the substrate;
a cover member covering the semiconductor element from above;
a frame supporting the cover member relative to the substrate; and
a frame holding portion detachably holding the frame relative to the substrate.

### REFERENCE SIGNS LIST

1 Solid-state imaging device (semiconductor device)
2 Image sensor (semiconductor element)
4 Cover glass (cover member)
4b Lower surface
4c Side surface
5 Substrate
5a Surface (upper surface)
6 Frame
20 Wall portion
20a Upper surface
23 Glass support surface (support surface)
24 Lower surface
26 Frame main body portion
30 Cover fixing portion (cover holding portion)
31 Step forming portion (cover fixing portion)
32 Clip portion (cover fixing portion, retaining portion)
33 Hook portion (cover fixing portion, retaining portion)
35 Step portion
60 Recess
80 Solid-state imaging device (semiconductor device)
81 Substrate-side frame (first frame portion)
82 Glass-side frame (second frame portion)
86 Frame-shaped main body portion (main body portion)
92 Clip portion (engagement portion)
93 Hook portion (engagement portion)
102 Engagement recess
103 Engagement recess
120 Solid-state imaging device (semiconductor device)
121 Substrate-side frame (first frame portion)
122 Glass-side frame (second frame portion)
126 Frame-shaped main body portion (main body portion)
132 Clip (engagement portion, rotation engaging body)
133 Coil spring (urging member)
158 Engagement recess (engaged portion)
180 Solid-state imaging device (semiconductor device)
181 Step forming portion
182 Bonding portion
182B Hot melt bonding portion
185 Step portion
201 Groove portion (recess)
221 Groove portion (recess)
230 Solid-state imaging device (semiconductor device)
231 Step forming portion
232 Bonding portion
232B Hot melt bonding portion
251 Groove portion (recess)
271 Groove portion (recess)
280 Solid-state imaging device (semiconductor device)
281 Hook portion (frame holding portion, engagement portion, retaining protruding piece portion)
301 Engagement recess (engaged portion)
321 Retaining pin portion (frame holding portion, engagement portion, retaining protruding piece portion)
331 Engagement hole portion (engaged portion)
340 Solid-state imaging device (semiconductor device)
341 Retaining pin portion (frame holding portion, engagement portion)
351 Engagement hole portion (engaged portion)
500 Camera device (electronic device)
501 Solid-state imaging device (semiconductor device)

1. A semiconductor device comprising:
a substrate;
a semiconductor element mounted on the substrate;
a cover member covering the semiconductor element from above;
a frame supporting the cover member relative to the substrate; and
a cover holding portion detachably holding the cover member relative to at least a part of the frame.

2. The semiconductor device according to claim 1, wherein
the frame includes a frame main body portion that surrounds the semiconductor element and forms a support surface supporting the cover member, and
the semiconductor device further comprises, as the cover holding portion, a cover fixing portion that is provided on an upper side of the frame main body portion and fixes the cover member to the frame by restricting movement of the cover member supported on the support surface relative to the frame main body portion.

3. The semiconductor device according to claim 2, wherein
the cover member is a member having a shape of a flat plate, and
the frame includes, as the cover fixing portion, a step forming portion that forms a step portion relative to the support surface and comes into contact with a side surface of the cover member to restrict movement of the cover member, and a retaining portion that comes into contact with the side surface of the cover member and restricts movement of the cover member in a direction away from the support surface.

4. The semiconductor device according to claim 3, wherein
the frame includes, as the retaining portion,
a clip portion configured to attach and detach the cover member to and from the frame main body portion with temporary elastic deformation, and
a hook portion provided on an opposite side of the cover member from the clip portion, the hook portion allowing an edge portion of the cover member to be fitted between the hook portion and the support surface.

5. The semiconductor device according to claim 2, wherein
the frame main body portion has a recess that opens at the support surface and is partially covered with the cover member.

6. The semiconductor device according to claim 1, wherein
the frame includes
a first frame portion fixed to the substrate, and
a second frame portion that forms the cover holding portion and is detachably attached to the first frame portion.

7. The semiconductor device according to claim 6, wherein
the second frame portion includes
a frame-shaped main body portion holding the cover member, and
an engagement portion that is provided in the main body portion and engages with the first frame portion such that the second frame portion is held by the first frame portion.

8. The semiconductor device according to claim 7, wherein
the engagement portion is a rotation engaging body rotatably supported relative to the main body portion in a state of being urged by an urging member in a direction of engaging with an engaged portion formed in the first frame portion.

9. The semiconductor device according to claim 6, wherein
the first frame portion includes a recess that opens at an upper surface and is partially covered with the cover member.

10. The semiconductor device according to claim 1, wherein
the frame includes a frame main body portion that surrounds the semiconductor element and forms a support surface that supports the cover member, and
the semiconductor device further comprises, as the cover holding portion,
a step forming portion that is provided on an upper side of the frame main body portion, forms a step portion relative to the support surface, and comes into contact with a side surface of the cover member to restrict movement of the cover member, and
a bonding portion that is interposed between the frame main body portion and the cover member and includes an adhesive for fixing the cover member to the frame main body portion.

11. The semiconductor device according to claim 10, wherein
the frame main body portion has a recess that opens at the support surface and is partially covered with the cover member.

12. The semiconductor device according to claim 10, wherein
the adhesive includes a hot melt adhesive, and
a recess for positioning the bonding portion is formed in at least one of the support surface and a lower surface of the cover member facing the support surface.

13. A semiconductor device comprising:
a substrate;
a semiconductor element mounted on the substrate;
a cover member covering the semiconductor element from above;
a frame supporting the cover member relative to the substrate; and
a frame holding portion detachably holding the frame relative to the substrate.

14. The semiconductor device according to claim 13, wherein
the frame includes a frame main body portion that surrounds the semiconductor element and forms a support surface that supports the cover member,
the cover member is fixed to the support surface, and
the semiconductor device further comprises, as the frame holding portion,
a step forming portion that is provided on a lower side of the frame main body portion, forms a step portion relative to a lower surface of the frame main body portion, and comes into contact with a side surface of the substrate to restrict movement of the substrate, and
a bonding portion that is interposed between the frame main body portion and the substrate and includes an adhesive for fixing the frame main body portion to the substrate.

15. The semiconductor device according to claim 14, wherein
the adhesive includes a hot melt adhesive, and
a recess for positioning the bonding portion is formed in at least one of a lower surface of the frame main body portion and an upper surface of the substrate facing the lower surface.

16. The semiconductor device according to claim 13, wherein
the frame includes a frame main body portion that surrounds the semiconductor element and forms a support surface supporting the cover member,
the cover member is fixed to the support surface, and
the semiconductor device further comprises, as the frame holding portion, an engagement portion that is provided on a lower side of the frame main body portion and fixes the frame to the substrate by engaging with the substrate.

17. The semiconductor device according to claim 16, wherein
the engagement portion includes a retaining protruding piece portion that is configured to be in a state of being retained to an engaged portion formed in the substrate with temporary elastic deformation.

18. The semiconductor device according to claim 16, wherein
the engagement portion and the substrate are configured such that relative rotation of the frame and the substrate with an up-down direction as a rotation axis direction causes a state in which the engagement portion engages with an engaged portion formed in the substrate.

19. An electronic device comprising
a semiconductor device including:
a substrate;
a semiconductor element mounted on the substrate;
a cover member covering the semiconductor element from above;
a frame supporting the cover member relative to the substrate; and
a cover holding portion detachably holding the cover member relative to at least a part of the frame.

20. An electronic device comprising
a semiconductor device including:
a substrate;
a semiconductor element mounted on the substrate;
a cover member covering the semiconductor element from above;
a frame supporting the cover member relative to the substrate; and
a frame holding portion detachably holding the frame relative to the substrate.
